(19) United States
(12) Patent Application Publication
(10) Pub. No.: US 2009/0039767 A1
(43) Pub. Date: Feb. 12, 2009

(54) METAL COMPLEX COMPOUND, MATERIAL FOR ORGANIC ELECTROLUMINESCENCE DEVICE AND ORGANIC ELECTROLUMINESCENCE DEVICE USING THE SAME

(75) Inventors: Masa-aki Haga, Tokyo (JP); Masumi Itabashi, Tokyo (JP); Misa Ashizawa, Tokyo (JP); Fumio Okuda, Chiba (JP); Toshinari Ogiwara, Chiba (JP); Hideaki Nagashima, Chiba (JP)

Correspondence Address: OBLON, SPIVAK, MCCLELLAND MAIER & NEUSTADT, P.C., 1940 DUKE STREET, ALEXANDRIA, VA, 22314, US

(73) Assignees: IDEMITSU KOSAN CO., LTD., Chiyoda-ku (JP); CHUO UNIVERSITY, Hachioji-shi (JP)

(21) Appl. No.: 11/833,657

(22) Filed: Aug. 3, 2007

(51) Int. Cl. H01L 51/54; C07F 17/02

(52) U.S. Cl. 313/504; 546/4

(57) ABSTRACT

Provided are an organic electroluminescence device which: can emit blue light having a short wavelength and a high color purity; and can be combined with any other light emitting compound to emit white light and a metal complex compound for realizing the device, and a material for an organic electroluminescence device. The metal complex is of a specific structure having a tridentate chelate ligand and an electron withdrawing group. The material for an organic electroluminescence device is formed of the metal complex compound. The organic electroluminescence device has an organic thin film layer formed of one or more layers including at least a light emitting layer, the organic thin film layer being interposed between a pair of electrodes. In the organic electroluminescence device, at least one layer of the organic thin film layer contains the metal complex compound, and emits light by applying a voltage between both the electrodes.

### TECHNICAL FIELD

The present invention relates to a novel metal complex compound and an organic electroluminescence device using the compound, in particular, to an organic electroluminescence device which: can emit blue light having a short wavelength and a high color purity; and can be combined with any other light emitting compound to emit white light and a metal complex compound for realizing the device, and a material for an organic electroluminescence device.

### BACKGROUND ART

Investigation has been vigorously conducted on the use of an organic electroluminescence (EL) device as a display device for color display that replaces liquid crystallin recent years. However, the performance of the organic EL device as a light emitting device is still insufficient to realize the enlargement of the screen size of a display device using the organic EL device. A green light emitting device using an ortho-metallized iridium complex (fac-tris(2-phenylpyridine)iridium), which is a phosphorescent material, as a light emitting material has been proposed as means for improving the performance of the organic EL device (Non-patent Document 1; Non-patent Document 2).

At present, the color of light emitted from an organic EL device utilizing phosphorescence has been limited to a green color and a red color, so the scope of application of the device as a color display is narrow, and the development of a device with improved light emitting property for any other color has been demanded. In particular, no blue light emitting device having an outer quantum yield in excess of 5% has been reported. If the blue light emitting device can be improved, a color display formed only of phosphorescent organic EL devices will be able to display full colors and a white color. Accordingly, the improvement makes great strides forward in putting a phosphorescent EL device to practical use.

At present, the development of a compound containing Ir as a phosphorescent complex has been vigorously conducted, and the following compound A is known as a compound for a green light emitting device. On the other hand, the following compound B is known as a compound for a blue light emitting device, but is not practical in terms of the lifetime and efficiency of a device formed of the compound. In view of the foregoing, there arises a need for developing another complex for a blue light emitting device. However, no factor other than the compound B has been found at present.

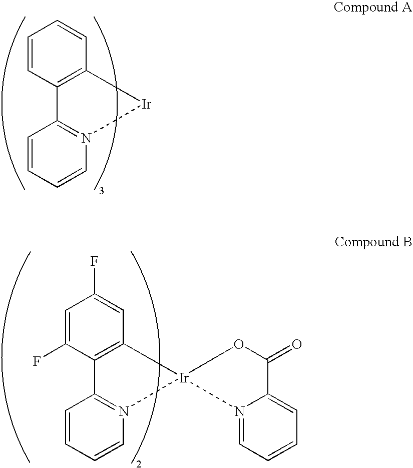

The above-mentioned compounds A and B belong to the group of complexes each using a bidentate chelate ligand. However, few complexes each using a tridentate chelate ligand similar to the bidentate ligand are known, and only a compound C described below (see Non-patent Document 3) is known.

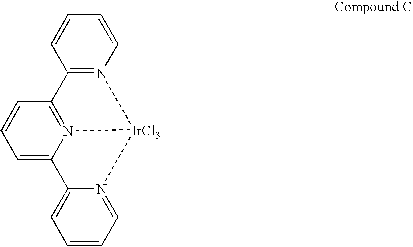

However, the wavelength of light emission of compound C is in a region of 600 nm, that is, a red color region, not in a blue color region. If a complex capable of emitting light in a blue color region can be realized by using the tridentate chelate ligand, the realization will lead to the possibility of new technical development.

In addition, Patent Documents 1 and 2 each disclose a metal complex compound having a tridentate chelate ligand. However, none of the documents discloses a technology for causing the metal complex compound to emit light having an additionally short wavelength by adding an electron withdrawing group to a specific site of the compound.

[Non-patent Document 1] D. F. O'Brien and M. A. Baldo et al. “Improved energy transfer in electrophosphorescent devices” Applied Physics letters Vol. 74 No. 3, pp 442-444, Jan. 18, 1999

[Non-patent Document 2] M. A. Baldo et al. “Very high-efficiency green organic light-emitting devices based on electrophosphorescence” Applied Physics letters Vol. 75 No. 1, pp 4-6, Jul. 5, 1999

[Non-patent Document 3] J-P. Collin et al., J. Am. Chem. Soc., 121, 5009 (1999)

[Non-patent Document 4] J. A. G. Williams, Inorg. Chem., 43, 6513 (2004)

[Patent Document 1] WO 2006/051806

[Patent Document 2] JP 2006-160724

### DISCLOSURE OF THE INVENTION

### Problems to be Solved by the Invention

The present invention has been made to overcome the above problems and has an object of providing an organic EL device which emits blue light with high purity and of short wavelength, and which is capable of white light emission by combining with other light emitting compounds and a metal complex compound for realizing the device, and a material for organic EL device.

### Means for Solving the Problems

The inventors of the present invention clarified a novel structural factor in emitting blue light, which employs a metal complex compound having an electron withdrawing group and a partial structure with a tridentate chelate ligand represented by a following general formula (I), enables to emit highly pure blue light of short wavelength, and the present invention has been thus accomplished.

That is, the present invention provides a metal complex compound which includes a partial structure having a tridentate chelate ligand represented by the following general formula (I).

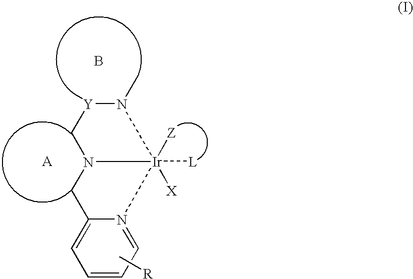

where: Ring A is an aromatic hydrocarbon group which has 6 to 20 carbon atoms and which may have a substituent, or a heterocyclic group which has 2 to 20 carbon atoms and which may have a substituent;

Ring B is a heterocyclic group which has 2 to 20 carbon atoms and which may have a substituent, N represents a nitrogen atom, and Y represents a carbon atom or a nitrogen atom;

L and Z each independently represent an organic group containing an atom belonging to any one of Groups 14 to 16 in the periodic table;

X represents a monovalent ligand containing an atom belonging to any one of Groups 14 to 17 in the periodic table; and

R represents a hydrogen atom, a cyano group, a nitro group, a halogen atom, an alkyl group which has 1 to 12 carbon atoms and which may have a substituent, an alkylamino group which has 1 to 12 carbon atoms and which may have a substituent, an arylamino group which has 6 to 20 carbon atoms and which may have a substituent, an alkoxy group which has 1 to 12 carbon atoms and which may have a substituent, an alkoxy halide group which has 1 to 12 carbon atoms and which may have a substituent, an aryloxy group which has 6 to 20 carbon atoms and which may have a substituent, an aromatic hydrocarbon group which has 6 to 20 carbon atoms and which may have a substituent, a heterocyclic group which has 2 to 20 carbon atoms and which may have a substituent, an alkyl halide group which has 1 to 12 carbon atoms and which may have a substituent, an alkenyl group which has 2 to 12 carbon atoms and which may have a substituent, an alkynyl group which has 2 to 12 carbon atoms and which may have a substituent, or a cycloalkyl group which has 3 to 20 carbon atoms and which may have a substituent, and the number of R may be two or more, and, in this case, Rs may be identical to or different from each other, and adjacent Rs may be bonded to each other to form a cyclic structure,

provided that at least one of the tridentate chelate ligand and a bidentate chelate ligand contains an electron withdrawing group.

Further, the present invention provides a material for an organic electroluminescence device including the above metal complex compound, and an organic electroluminescence device including an organic thin film layer formed of one or more layers including at least a light emitting layer, the organic thin film layer being interposed between a pair of electrodes, in which at least one layer of the organic thin film layer contains the above metal complex compound and emits light by applying a voltage between both the electrodes.

Further, according to the present invention, there is provided an organic EL device capable of emitting white light having a high color purity by simultaneously using the metal complex compound and a red light emitting material as luminous dopants for its light emitting layer.

### EFFECT OF THE INVENTION

The present invention provides an organic EL device, which emits blue light with high purity and of short wavelength with an enhanced efficiency of light emission, and which can emit white light by combining with other light emitting compounds. The present invention also provides a metal complex compound realizing the organic EL device.

### BRIEF DESCRIPTION OF THE DRAWINGS

FIG. 1 is a view showing a UV absorption spectrum of Metal Complex Compound 3.

FIG. 2 is a view showing a UV absorption spectrum of Metal Complex Compound 4.

FIG. 3 is a view showing a UV absorption spectrum of Metal Complex Compound 5.

FIG. 4 is a view showing a UV absorption spectrum of Metal Complex Compound 6.

FIG. 5 is a view showing a UV absorption spectrum of Metal Complex Compound 7.

FIG. 6 is a view showing a UV absorption spectrum of Metal Complex Compound 8.

FIG. 7 is a view showing a UV absorption spectrum of Metal Complex Compound 9.

FIG. 8 is a view showing a UV absorption spectrum of Metal Complex Compound 10.

FIG. 9 is a view showing a UV absorption spectrum of Metal Complex Compound 11.

FIG. 10 is a view showing a UV absorption spectrum of Metal Complex Compound 12.

FIG. 11 is a view showing a UV absorption spectrum of Metal Complex Compound 29.

FIG. 12 is a view showing a UV absorption spectrum of Metal Complex Compound 30.

FIG. 13 is a view showing a room temperature emission spectrum of Metal Complex Compound 3.

FIG. 14 is a view showing a room temperature emission spectrum of Metal Complex Compound 4.

FIG. 15 is a view showing a room temperature emission spectrum of Metal Complex Compound 5.

FIG. 16 is a view showing a room temperature emission spectrum of Metal Complex Compound 6.

FIG. 17 is a view showing a room temperature emission spectrum of Metal Complex Compound 7.

FIG. 18 is a view showing a room temperature emission spectrum of Metal Complex Compound 8.

FIG. 19 is a view showing a room temperature emission spectrum of Metal Complex Compound 9.

FIG. 20 is a view showing a room temperature emission spectrum of Metal Complex Compound 10.

FIG. 21 is a view showing a low temperature emission spectrum of Metal Complex Compound 11.

FIG. 22 is a view showing a room temperature emission spectrum of Metal Complex Compound 12.

FIG. 23 is a view showing a room temperature emission spectrum of Metal Complex Compound 29.

FIG. 24 is a view showing a low temperature emission spectrum of Metal Complex Compound 30.

FIG. 25 is a view showing a low temperature emission spectrum of Metal Complex Compound 3.

FIG. 26 is a view showing a low temperature emission spectrum of Metal Complex Compound 4.

FIG. 27 is a view showing a low temperature emission spectrum of Metal Complex Compound 5.

FIG. 28 is a view showing a low temperature emission spectrum of Metal Complex Compound 6.

FIG. 29 is a view showing a low temperature emission spectrum of Metal Complex Compound 7.

FIG. 30 is a view showing a low temperature emission spectrum of Metal Complex Compound 8.

FIG. 31 is a view showing a low temperature emission spectrum of Metal Complex Compound 9.

FIG. 32 is a view showing a low temperature emission spectrum of Metal Complex Compound 10.

FIG. 33 is a view showing a low temperature emission spectrum of Metal Complex Compound 11.

FIG. 34 is a view showing a low temperature emission spectrum of Metal Complex Compound 12.

FIG. 35 is a view showing a low temperature emission spectrum of Metal Complex Compound 29.

FIG. 36 is a view showing a low temperature emission spectrum of Metal Complex Compound 30.

FIG. 37 is a view showing an X-ray crystallographic analysis of Metal Complex Compound 3.

FIG. 38 is a view showing an X-ray crystallographic analysis of Metal Complex Compound 4.

FIG. 39 is a view showing an X-ray crystallographic analysis of Metal Complex Compound 9.

FIG. 40 is a view showing an X-ray crystallographic analysis of Metal Complex Compound 29.

FIG. 41 is a view showing an EL spectrum in an organic EL device of each of Examples 1 to 4.

FIG. 42 is a view showing an EL spectrum in an organic EL device of each of Examples 5 to 7.

FIG. 43 is a view showing an EL spectrum in an organic EL device of each of Examples 8 to 10.

FIG. 44 is a view showing an EL spectrum in an organic EL device of Example 11.

FIG. 45 is a view showing an EL spectrum in an organic EL device of Example 12.

FIG. 46 is a view showing an EL spectrum in an organic EL device of each of Examples 13 to 15.

FIG. 47 is a view showing an EL spectrum in an organic EL device of Example 16.

FIG. 48 is a view showing an EL spectrum in an organic EL device of each of Examples 17 and 18.

### BEST MODE FOR CARRYING OUT THE INVENTION

A metal complex compound of the present invention includes a partial structure having a tridentate chelate ligand represented by the following general formula (I):

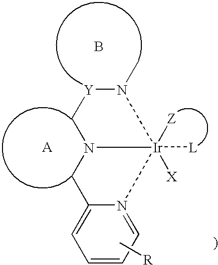

In the general formula (I), Ring A is an aromatic hydrocarbon group which has 6 to 20 carbon atoms and which may have a substituent, or a heterocyclic group which has 2 to 20 carbon atoms and which may have a substituent, Ring B is a heterocyclic group which has 2 to 20 carbon atoms and which may have a substituent, N represents a nitrogen atom, and Y represents a carbon atom or a nitrogen atom.

Examples of the Ring A aromatic hydrocarbon group include residues such as benzene, naphthalene, anthracene, phenanthrene, pyrene, biphenyl, terphenyl, and fluoranthene, and the benzene is preferred.

Examples of the heterocyclic group corresponding to each of Ring A and Ring B include the residues of imidazole, benzimidazole, pyrrole, furan, thiophene, benzothiophene, oxadiazoline, indoline, carbazole, pyridine, quinoline, isoquinoline, benzoquinone, pyralozine, imidazolidine, piperidine, pyrazole, thiazole, oxazole, benzofuran, and the like. Of those, the residues of pyridine, pyrazole, thiazole, oxazole, and the benzofuran are preferred. The heterocyclic group corresponding to Ring B is particularly preferably pyridine.

Further, examples of a substituent for each of the groups include a halogen atom, a hydroxyl group, a substituted or unsubstituted amino group, a nitro group, a cyano group, a substituted or unsubstituted alkyl group, an alkyl group substituted with a fluorine atom, a substituted or unsubstituted alkenyl group, a substituted or unsubstituted cycloalkyl group, a substituted or unsubstituted alkoxyl group, a substituted or unsubstituted heterocyclic group, a substituted or unsubstituted arylalkyl group, a substituted or unsubstituted aryloxy group, a substituted or unsubstituted alkoxycarbonyl group, and a carboxyl group.

In the general formula (I), Land Z each independently represent an organic group containing an atom belonging to any one of Groups 14 to 16 in the periodic table.

Examples of the atom belonging to any one of Groups 14 to 16 in the periodic table included in the L and Z include carbon (C), nitrogen (N), oxygen (O), silicon (Si), phosphorus (P), sulfur (S), germanium (Ge), arsenic (As), and selenium (Se) atoms. Of those, carbon, nitrogen, and oxygen atoms are preferred.

Further, it is preferred that organic groups denoted by L and Z be each independently, for example, a hydrogen atom, a cyano group, a halogen atom, an alkyl group which has 1 to 12 carbon atoms and which may have a substituent, an alkylamino group which has 1 to 12 carbon atoms and which may have a substituent, an arylamino group which has 6 to 20 carbon atoms and which may have a substituent, an alkoxy group which has 1 to 12 carbon atoms and which may have a substituent, a halogenated alkoxy group which has 1 to 12 carbon atoms and which may have a substituent, an aryloxy group which has 6 to 20 carbon atoms and which may have a substituent, an aromatic hydrocarbon group which has 6 to 20 carbon atoms and which may have a substituent, a heterocyclic group which has 2 to 20 carbon atoms and which may have a substituent, a halogenated alkyl group which has 1 to 12 carbon atoms and which may have a substituent, an alkenyl group which has 2 to 12 carbon atoms and which may have a substituent, an alkynyl group which has 2 to 12 carbon atoms and which may have a substituent, or a cycloalkyl group which has 3 to 20 carbon atoms and which may have a substituent.

Examples of the halogen atom include fluorine, chlorine, bromine, and iodine atoms.

Examples of the alkyl group include a methyl group, an ethyl group, a propyl group, an isopropyl group, an n-butyl group, an s-butyl group, an isobutyl group, a t-butyl group, an n-pentyl group, an n-hexyl group, an n-heptyl group, and an n-octyl group.

Examples of the aromatic hydrocarbon group include residues such as benzene, naphthalene, anthracene, phenanthrene, pyrene, biphenyl, terphenyl, and fluoranthene.

Examples of the heterocyclic group include residues such as imidazole, benzimidazole, pyrrole, furan, thiophene, benzothiophene, oxadiazoline, indoline, carbazole, pyridine, quinoline, isoquinoline, benzoquinone, pyralozine, imidazolidine, and piperidine.

Examples of the alkylamino group include groups each obtained by substituting a hydrogen atom of an amino group with the alkyl group.

Examples of the arylamino group include groups each obtained by substituting a hydrogen atom of an amino group with the aromatic hydrocarbon group.

The alkoxy group is represented as —OY′, and examples of Y′ include the groups described above as the examples of the alkyl group.

Examples of the halogenated alkoxy group include groups each obtained by substituting a hydrogen atom of the alkoxy group with the halogen atom.

The aryloxy group is represented as —OY″, and examples of Y″ include the groups described above as the examples of the aromatic hydrocarbon group.

Examples of the halogenated alkyl group include groups each obtained by substituting a hydrogen atom of the alkyl group with the halogen atom.

Examples of the alkenyl group include a vinyl group, an allyl group, a 2-butenyl group, and a 3-pentenyl group.

Examples of the alkynyl group include an ethinyl group and a methylethinyl group.

Examples of the cycloalkyl group include a cyclopropyl group, a cyclobutyl group, a cyclopentyl group, and a cyclohexyl group.

In addition, examples of a substituent for each of those groups include examples similar to those described for Rings A and B.

In the general formula (I), X represents a monovalent ligand containing an atom belonging to any one of Groups 14 to 17 in the periodic table.

Examples of the atom belonging to any one of Groups 14 to 17 in the periodic table to be incorporated into X include carbon (C), nitrogen (N), oxygen (O), fluorine (F), silicon (Si), phosphorus (P), sulfur (S), chlorine (Cl), germanium (Ge), arsenic (As), selenium (Se), bromine (Br), andiodine (I) atoms. Of those, carbon, nitrogen, chlorine, bromine, and iodine atoms are preferred.

In addition, examples of the ligand represented by X include a cyano group, a chlorine atom, a bromine atom, an iodine atom, an alkoxy group, a hydrogen atom, Si(R′)₃ (R′ represents a group similar to that represented by R below), a substituted or unsubstituted phenyl group, and the following groups.

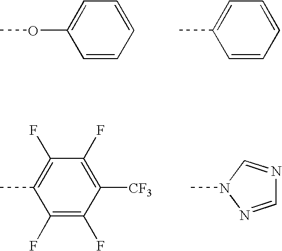

Preferred examples of the ligand include a cyano group, a chlorine atom, a bromine atom, an iodine atom, an alkoxy group, a hydrogen atom, Si(R′)₃, and a substituted phenyl group.

In the general formula (I), R represents a hydrogen atom, a cyano group, a nitro group, a halogen atom, an alkyl group which has 1 to 12 carbon atoms and which may have a substituent, an alkylamino group which has 1 to 12 carbon atoms and which may have a substituent, an arylamino group which has 6 to 20 carbon atoms and which may have a substituent, an alkoxy group which has 1 to 12 carbon atoms and which may have a substituent, a halogenated alkoxy group which has 1 to 12 carbon atoms and which may have a substituent, an aryloxy group which has 6 to 20 carbon atoms and which may have a substituent, an aromatic hydrocarbon group which has 6 to 20 carbon atoms and which may have a substituent, a heterocyclic group which has 2 to 20 carbon atoms and which may have a substituent, a halogenated alkyl group which has 1 to 12 carbon atoms and which may have a substituent, an alkenyl group which has 2 to 12 carbon atoms and which may have a substituent, an alkynyl group which has 2 to 12 carbon atoms and which may have a substituent, or a cycloalkyl group which has 3 to 20 carbon atoms and which may have a substituent. Specific examples of each of those groups may be the same as is represented by L and Z.

Of those, a hydrogen atom, an isopropyl group, a t-butyl group, or a methyl group is preferred.

In addition, the number of R is specifically 0 to 4, multiple Rs may be identical to or different from each other, and adjacent Rs may be bonded to each other to form a cyclic structure.

Examples of the cyclic structure include: cycloalkanes (such as cyclopropane, cyclobutane, cyclopropane cyclohexane, and cycloheptane); aromatic hydrocarbon rings (such as benzene, naphthalene, anthracene, phenanthrene, pyrene, biphenyl, terphenyl, and fluoranthene); and heterocyclic rings (such as imidazole, benzimidazole, pyrrole, furan, thiophene, benzothiophene, oxadiazoline, diphenylanthracene, indoline, carbazole, pyridine, quinoline, isoquinoline, benzoquinone, pyralozine, imidazolidine, and piperidine).

In addition, examples of a substituent for each of those groups include examples similar to those described above.

The metal complex compound of the present invention is such that at least one of the tridentate chelate ligand and the bidentate chelate ligand in the general formula (I) contains an electron withdrawing group. In addition, each of both the tridentate chelate ligand and the bidentate chelate ligand preferably contains an electron withdrawing group because light having an additionally short wavelength can be emitted, or an additionally high quantum yield can be obtained.

Examples of the electron withdrawing group include a halogen atom (such as a fluorine, chlorine, bromine, or iodine atom), a cyano group, a nitro group, a halogen atom-containing alkyl or ester group, and an aldehyde group. Of those, a halogen atom or a halogen atom-containing alkyl group is preferred.

The metal complex compound of the present invention can emit blue light having an additionally short wavelength because the introduction of the electron withdrawing group as described above acts to stabilize the HOMO of the metal complex compound so that an energy difference between the HOMO and LUMO of the metal complex compound may enlarge. The action becomes particularly strong when a fluorine atom is used as the electron withdrawing group. In addition, a metal complex compound into which a fluorine atom is introduced is efficient for the production of an organic EL device by vapor deposition because the compound is excellent in sublimation property.

In addition, the metal complex compound of the present invention has improved stability and an increased quantum yield because the tridentate chelate ligand has a pyridine ring as an essential structure.

In the general formula (I), the tridentate chelate ligand is preferably represented by the following general formula (1) or (2), and is preferably a compound represented by any one of the following general formulae (3) to (16).

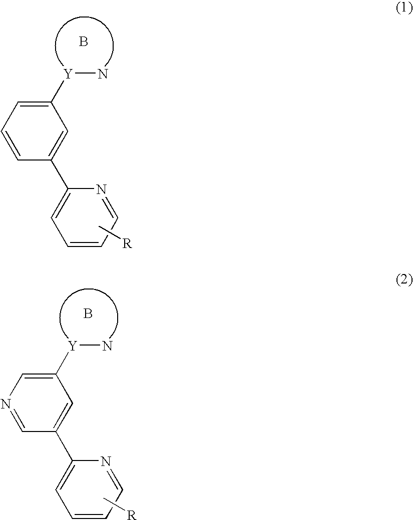

(In the formulae, Ring B, Y, and R each have the same meaning as that described above.)

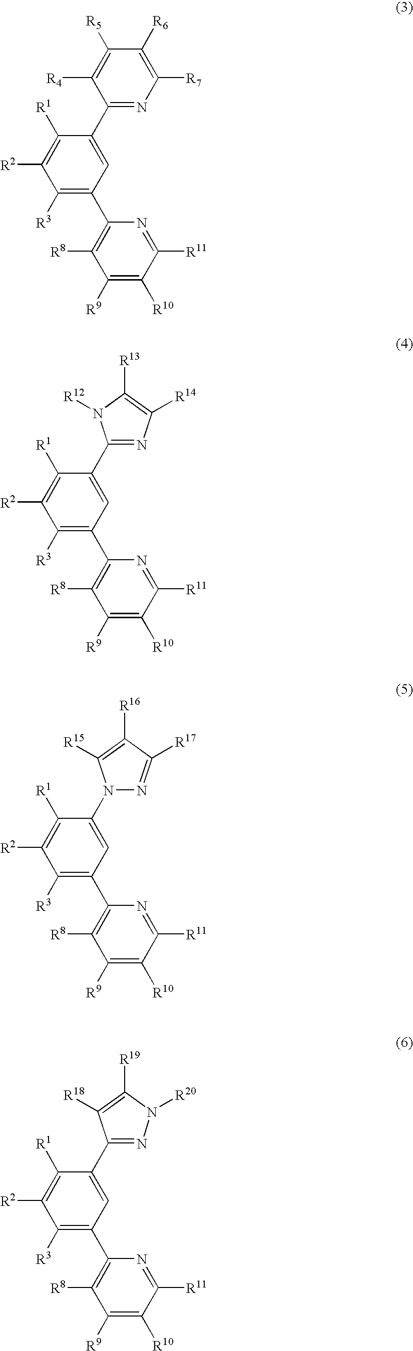

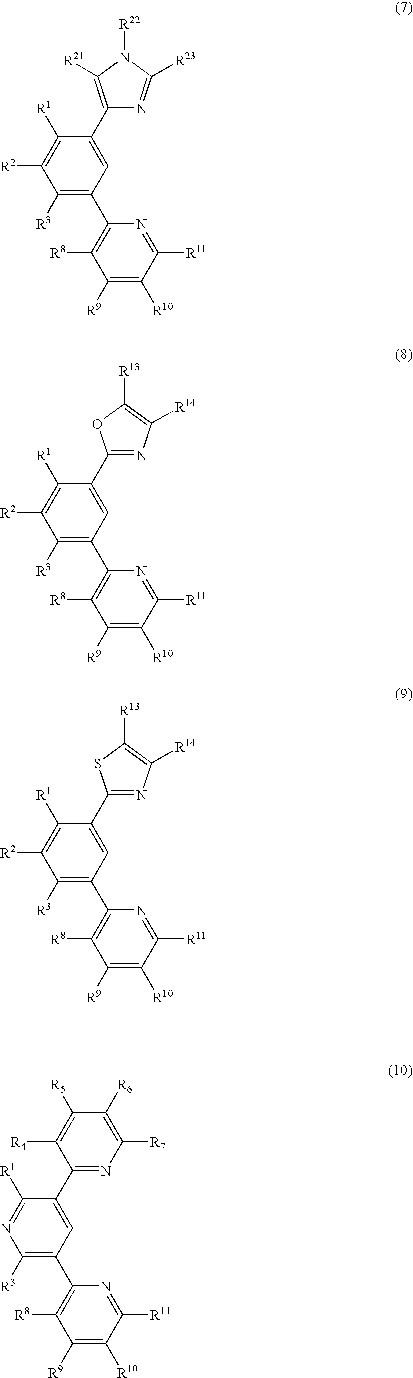

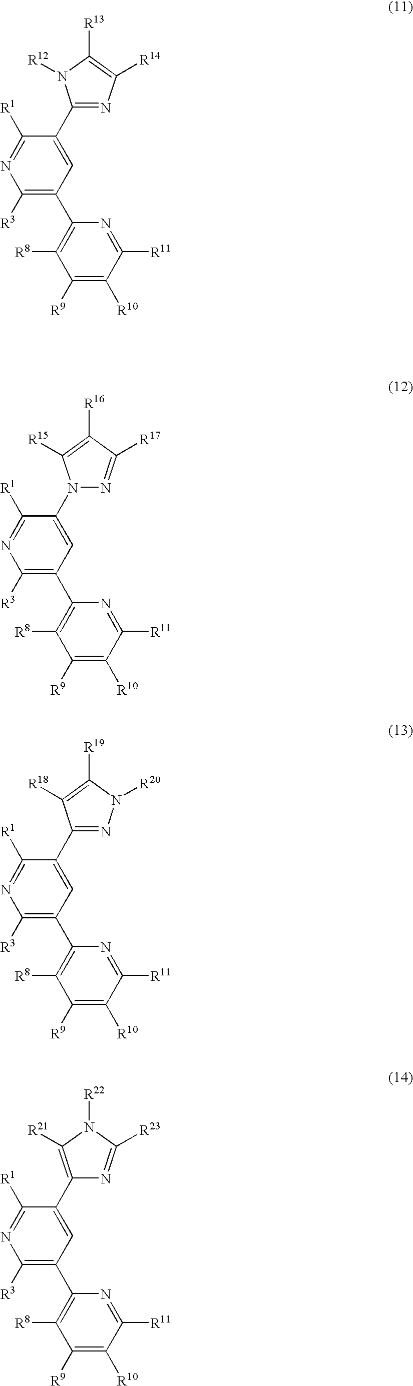

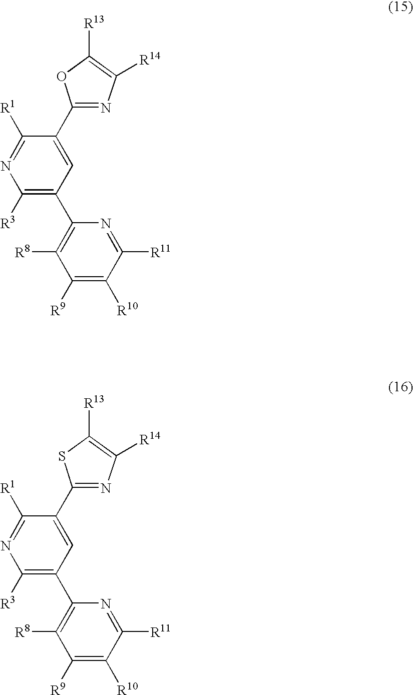

(In the formulae, R¹ to R²³ each have the same meaning as that of R described above, adjacent groups of R¹ to R²³ may be bonded to each other to form a cyclic structure, and specific examples of each of R¹ to R²³ include examples similar to those of R.)

Further, examples of the tridentate chelate ligand include the following ligands.

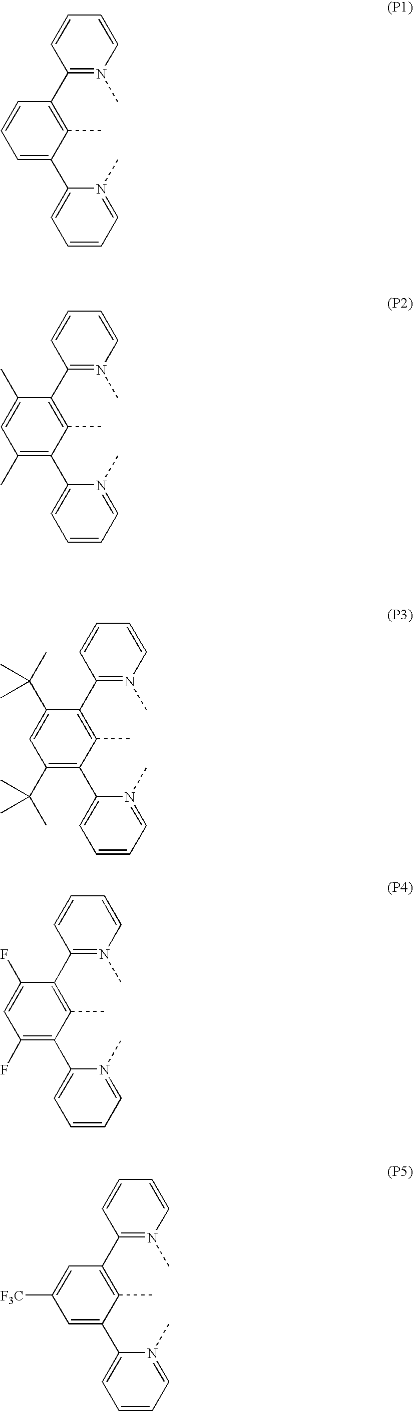

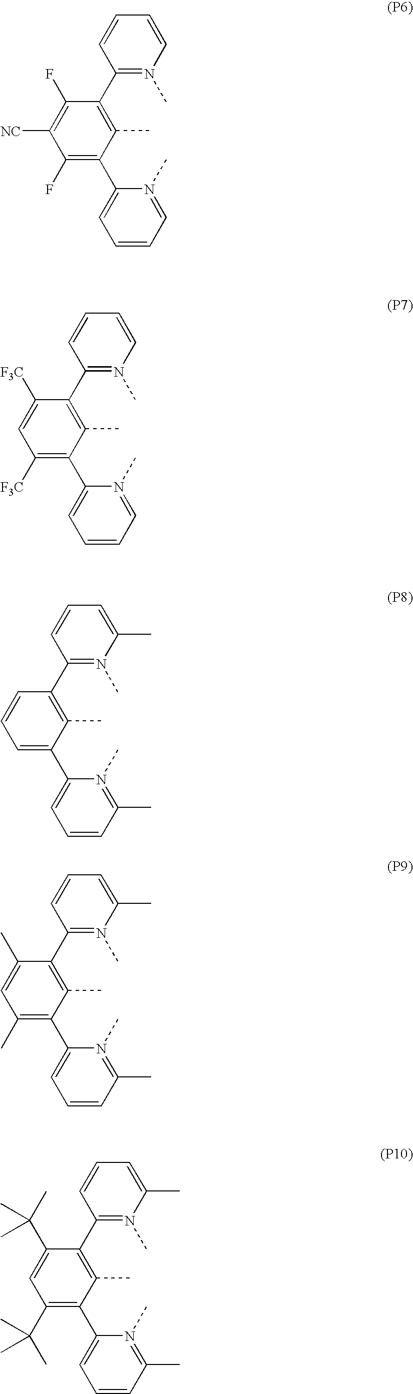

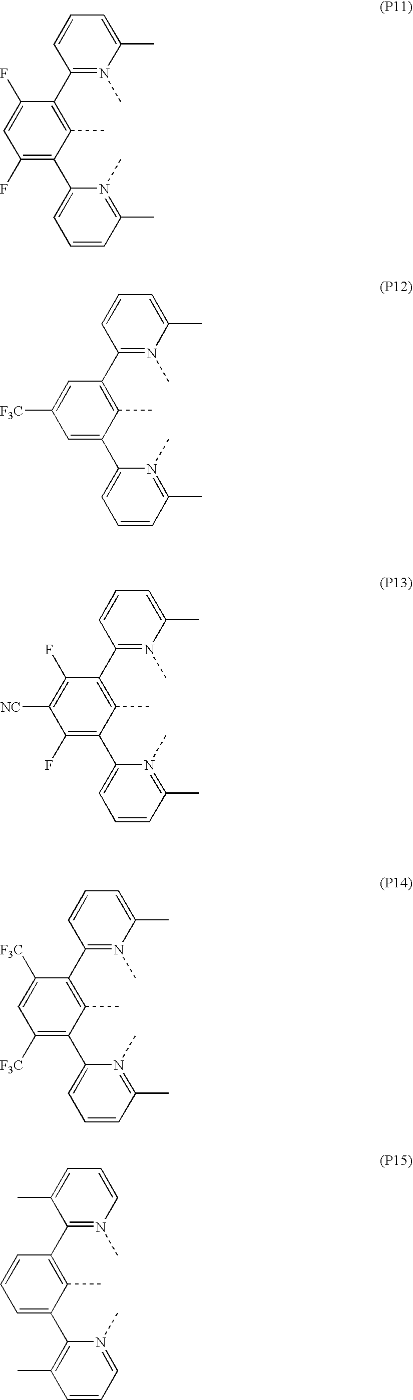

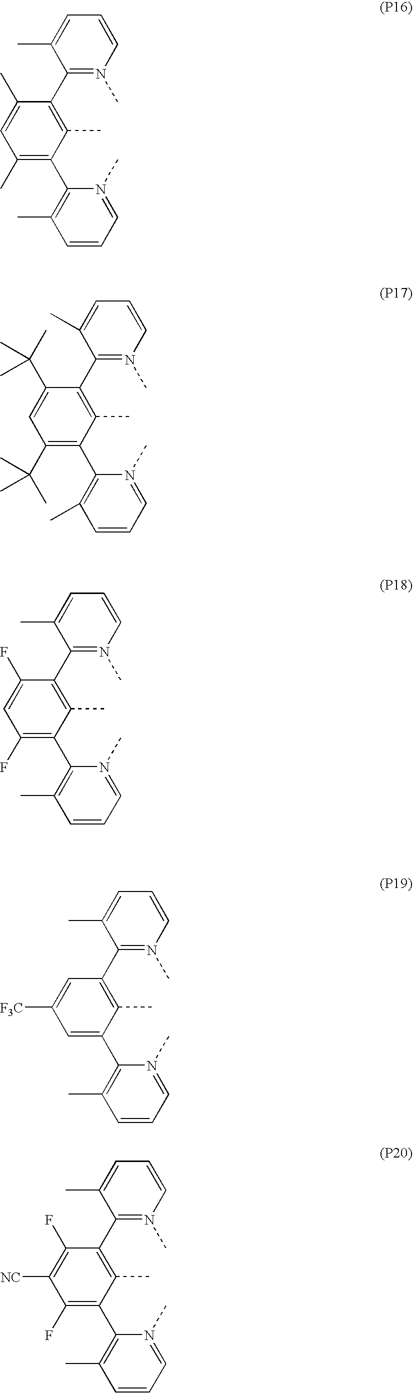

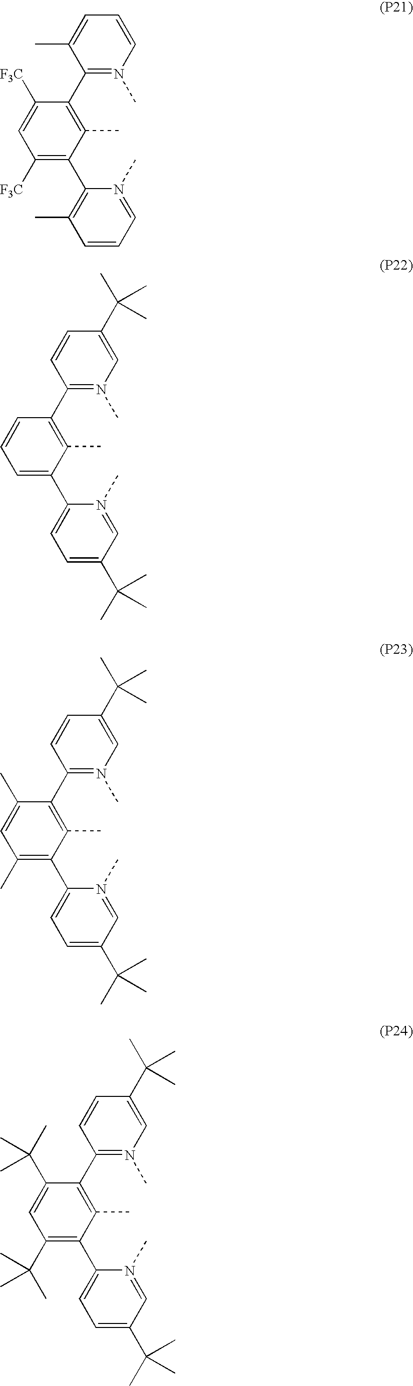

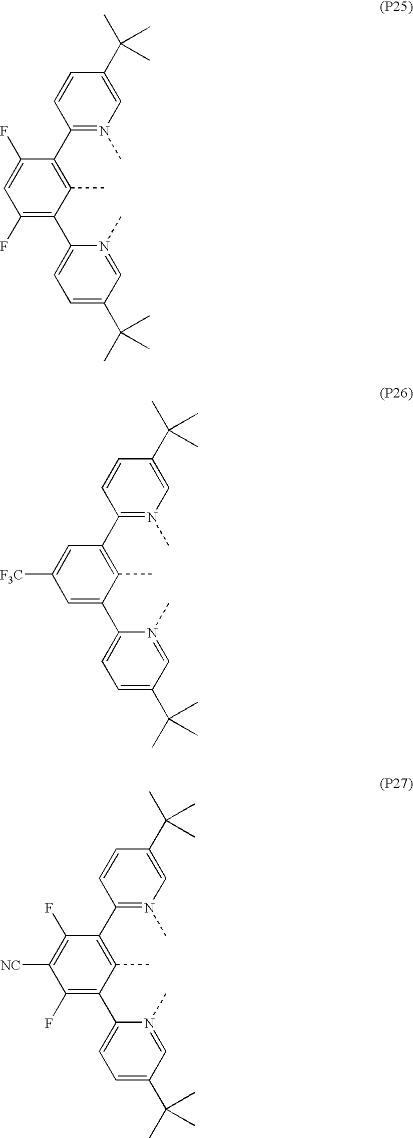

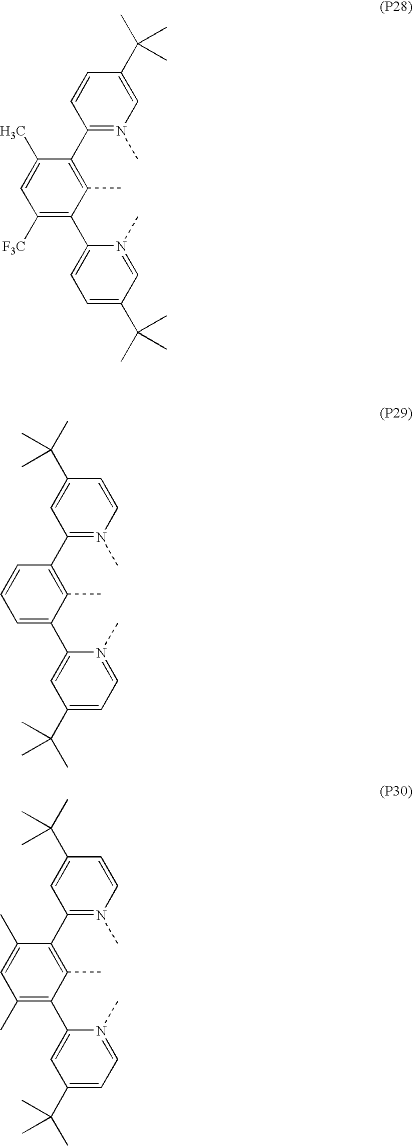

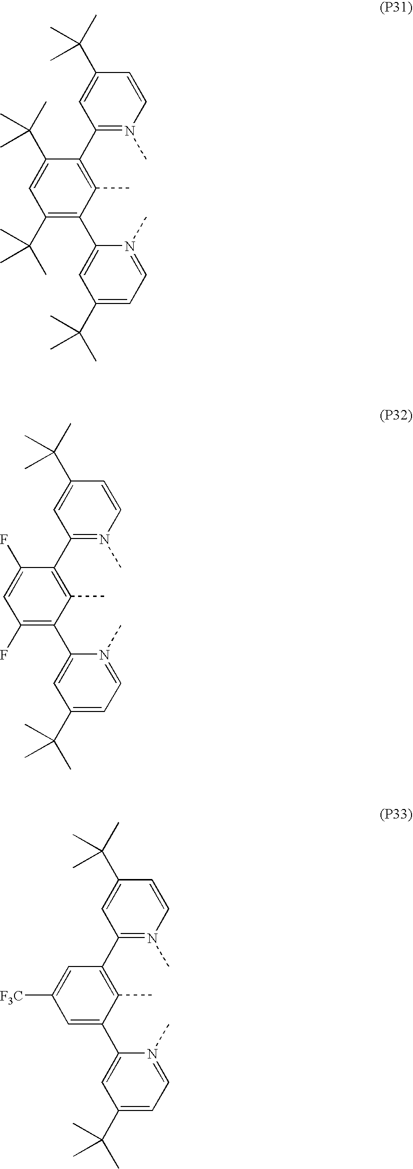

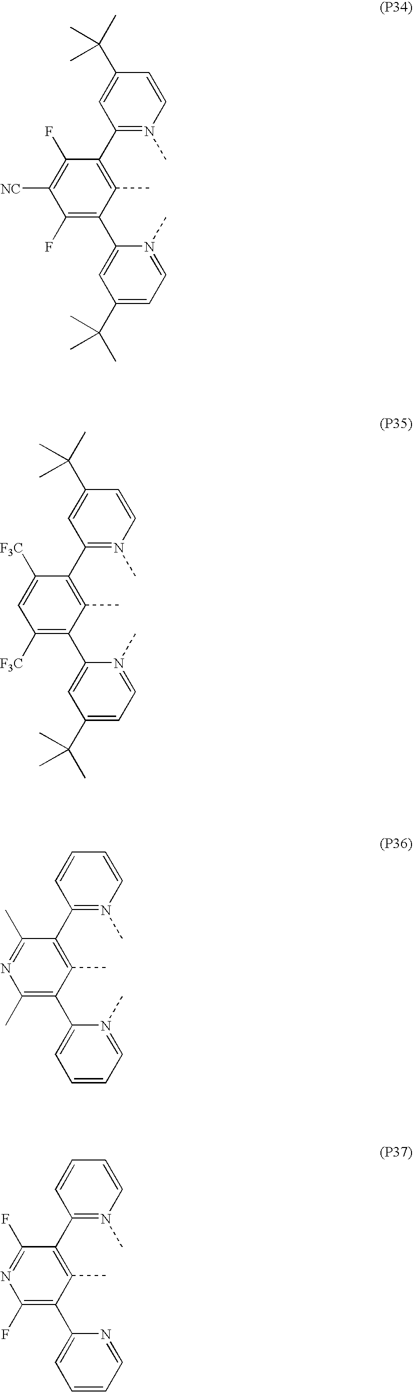

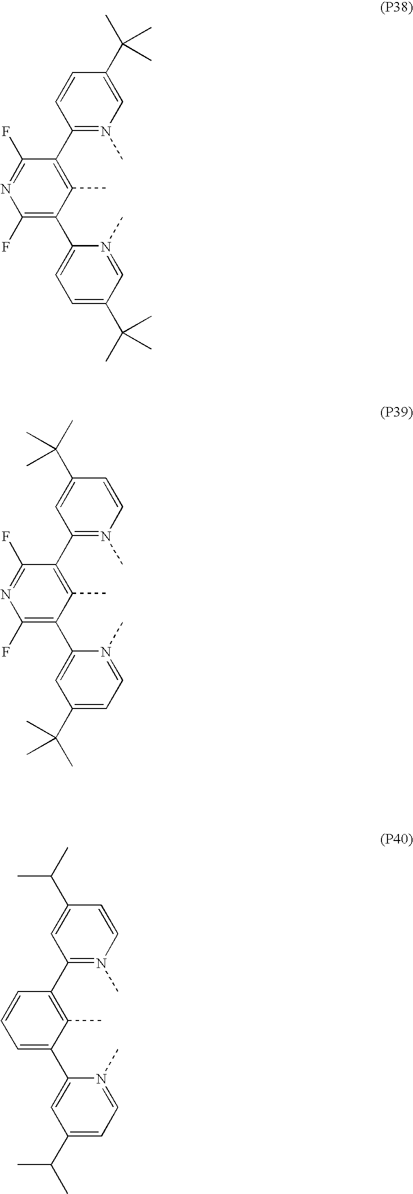

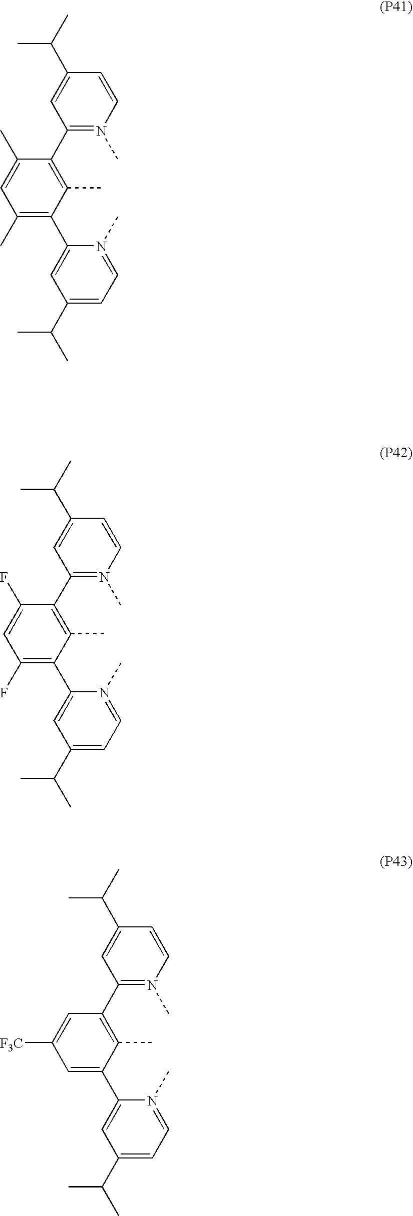

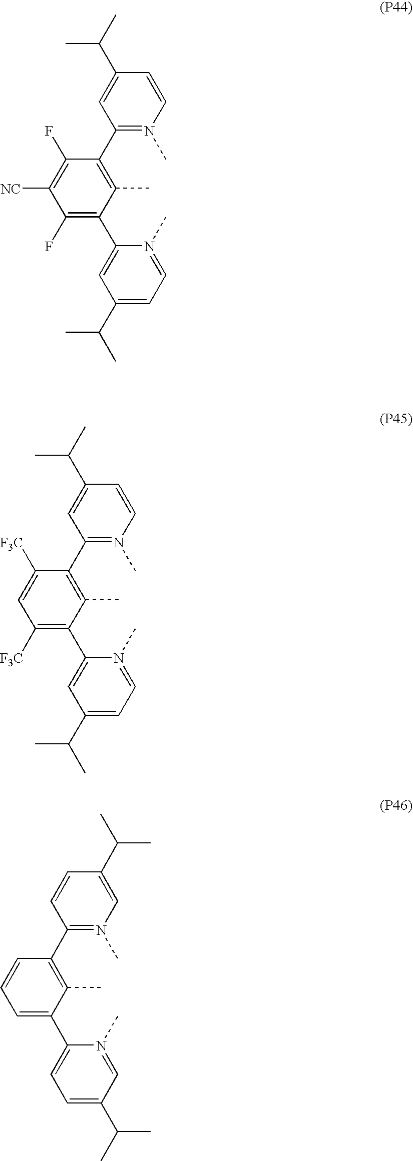

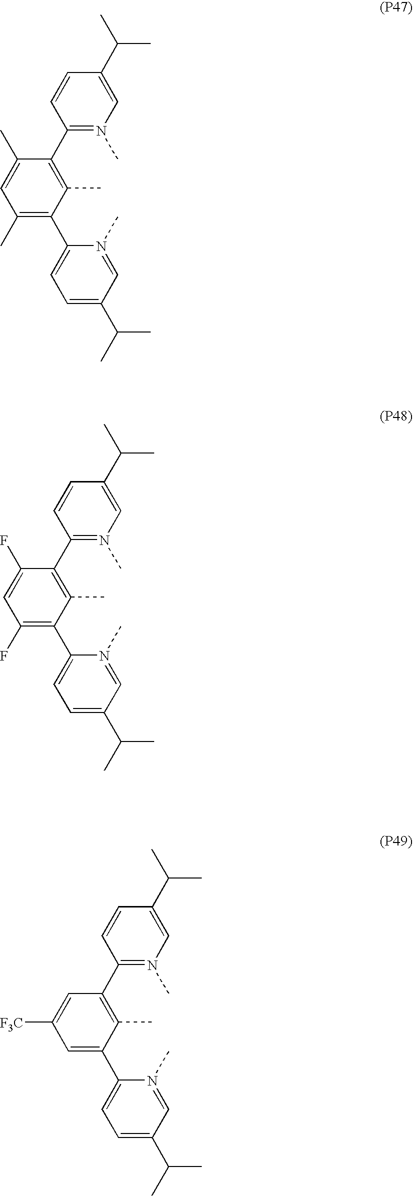

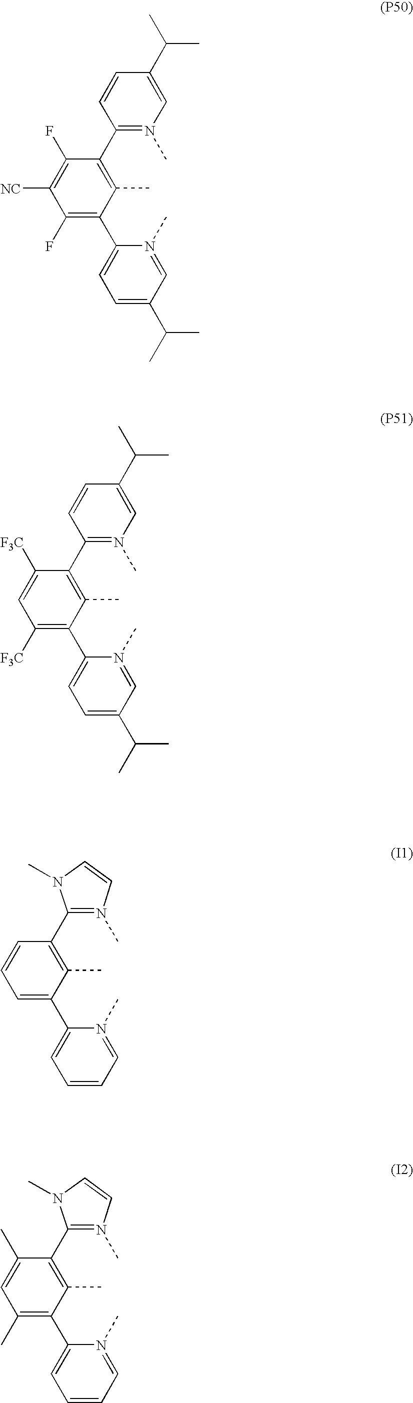

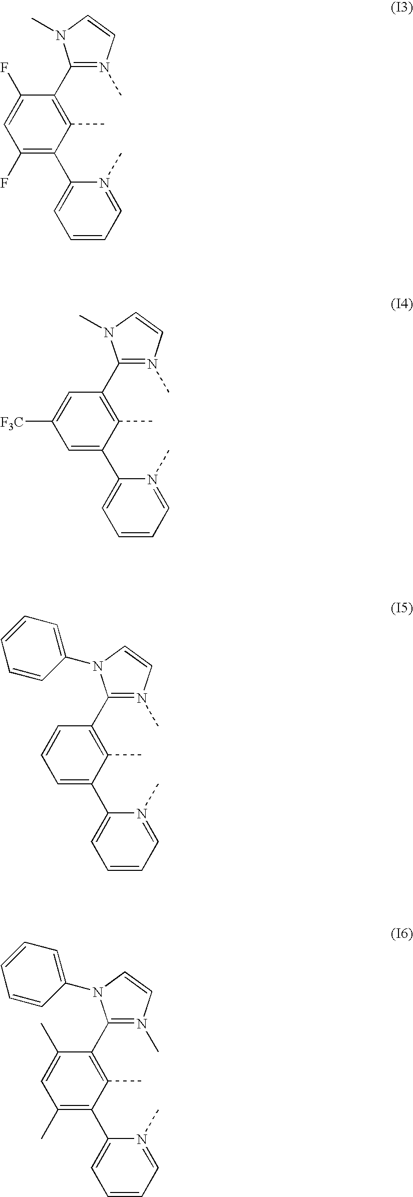

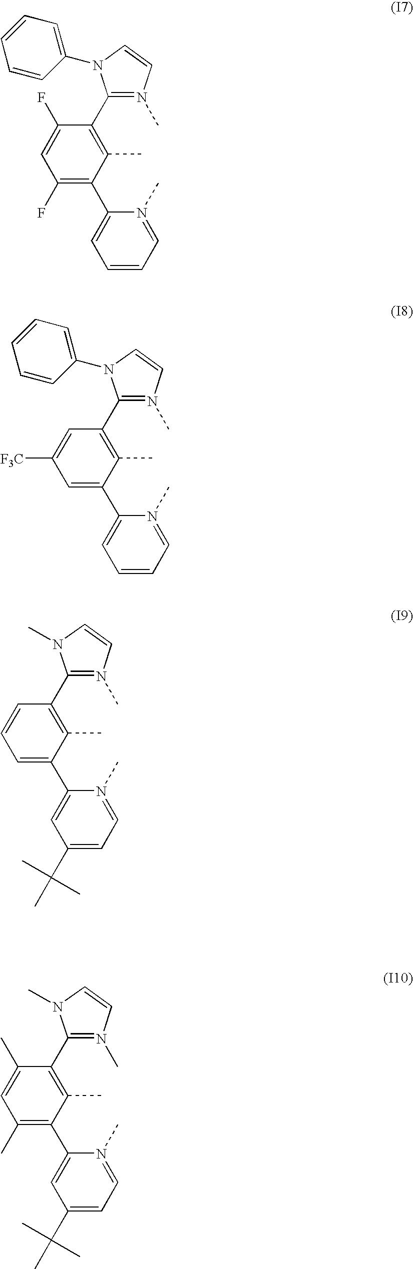

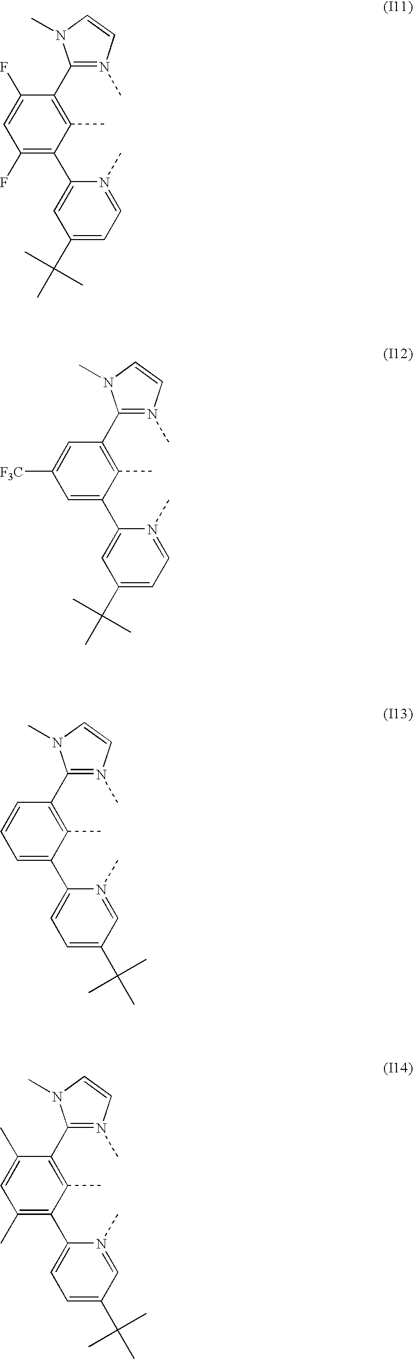

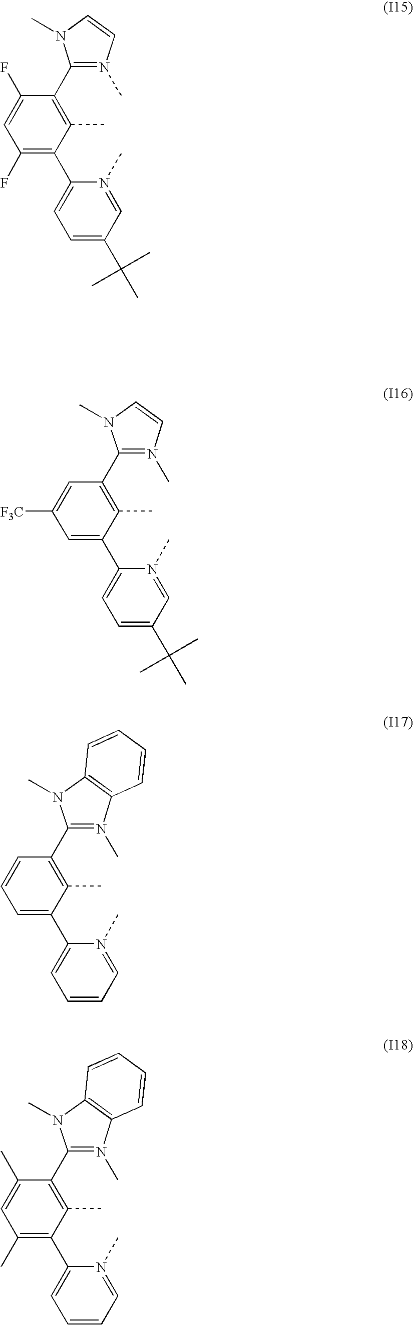

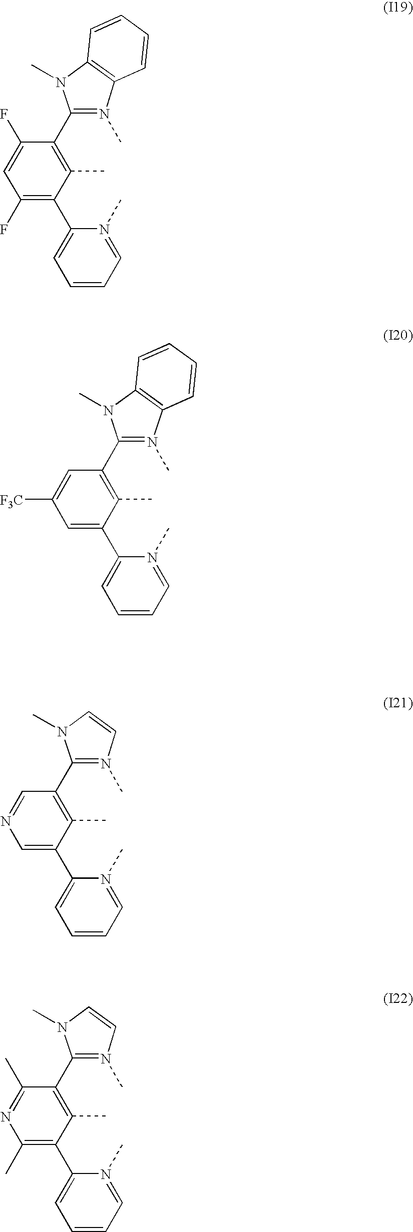

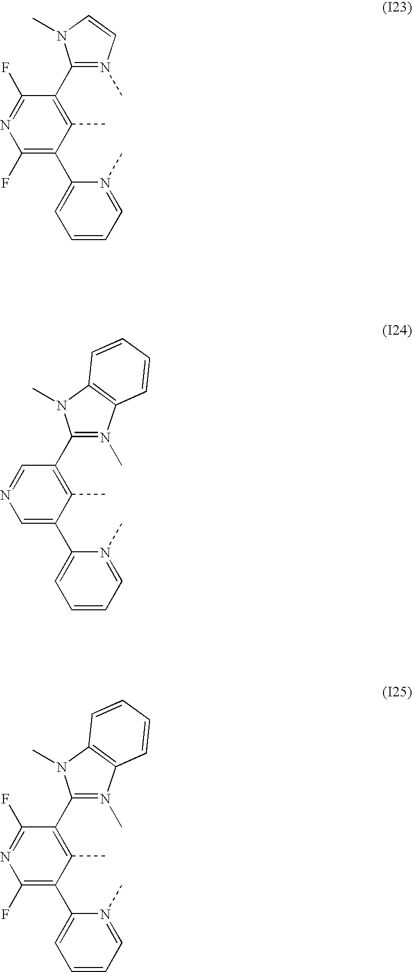

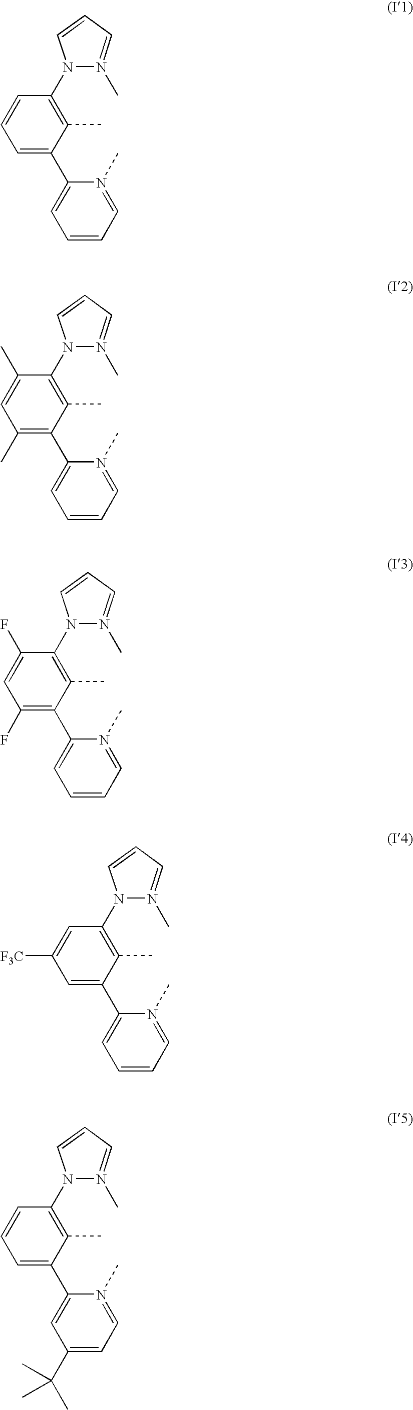

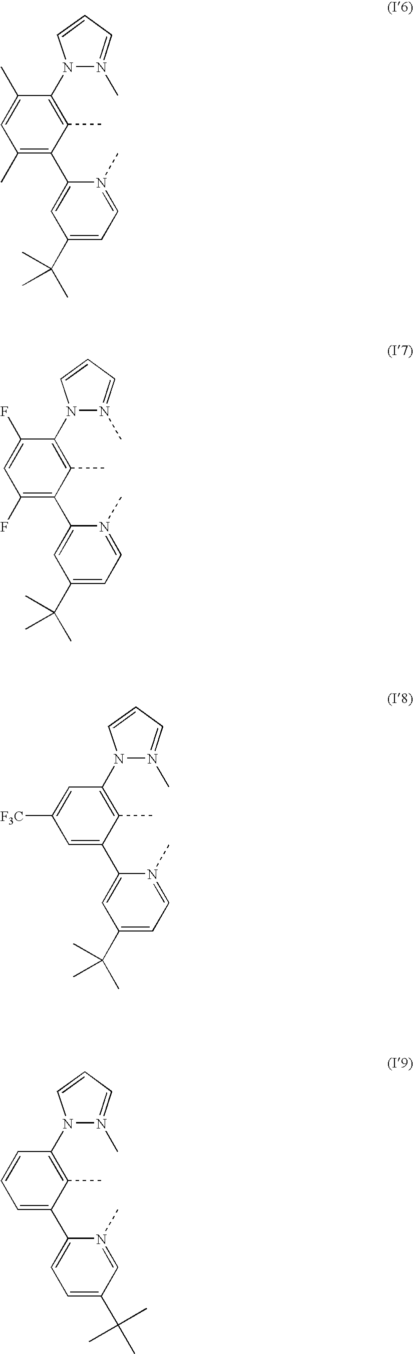

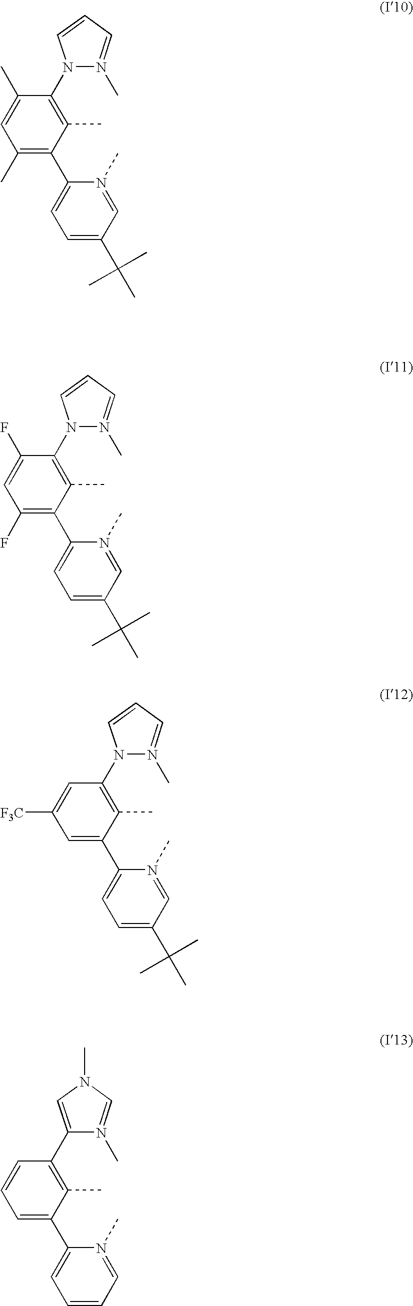

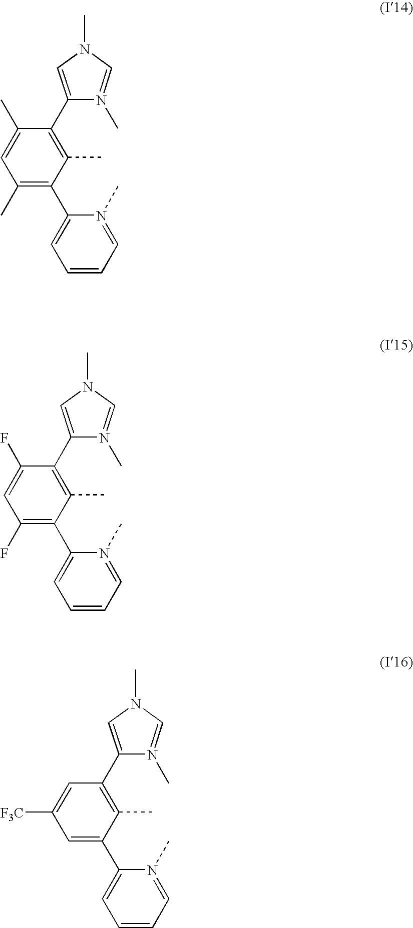

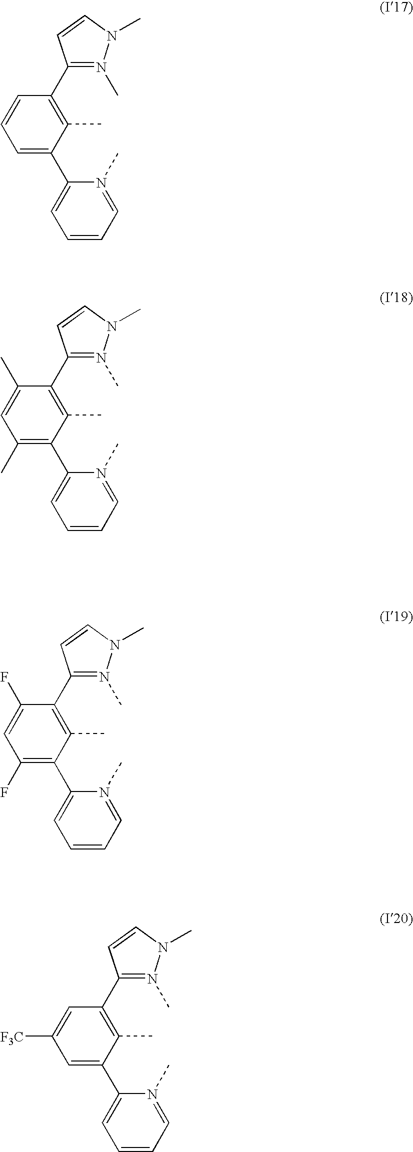

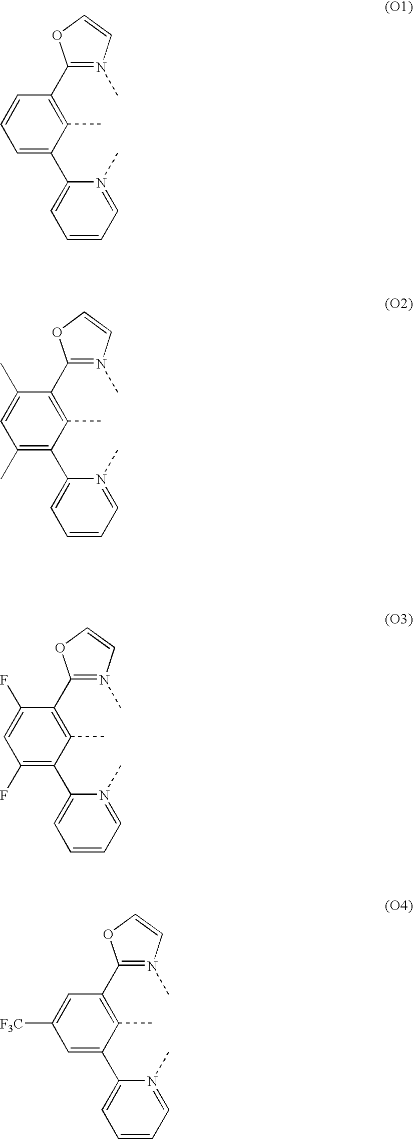

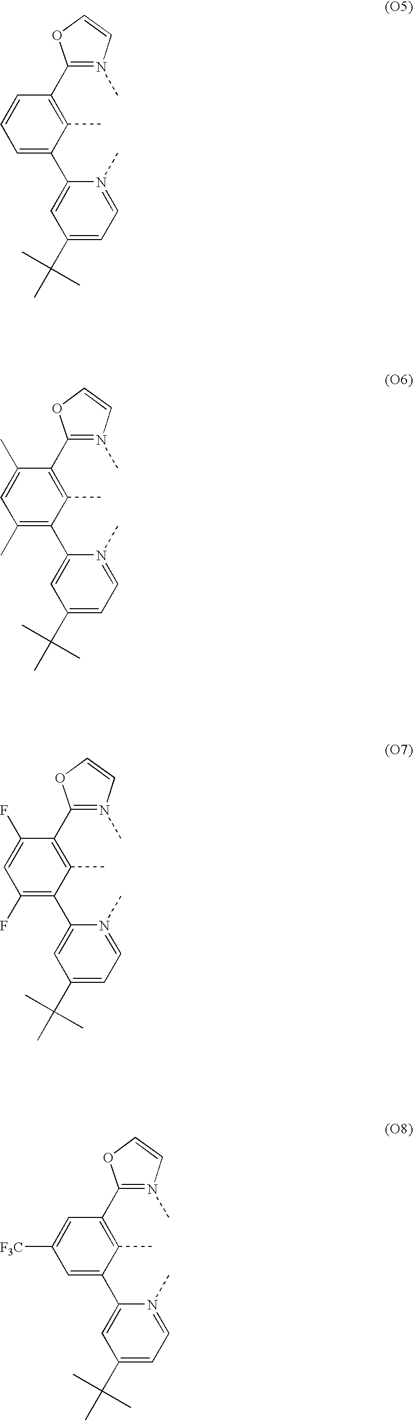

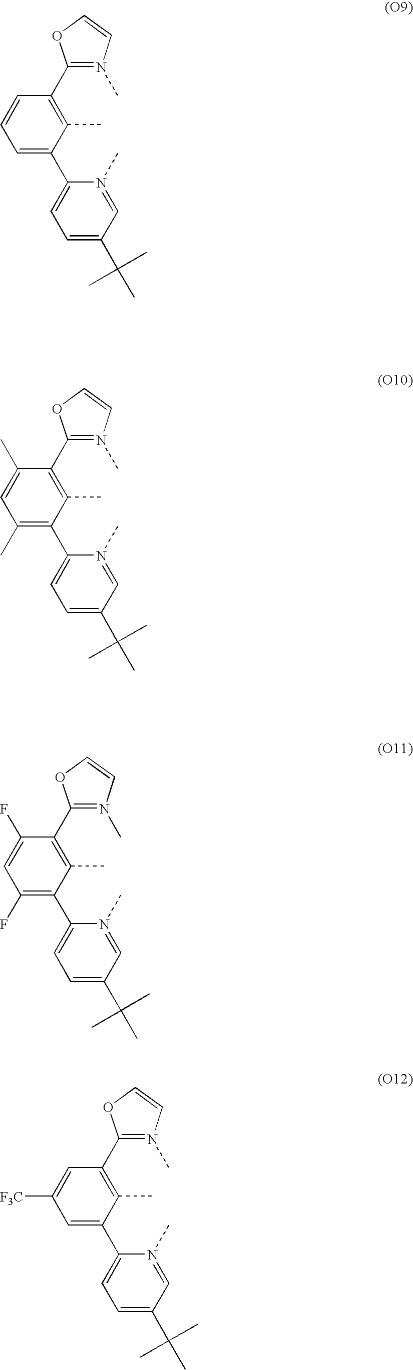

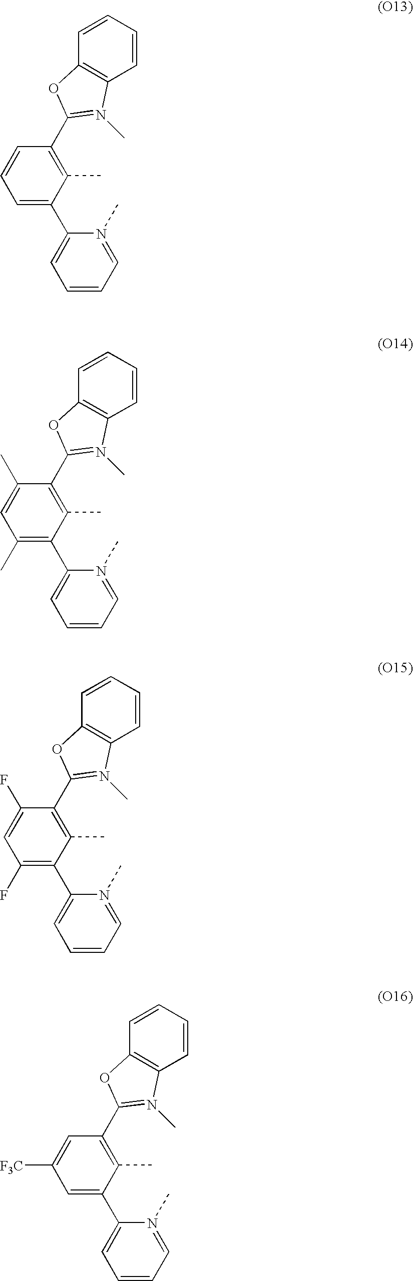

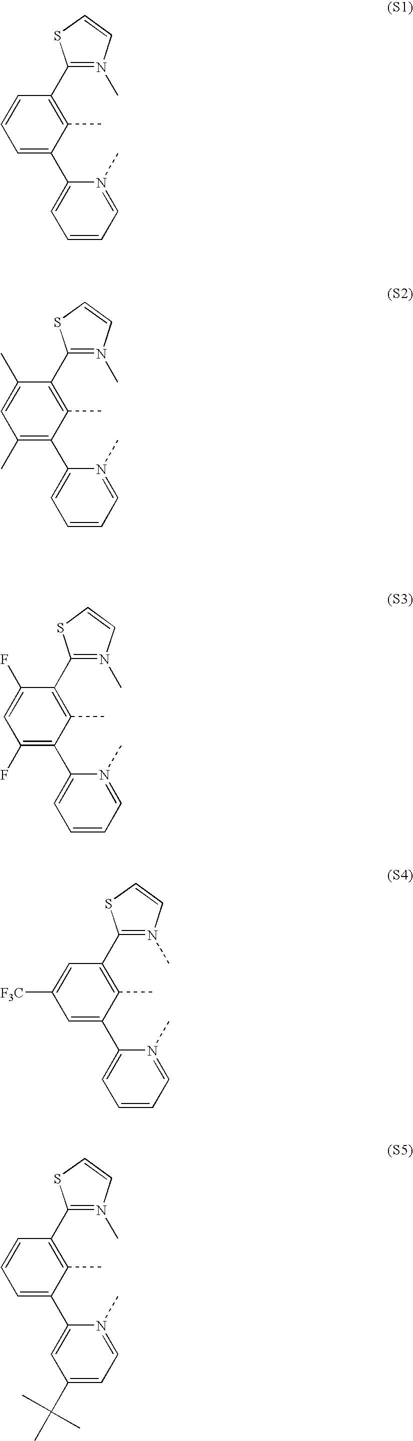

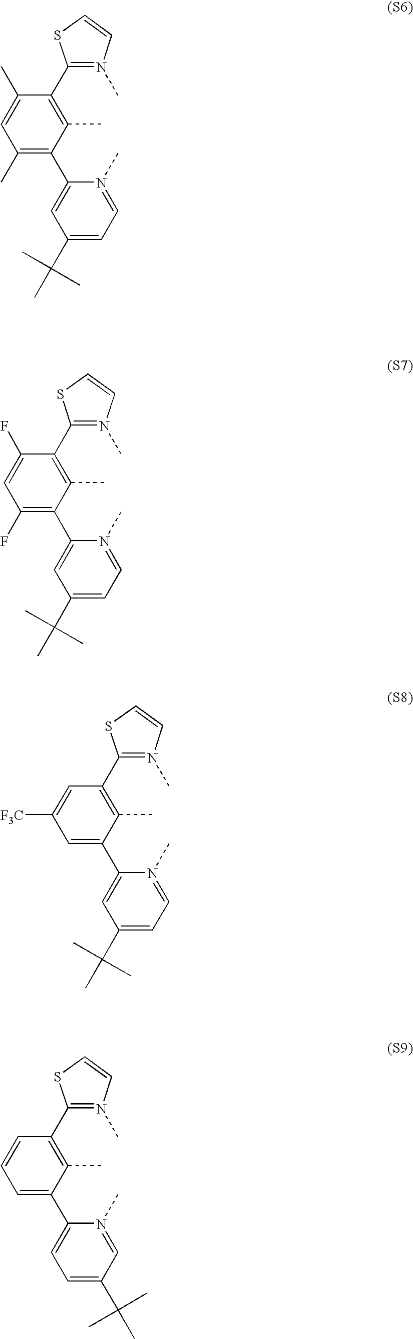

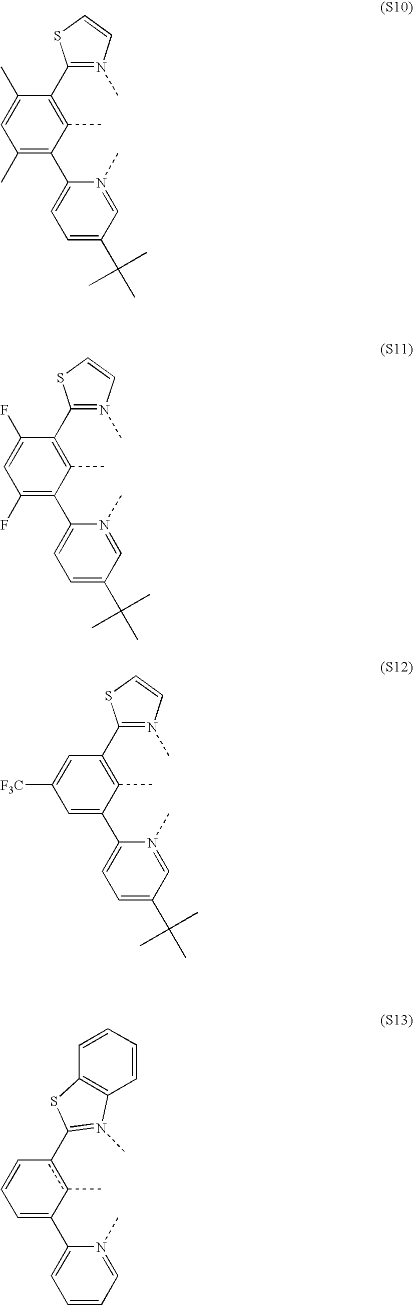

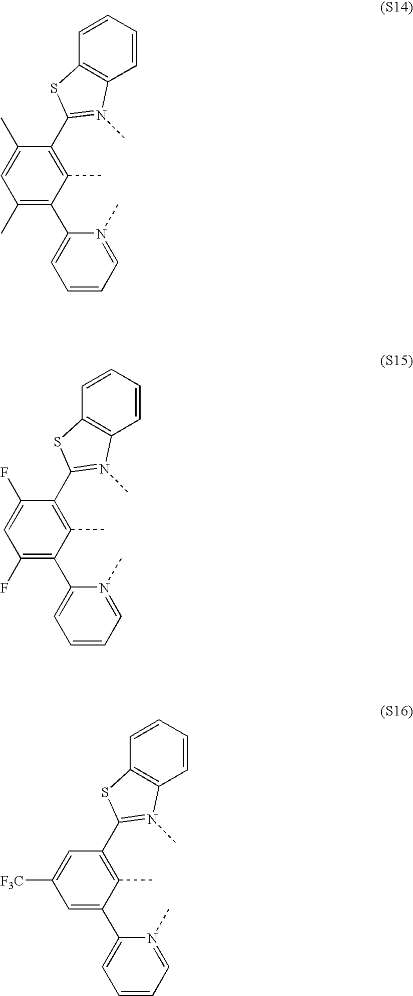

In the general formula (I), the bidentate chelate ligand formed of L-Z is preferably a compound represented by any one of the following general formulae (17) to (22).

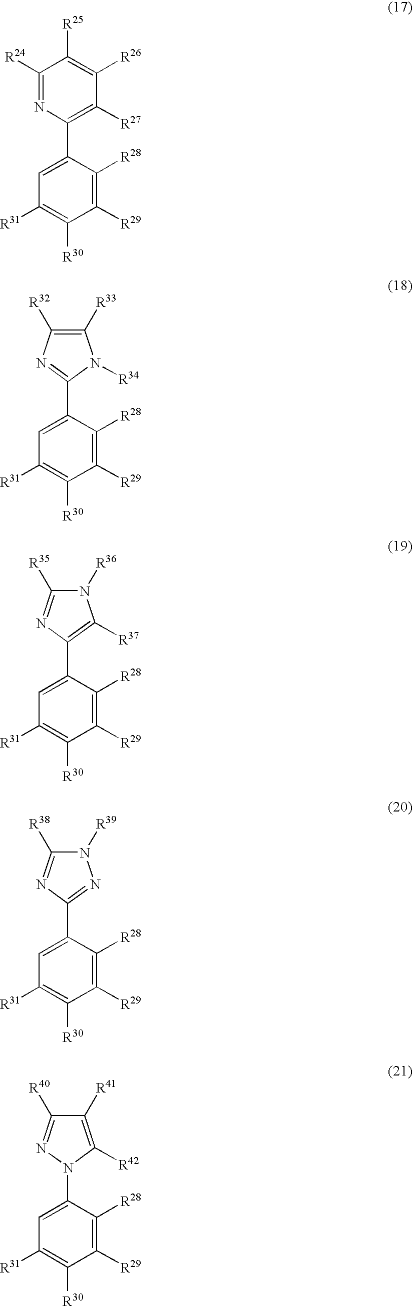

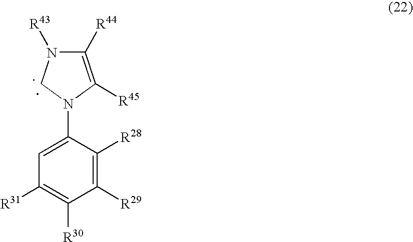

(In the formulae, R²⁴ to R⁴⁵ each have the same meaning as that of R described above, adjacent groups of R²⁴ to R⁴⁵ may be bonded to each other to form a cyclic structure, and specific examples of each of R²⁴ to R⁴⁵ include examples similar to those of R.)

Further, examples of the bidentate chelate ligand include the following ligands.

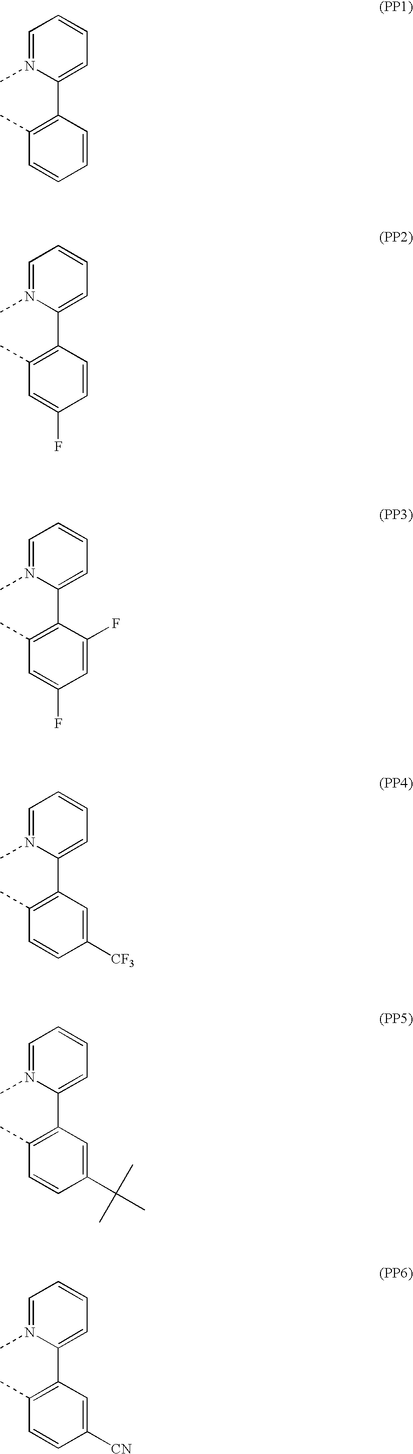

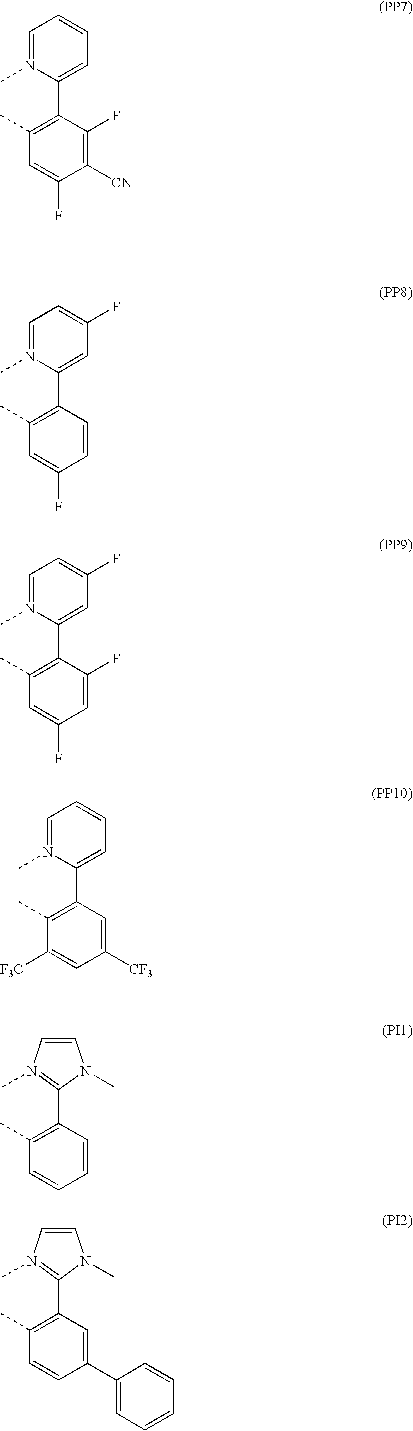

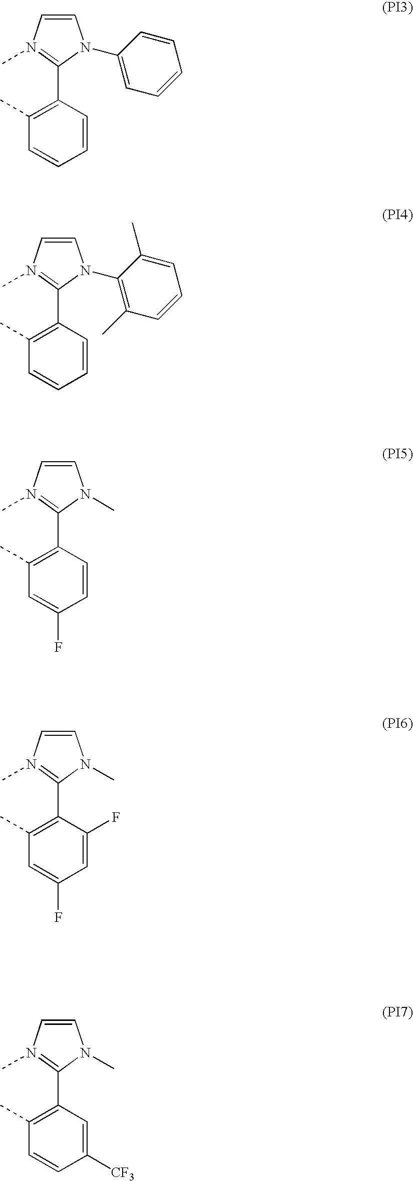

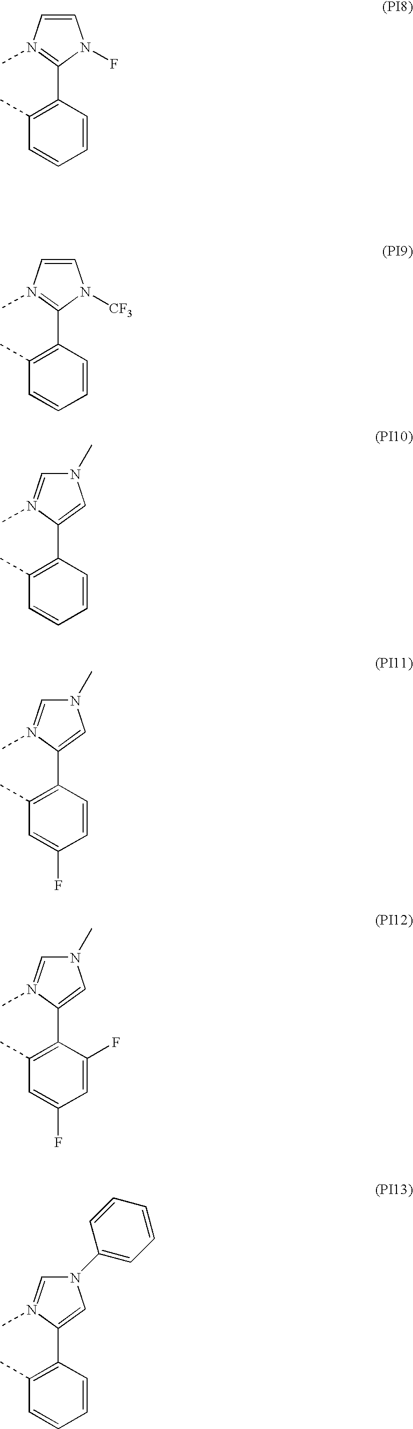

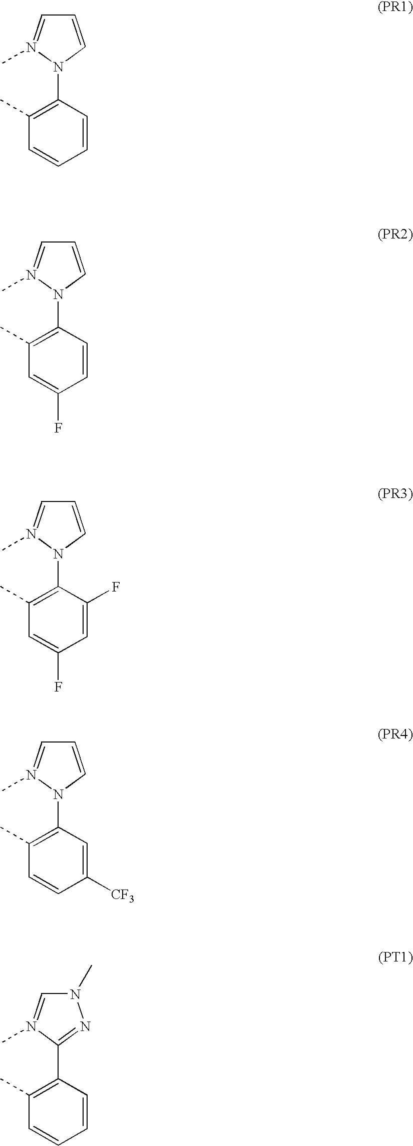

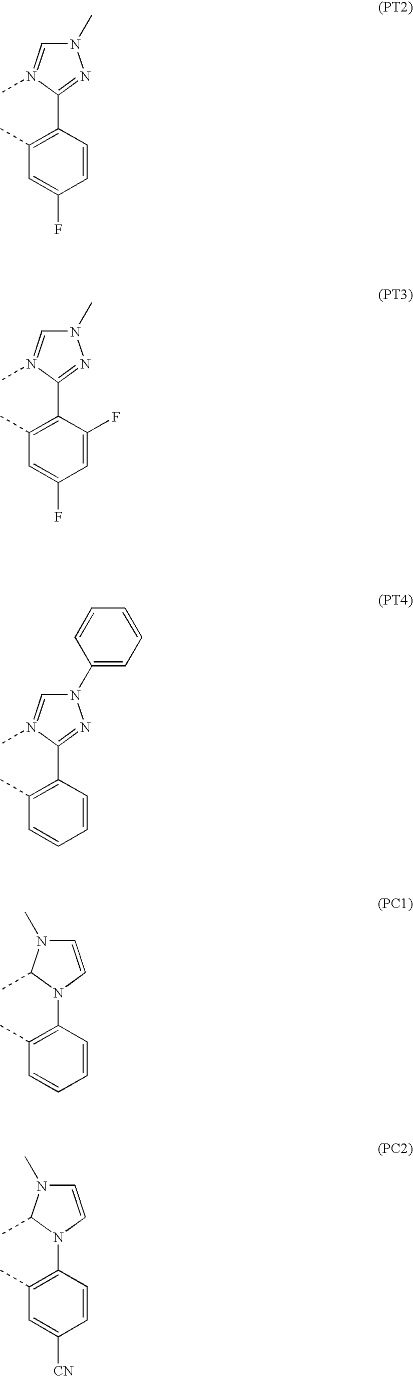

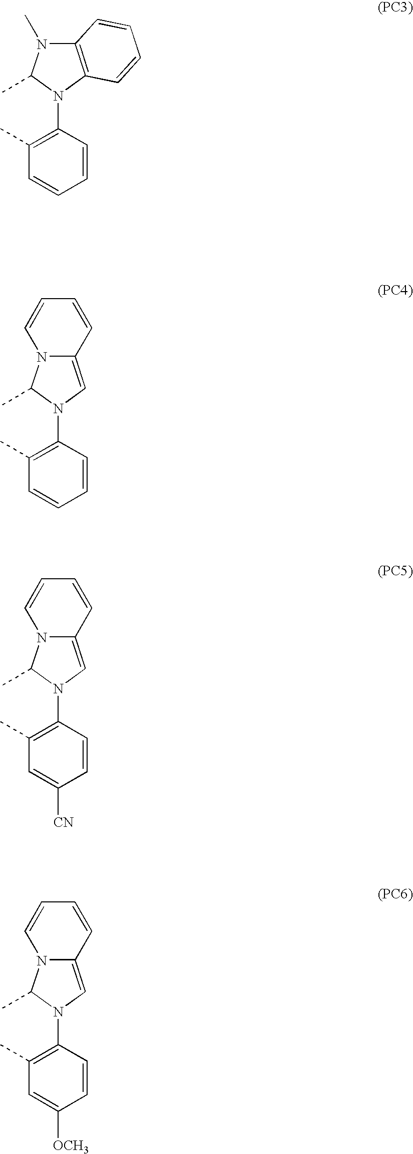

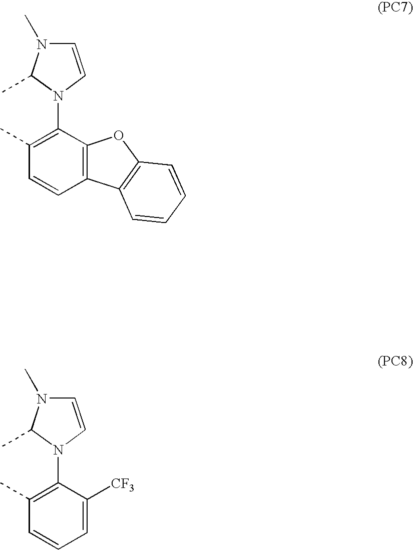

The metal complex compound of the present invention is preferably represented by any one of the following general formulae (I-1) to (I-12) and (I-13) to (I-24).

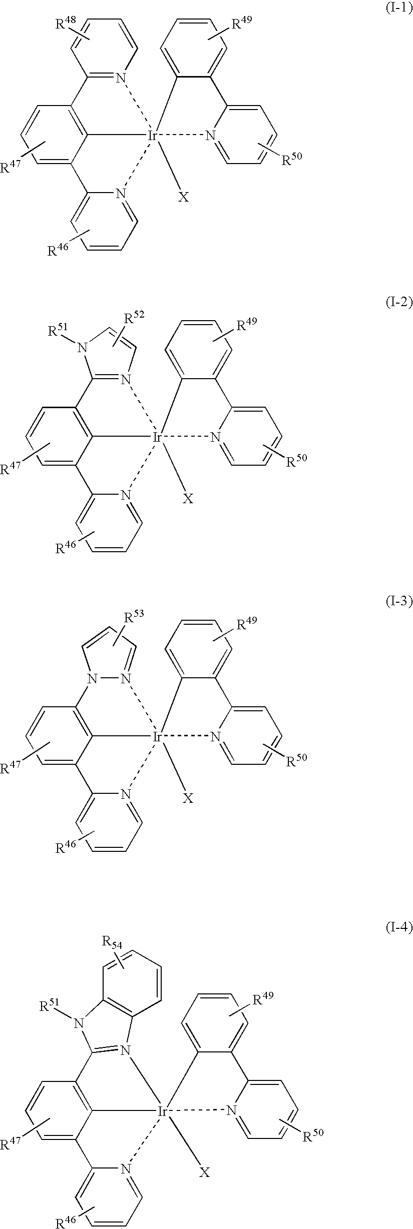

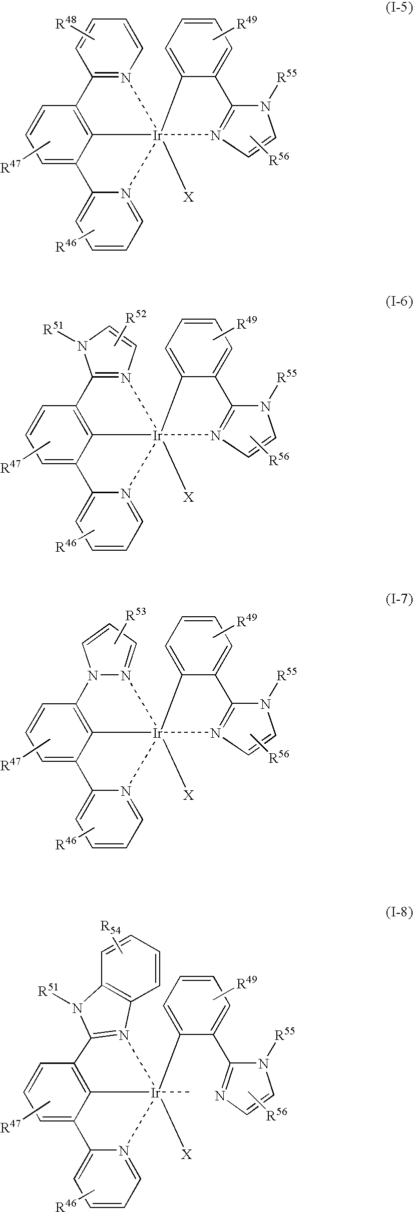

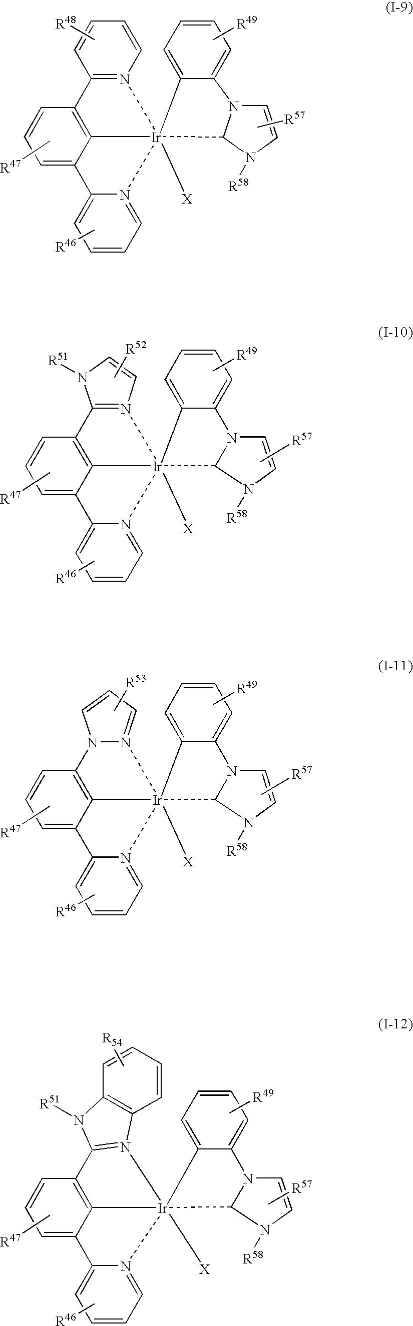

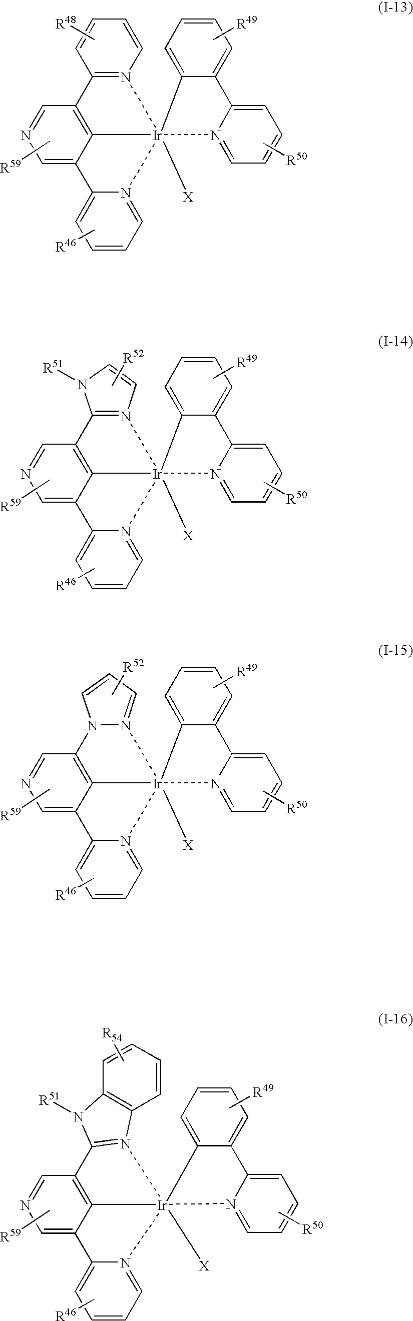

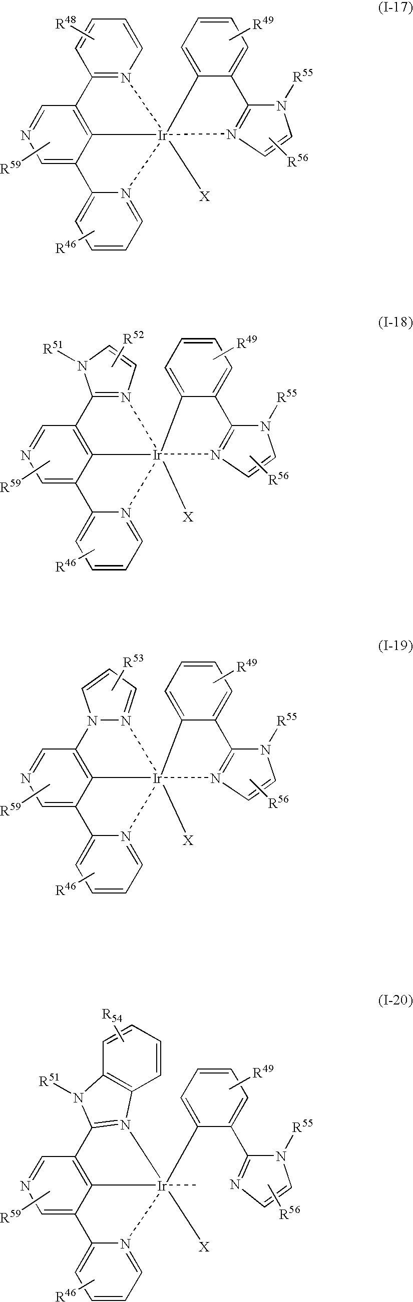

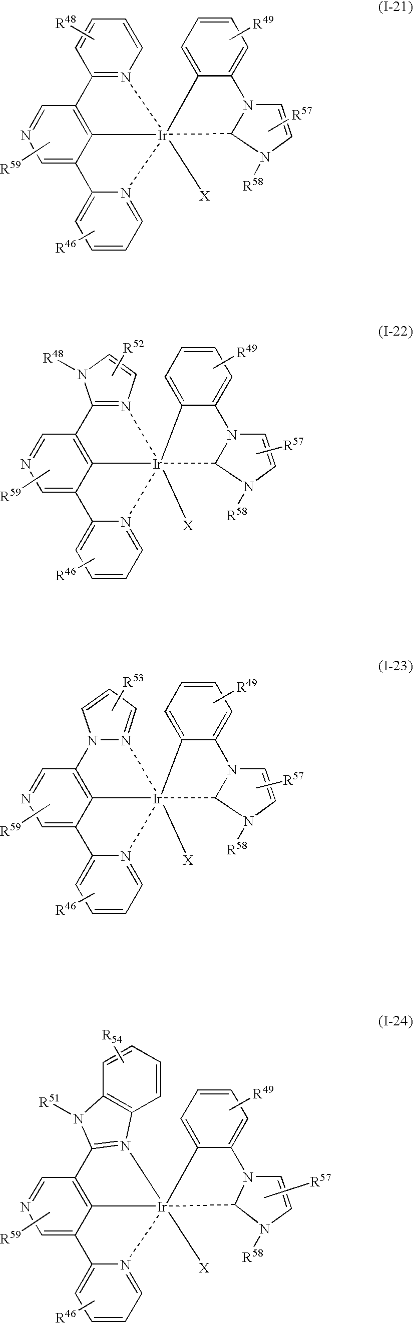

(In the formulae (I-1) to (I-12), R⁴⁶ to R⁵⁸ each have the same meaning as that of R described above, the number of each of R⁴⁶ to R⁵⁸ may be two or more, and, in this case, R⁴⁶s, R⁴⁷s, R⁴⁸s, R⁴⁹s, R⁵⁰s, R⁵¹s, R⁵²s, R⁵³s, R⁵⁴s, R⁵⁵s, R⁵⁶s, R⁵⁷s, or R⁵⁸s may be identical to or different from each other, adjacent groups of R⁴⁶ to R⁵⁸ may be bonded to each other to form a cyclic structure, and specific examples of each of R⁴⁶ to R⁵⁸ include examples similar to those of R, provided that one or more of R⁴⁶ to R⁵⁸ must each represent an electron withdrawing group.

In the formulae (I-13) to (I-24), R⁴⁶ and R⁴⁸ to R⁵⁹ each have the same meaning as that of R described above, the number of each of R⁴⁶ and R⁴⁸ to R⁵⁹ may be two or more, and, in this case, R⁴⁶s, R⁴⁸s, R⁴⁹s, R⁵⁰s, R⁵¹s, R⁵²s, R⁵³s, R⁵⁴s, R⁵⁵s, R⁵⁶s, R⁵⁷s, R⁵⁸s, or R⁵⁹s may be identical to or different from each other, adjacent groups of R⁴⁶ and R⁴⁸ to R⁵⁹ may be bonded to each other to form a cyclic structure, and specific examples of each of R⁴⁶ and R⁴⁸ to R⁵⁹ include examples similar to those of R, provided that one or more of R⁴⁸ to R⁵⁹ must each represent an electron withdrawing group.)

In addition, preferred specific examples of the metal complex compound of the present invention include, but not limited to, the following exemplified compounds each formed of a combination of partial structures shown in Table 1 below.

TABLE 1

| | Tridentate ligand | | |
|---|---|---|---|
| Compound No. | including Rings A and B | Z-L | X |
| 1 | P4 | PP1 | Cl |
| 2 | P4 | PP1 | CN |
| 3 | P4 | PP2 | Cl |
| 4 | P4 | PP2 | CN |
| 5 | P4 | PP3 | Cl |
| 6 | P4 | PP3 | CN |
| 7 | P4 | PC1 | Cl |
| 8 | P4 | PC1 | CN |
| 9 | P4 | PP4 | Cl |
| 10 | P4 | PP4 | CN |
| 11 | P5 | PP2 | Cl |
| 12 | P5 | PP2 | CN |
| 13 | P32 | PP4 | Cl |
| 14 | P32 | PP4 | CN |
| 15 | P32 | PP2 | Cl |
| 16 | P32 | PP2 | CN |
| 17 | P25 | PP4 | Cl |
| 18 | P25 | PP4 | CN |
| 19 | P25 | PP2 | Cl |
| 20 | P25 | PP2 | CN |
| 21 | P33 | PP4 | Cl |
| 22 | P33 | PP4 | CN |
| 23 | P33 | PP2 | Cl |
| 24 | P33 | PP2 | CN |
| 25 | P26 | PP4 | Cl |
| 26 | P26 | PP4 | CN |
| 27 | P26 | PP2 | Cl |
| 28 | P26 | PP2 | CN |
| 29 | I3 | PP2 | Cl |
| 30 | I3 | PP2 | CN |
| 31 | I3 | PP4 | Cl |
| 32 | I3 | PP4 | CN |
| 33 | I4 | PP2 | Cl |
| 34 | I4 | PP2 | CN |
| 35 | I4 | PP4 | Cl |
| 36 | I4 | PP4 | CN |
| 37 | P42 | PP2 | Cl |
| 38 | P42 | PP2 | CN |
| 39 | P43 | PP2 | Cl |
| 40 | P43 | PP2 | CN |
| 41 | P48 | PP2 | Cl |
| 42 | P48 | PP2 | CN |
| 43 | P49 | PP2 | Cl |
| 44 | P49 | PP2 | CN |

A material for an organic EL device of the present invention is formed of the metal complex compound of the present invention.

An organic EL device of the present invention is an organic EL device including an organic thin film layer formed of one or more layers including at least a light emitting layer, the organic thin film layer being interposed between a pair of electrodes formed of an anode and a cathode, in which at least one layer of the organic thin film layer contains the metal complex compound of the present invention, and emits light by applying a voltage between both the electrodes.

The light emitting layer of the organic EL device of the present invention preferably contains the metal complex compound of the present invention; the light emitting layer preferably contains the metal complex compound of the present invention at a content of 1 to 30 wt % with respect to the total weight of the light emitting layer.

In addition, the light emitting layer is typically formed into a thin film by vacuum vapor deposition or application; the layer containing the metal complex compound of the present invention is preferably formed by application because a production process for the organic EL device can be simplified by application as compared to vacuum vapor deposition.

The device structure of the organic EL device in the present invention is a structure obtained by laminating one or two or more organic layers between electrodes, and examples of the structure include (i) a structure formed of an anode, a light emitting layer, and a cathode, (ii) a structure formed of an anode, a hole injecting/transporting layer, a light emitting layer, an electron injecting/transporting layer, and a cathode, (iii) a structure formed of an anode, a hole injecting/transporting layer, a light emitting layer, and a cathode, and (iv) a structure formed of an anode, a light emitting layer, an electron injecting/transporting layer, and a cathode.

The compound in the present invention may be used in any one of the above organic layers, and any other hole transporting material, light emitting material, or electron transporting material can be doped with the compound. A method of forming each layer of the organic EL device is not particularly limited; in addition to a vapor deposition method, a light emitting medium or a light emitting layer can be formed by any one of various wet methods each involving the use of a solution prepared by dissolving a light emitting composition of the present invention or the respective compounds of which the composition is formed. The solution can be formed into the light emitting medium or the light emitting layer by any one of the known methods including: an application method such as a dipping method, a spin coating method, a casting method, a bar coat method, or a roll coat method; and an ink-jet method. The thickness of each organic layer of the organic EL device of the present invention, which is not particularly limited, is preferably in the range of several nanometers to 1 μm in ordinary cases because, in general, an excessively small thickness is apt to cause a defect such as a pinhole, and an excessively large thickness requires a high applied voltage to result in poor efficiency of the organic EL device.

Examples of a solvent to be used in preparing a light emitting solution forming a light emitting layer include: halogen-based hydrocarbon-based solvents such as dichloromethane, dichloroethane, chloroform, carbon tetrachloride, tetrachloroethane, trichloroethane, chlorobenzene, dichlorobenzene, and chlorotoluene; ether-based solvents such as dibutyl ether, tetrahydrofuran, dioxane, and anisole; alcohol-based solvents such as methanol, ethanol, propanol, butanol, pentanol, hexanol, cyclohexanol, methyl cellosolve, ethyl cellosolve, and ethylene glycol; hydrocarbon-based solvents such as benzene, toluene, xylene, ethylbenzene, hexane, octane, and decane; and ester-based solvents such as ethyl acetate, butyl acetate, and amyl acetate. Of those, the halogen-based hydrocarbon-based solvents and the hydrocarbon-based solvents are preferred. In addition, one kind of those solvents may be used alone, or two or more kinds of them may be used as a mixture. It should be noted that the solvent that can be used is not limited to the foregoing. In addition, the metal complex compound of the present invention may be dissolved as a dopant in the light emitting solution in advance.

In addition, when the metal complex compound of the present invention is used as a dopant, an organic EL device capable of emitting white light can be obtained by using the compound in combination with any other luminous dopant in a light emitting layer. The above other luminous dopant may be a fluorescent material or a phosphorescent material, and is not particularly limited; a dopant having a maximum luminous wavelength in a yellow-to-red region is desirable.

An electron injecting/transporting material to be used in the present invention is not particularly limited, and any compound may be used as long as the compound is typically used as an electron injecting/transporting material. Examples of the material include: a nitrogen-containing ring derivative; an oxadiazole derivative such as 2-(4-biphenylil)-5-(4-t-butylphenyl)-1,3,4-oxadiazole or bis{2-(4-t-butylphenyl)-1,3,4-oxadiazole}-m-phenylene; a triazole derivative; and a quinolinol-based metal complex. In addition, an insulator or a semiconductor is preferably used as an inorganic compound of which the electron injecting/transporting layer is constituted.

In addition, when the organic EL device of the present invention has at least one of an electron injecting layer and an electron transporting layer between the light emitting layer and the cathode, at least one of the electron injecting layer and the electron transporting layer preferably contains a nitrogen-containing ring derivative as a main component.

The nitrogen-containing ring derivative is preferably an aromatic heterocyclic compound having a hetero atom in any one of its molecules.

Preferred examples of the nitrogen-containing ring derivative include derivatives each represented by a general formula (A).

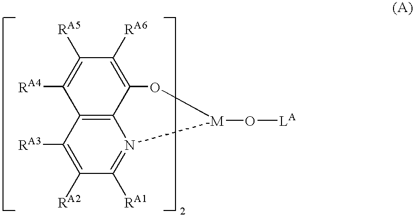

R^{A1} to R^{A6} each independently represent a hydrogen atom, a halogen atom, an oxy group, an amino group, or a hydrocarbon group having 1 to 40 carbon atoms, and each of them may be substituted.

Examples of the halogen atom include examples similar to those described above. In addition, examples of the amino group which may be substituted include examples similar to those described for the alkylamino group, the arylamino group, and the aralkylamino group (examples of an arylalkyl group include examples similar to those described for the aromatic hydrocarbon group and the alkyl group).

Examples of the hydrocarbon group having 1 to 40 carbon atoms include a substituted or unsubstituted alkyl group, a substituted or unsubstituted alkenyl group, a substituted or unsubstituted cycloalkyl group, a substituted or unsubstituted alkoxy group, a substituted or unsubstituted aryl group (aromatic hydrocarbon group), a substituted or unsubstituted heterocyclic group, a substituted or unsubstituted aralkyl group, a substituted or unsubstituted aryloxy group, and a substituted or unsubstituted alkoxycarbonyl group. Examples of each of the alkyl group, the alkenyl group, the cycloalkyl group, the alkoxy group, the aryl group, the heterocyclic group, the aralkyl group, and the aryloxy group include examples similar to those described above. The alkoxycarbonyl group is represented by —COOY′, and examples of Y′ include examples similar to those described for the alkyl group.

M represents aluminum (Al), gallium (Ga), or indium (In), and preferably represents In.

LA in the general formula (A) is a group represented by the following general formula (A′) or (A″).

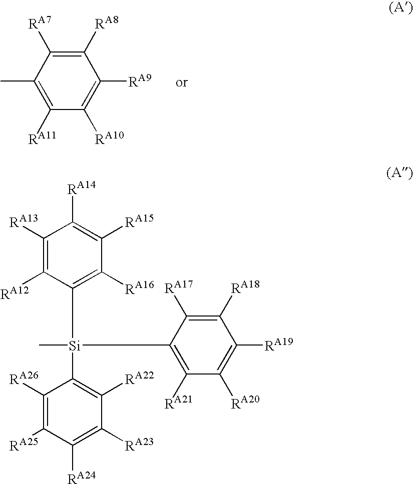

(In the formulae, R^{A7} to R^{A11} each independently represent a hydrogen atom, or a substituted or unsubstituted hydrocarbon group having 1 to 40 carbon atoms, and groups adjacent to each other of R^{A7} to R^{A11} may form a cyclic structure, and R^{A12} to R^{A26} each independently represent a hydrogen atom, or a substituted or unsubstituted hydrocarbon group having 1 to 40 carbon atoms, and groups adjacent to each other of R^{A12} to R^{A26} may form a cyclic structure.)

Examples of the hydrocarbon group having 1 to 40 carbon atoms represented by any one of R^{A7} to R^{A11} and R^{A12} to R^{A26} of the general formulae (A′) and (A″) include examples similar to specific examples of each of R^{A1} to R^{A6} described above.

In addition, a divalent group in the case where groups adjacent to each other of R^{A7} to R^{A11} and R^{A12} to R^{A26} forms a cyclic structure is, for example, a tetramethylene group, a pentamethylene group, a hexamethylene group, a diphenylmethane-2,2′-diyl group, a diphenylethane-3,3′-diyl group, or a diphenylpropane-4,4′-diyl group.

Specific examples of the metal chelate complex of the nitrogen-containing ring represented by the general formula (A) are shown below. However, the complex is not limited to those exemplified compounds.

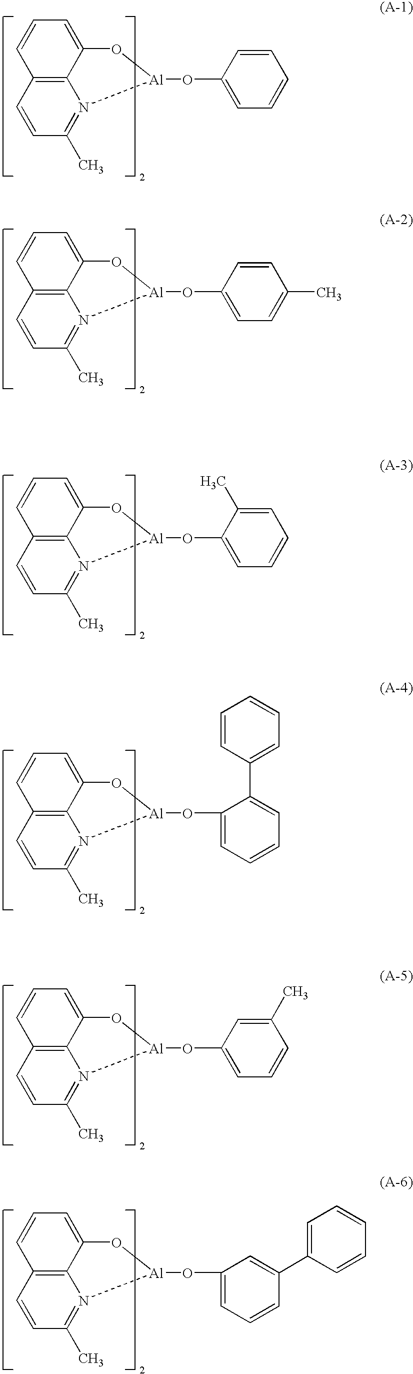

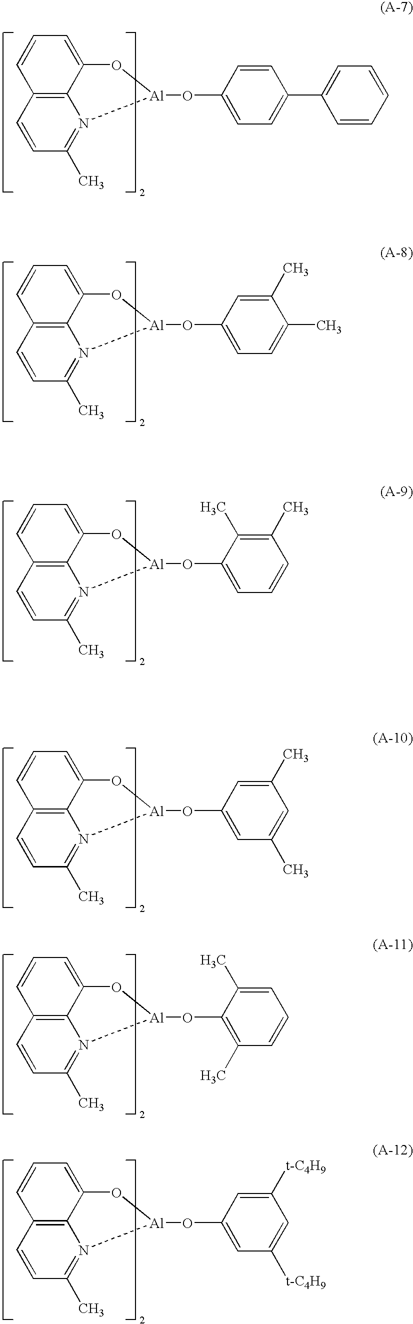

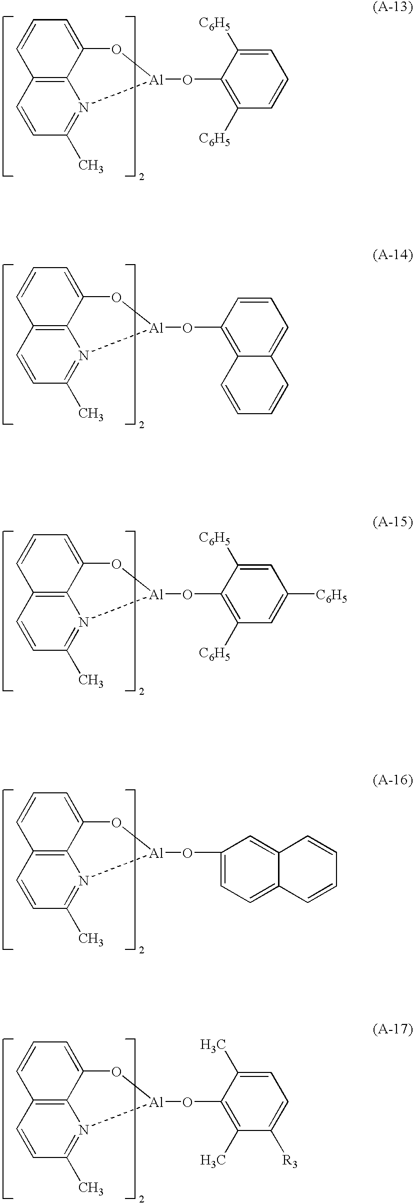

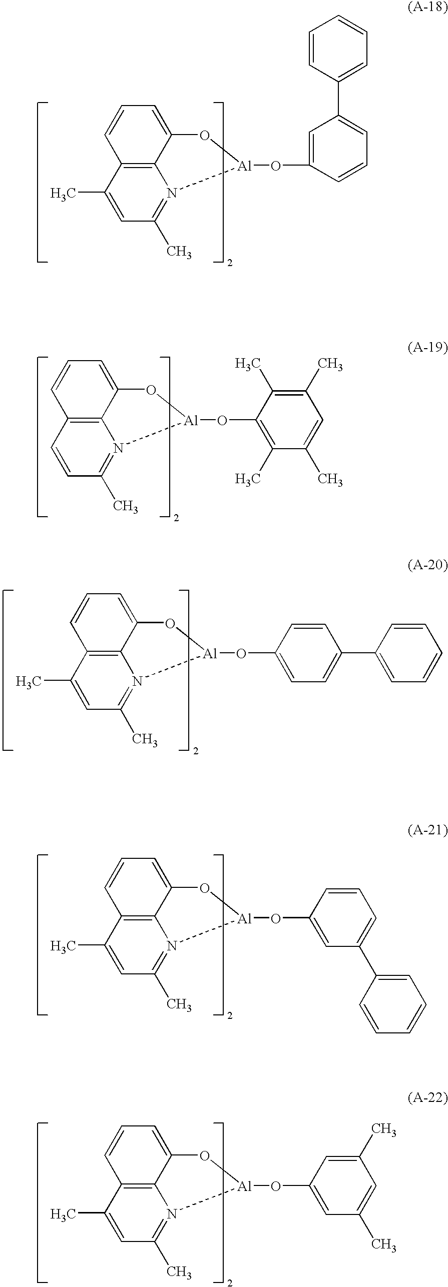

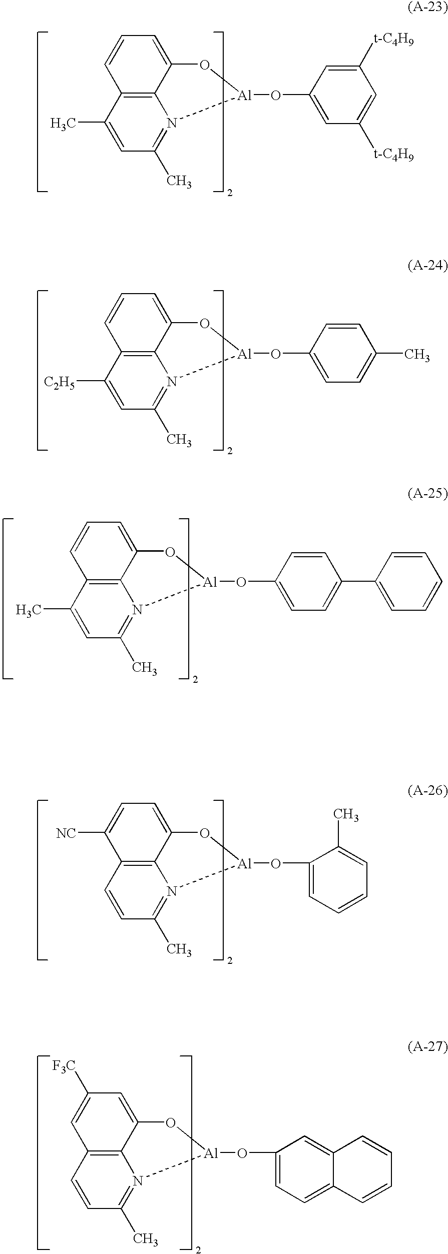

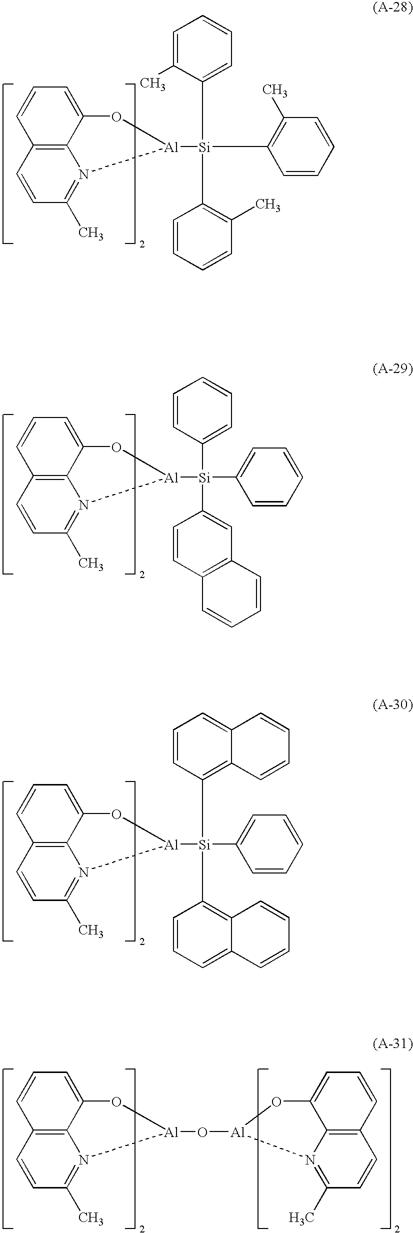

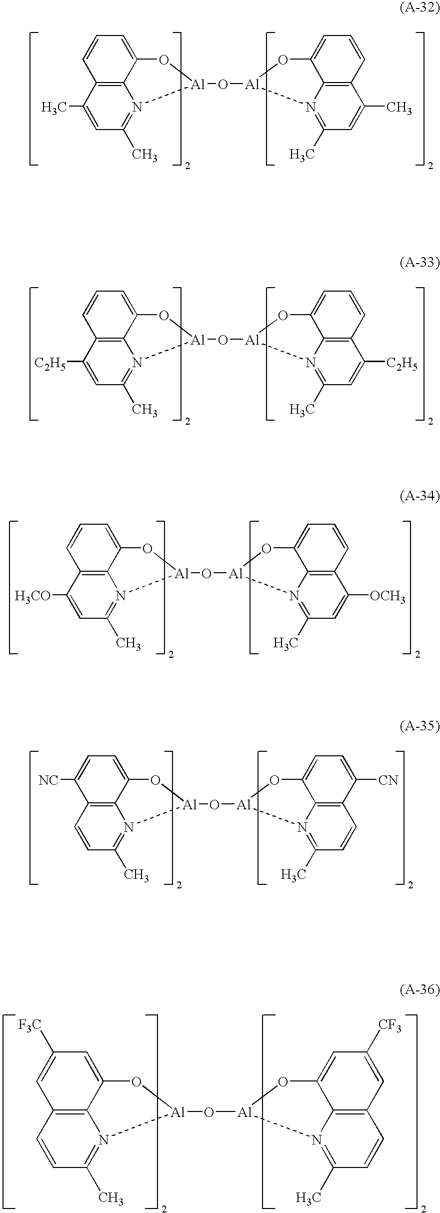

A nitrogen-containing five-membered ring derivative is also preferably used as the nitrogen-containing ring derivative. A nitrogen-containing five-membered ring for the derivative is, for example, an imidazole ring, a triazole ring, a tetrazole ring, an oxadiazole ring, a thiadiazole ring, an oxatriazole ring, or a thiatriazole ring, and the nitrogen-containing five-membered ring derivative is preferably a benzimidazole ring, a benzotriazole ring, a pyridinoimidazole ring, a pyrimidinoimidazole ring, or a pyridazinoimidazole ring, or particularly preferably a derivative represented by the following general formula (B).

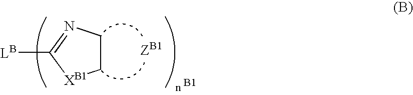

In the general formula (B), L^{B} represents a linking group which is divalent or more, and examples of the linking group include a carbon atom, a silicon atom, a nitrogen atom, a boron atom, an oxygen atom, a sulfur atom, a metal (such as barium or beryllium), an aromatic hydrocarbon ring, and an aromatic heterocyclic ring. Of those, a carbon atom, a nitrogen atom, a silicon atom, a boron atom, an oxygen atom, a sulfur atom, an aryl group, or an aromatic heterocyclic group is preferred, and a carbon atom, a silicon atom, an aryl group, or an aromatic heterocyclic group is more preferred.

The aryl group and the aromatic heterocyclic group each represented by L^{B} may each have a substituent, and the substituent is preferably an alkyl group, an alkenyl group, an alkynyl group, an aryl group, an amino group, an alkoxy group, an aryloxy group, an acyl group, an alkoxycarbonyl group, an aryloxycarbonyl group, an acyloxy group, an acylamino group, an alkoxycarbonylamino group, an aryloxycarbonylamino group, a sulfonylamino group, a sulfamoyl group, a carbamoyl group, an alkylthio group, an arylthio group, a sulfonyl group, a halogen atom, a cyano group, or an aromatic heterocyclic group, more preferably an alkyl group, an aryl group, an alkoxy group, an aryloxy group, a halogen atom, a cyano group, or an aromatic heterocyclic group, still more preferably an alkyl group, an aryl group, an alkoxy group, an aryloxy group, or an aromatic heterocyclic group, or particularly preferably an alkyl group, an aryl group, an alkoxy group, or an aromatic heterocyclic group.

Specific examples of LB include the following.

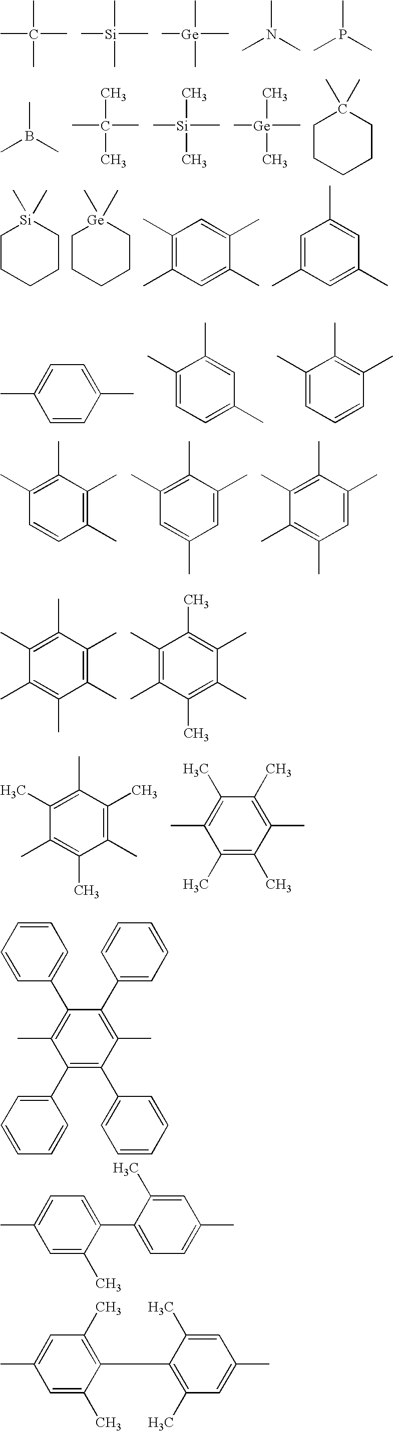

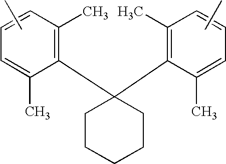

X^{B1} in the general formula (B) represents —O—, —S—, or ═N—R^{B1}. R^{B1} represents a hydrogen atom, an aliphatic hydrocarbon group, an aryl group, or a heterocyclic group.

The aliphatic hydrocarbon group represented by R^{B1} is a linear, branched, or cyclic alkyl group (alkyl group having preferably 1 to 20 carbon atoms, more preferably 1 to 12 carbon atoms, or particularly preferably 1 to 8 carbon atoms such as a methyl, ethyl, isopropyl, t-butyl, n-octyl, n-decyl, n-hexadecyl, cyclopropyl, cyclopentyl, or cyclohexyl group), a linear, branched, or cyclic alkenyl group (alkenyl group having preferably 2 to 20 carbon atoms, more preferably 2 to 12 carbon atoms, or particularly preferably 2 to 8 carbon atoms such as a vinyl, allyl, 2-butenyl, or 3-pentenyl group), or a linear, branched, or cyclic alkynyl group (alkynyl group having preferably 2 to 20 carbon atoms, more preferably 2 to 12 carbon atoms, or particularly preferably 2 to 8 carbon atoms such as a propargyl or 3-pentynyl group), and is preferably an alkyl group.

The aryl group represented by R^{B1} is a monocyclic group or a fused ring group, and is an aryl group having preferably 6 to 30 carbon atoms, more preferably 6 to 20 carbon atoms, or still more preferably 6 to 12 carbon atoms, and examples of the group include phenyl, 2-methylphenyl, 3-methylphenyl, 4-methylphenyl, 2-methoxyphenyl, 3-trifluoromethylphenyl, pentafluorophenyl, 1-naphthyl, and 2-naphthyl groups.

The heterocyclic group represented by R^{B1} is a monocyclic group or a fused ring group, is a heterocyclic group having preferably 1 to 20 carbon atoms, more preferably 1 to 12 carbon atoms, or still more preferably 2 to 10 carbon atoms, and is preferably an aromatic heterocyclic group containing at least one of a nitrogen atom, an oxygen atom, a sulfur atom, and a selenium atom. Examples of the heterocyclic group include pyrrolidine, piperidine, piperazine, morpholine, thiophene, selenophene, furan, pyrrole, imidazole, pyrazole, pyridine, pyrazine, pyridazine, pyrimidine, triazole, triazine, indole, indazole, purine, thiazoline, thiazole, thiadiazole, oxazoline, oxazole, oxadiazole, quinoline, isoquinoline, phthalazine, naphthylidine, quinoxaline, quinazoline, cinnoline, pteridine, acridine, phenanthroline, phenazine, tetrazole, benzimidazole, benzoxazole, benzothiazole, benzotriazole, tetrazaindene, carbazole, and azepine. Of those, furan, thiophene, pyridine, pyrazine, pyrimidine, pyridazine, triazine, quinoline, phthalazine, naphthylidine, quinoxaline, or quinazoline is preferred, furan, thiophene, pyridine, or quinoline is more preferred, and quinoline is still more preferred.

The aliphatic hydrocarbon group, the aryl group, and the heterocyclic group each represented by R^{B1} may each have a substituent. Examples of the substituent include examples similar to those described for the substituent for the group represented by L^{B}, and the same holds true for a preferred substituent for each of the groups.

R^{B1} represents preferably an aliphatic hydrocarbon group, an aryl group, or a heterocyclic group, more preferably an aliphatic hydrocarbon group (aliphatic hydrocarbon group having preferably 6 to 30 carbon atoms, more preferably 6 to 20 carbon atoms, or still more preferably 6 to 12 carbon atoms) or an aryl group, or still more preferably an aliphatic hydrocarbon group (aliphatic hydrocarbon group having preferably 1 to 20 carbon atoms, more preferably 1 to 12 carbon atoms, or still more preferably 2 to 10 carbon atoms).

X^{B1} represents preferably —O— or ═N—R^{B1}, more preferably ═N—R^{B1}.

Z^{B1} represents an atomic group needed for the formation of an aromatic ring. The aromatic ring formed of Z^{B1} may be either an aromatic hydrocarbon ring or an aromatic heterocyclic ring, and specific examples of the aromatic ring include a benzene ring, a pyridine ring, a pyrazine ring, a pyrimidine ring, a pyridazine ring, a triazine ring, a pyrrole ring, a furan ring, a thiophene ring, a selenophene ring, a tellurophene ring, an imidazole ring, a thiazole ring, a selenazole ring, a tellurazole ring, a thiadiazole ring, an oxadiazole ring, and a pyrazole ring. Of those, a benzene ring, a pyridine ring, a pyrazine ring, a pyrimidine ring, or a pyridazine ring is preferred, a benzene ring, a pyridine ring, or a pyrazine ring is more preferred, a benzene ring or a pyridine ring is still more preferred, and a pyridine ring is particularly preferred.

The aromatic ring formed of Z^{B1} may further form a fused ring with any other ring, and may have a substituent. Examples of the substituent include examples similar to those described for the substituent for the group represented by L^{B}, and the substituent is preferably an alkyl group, an alkenyl group, an alkynyl group, an aryl group, an amino group, an alkoxy group, an aryloxy group, an acyl group, an alkoxycarbonyl group, an aryloxycarbonyl group, an acyloxy group, an acylamino group, an alkoxycarbonylamino group, an aryloxycarbonylamino group, a sulfonylamino group, a sulfamoyl group, a carbamoyl group, an alkylthio group, an arylthio group, a sulfonyl group, a halogen atom, a cyano group, or a heterocyclic group, more preferably an alkyl group, an aryl group, an alkoxy group, an aryloxy group, a halogen atom, a cyano group, or a heterocyclic group, still more preferably an alkyl group, an aryl group, an alkoxy group, an aryloxy group, or an aromatic heterocyclic group, or particularly preferably an alkyl group, an aryl group, an alkoxy group, or an aromatic heterocyclic group.

n^{B1} represents an integer of 1 to 4, or preferably 2 or 3.

Of the nitrogen-containing five-membered ring derivatives each represented by the general formula (B), a derivative represented by the following general formula (B′) is more preferred.

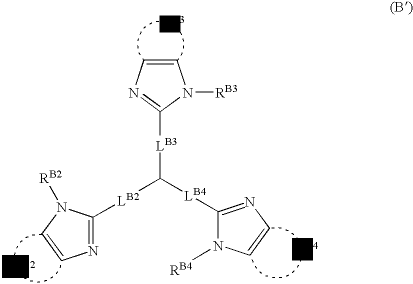

In the general formula (B′), R^{B2}, R^{B3}, and R^{B4} each have the same meaning as that of R^{B1} in the general formula (B), and the same holds true for preferred examples of each of R^{B2}, R^{B3}, and R^{B4}.

Z^{B2}, Z^{B3}, and Z^{B4} each have the same meaning as that of Z^{B1} in the general formula (B), and the same holds true for preferred examples of each of Z^{B2}, Z^{B3}, and Z^{B4}.

L^{B2}, L^{B3}, and L^{B4} each represent a linking group, and examples of the linking group include examples each obtained by making each of the examples of L^{B} in the general formula (B) divalent. The linking group is preferably a single bond, a divalent aromatic hydrocarbon ring group, a divalent aromatic heterocyclic group, or a linking group obtained by combining two or more of them, or more preferably a single bond. Each of L^{B2}, L^{B3}, and L^{B4} may have a substituent, examples of the substituent include examples similar to those described for the substituent for the group represented by LB in the general formula (B), and the same holds true for a preferred substituent for each of L^{B2}, L^{B3}, and L^{B4}.

Y represents a nitrogen atom, a 1,3,5-benzenetriyl group, a 2,4,6-triazinetriyl group, or a 2,4,6-pyridinetriyl group. A 1,3,5-benzenetriyl group may have a substituent at 2, 4, or 6-position, and examples of the substituent include an alkyl group, an aromatic hydrocarbon ring group, and a halogen atom.

Specific examples of the nitrogen-containing five-membered ring derivative represented by the general formula (B) or (B′) are shown below. However, the derivative is not limited to those exemplified compounds.

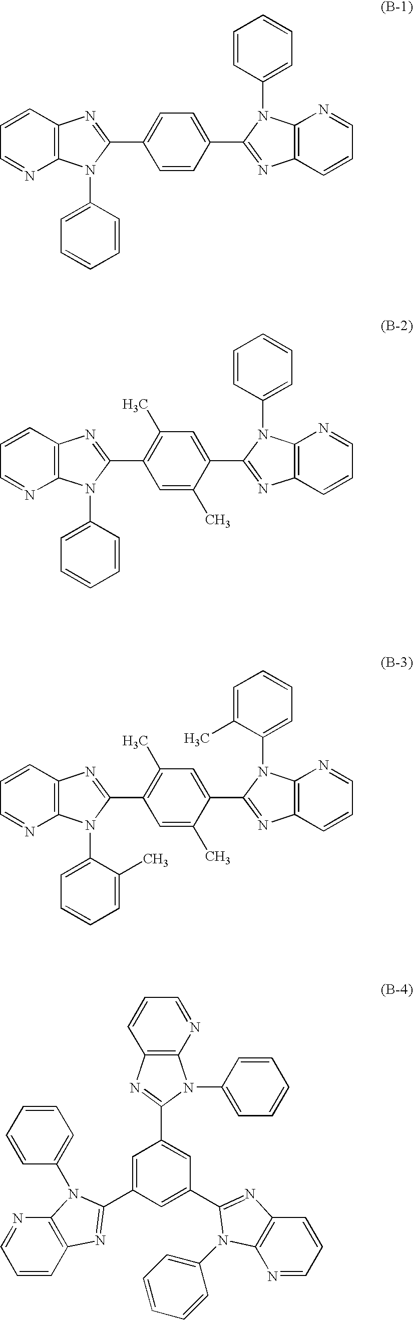

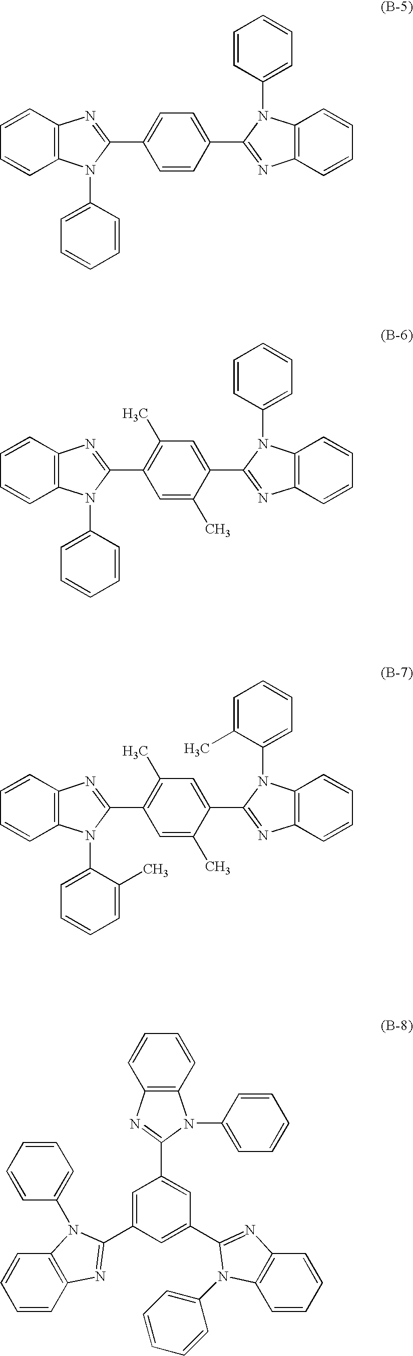

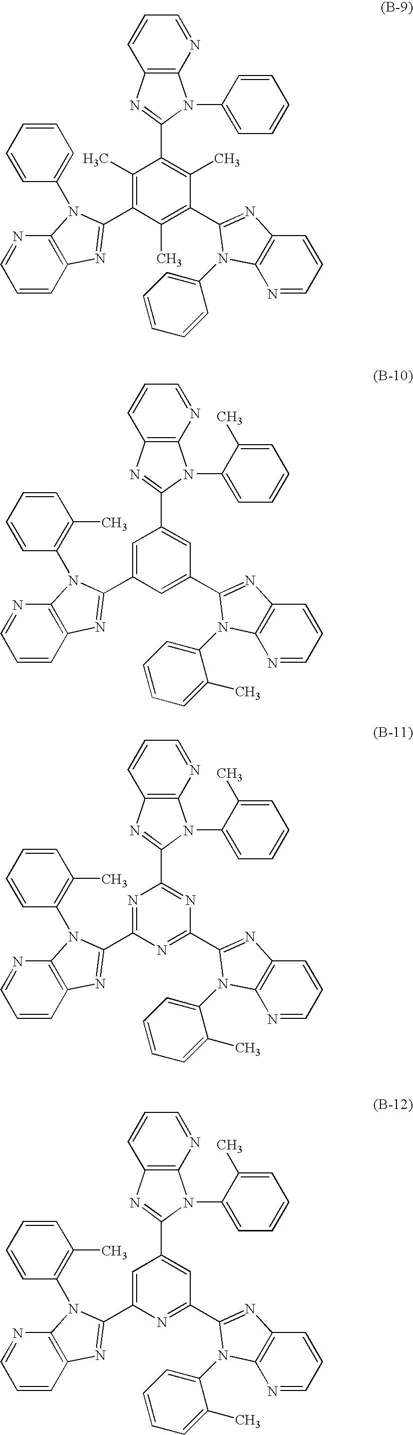

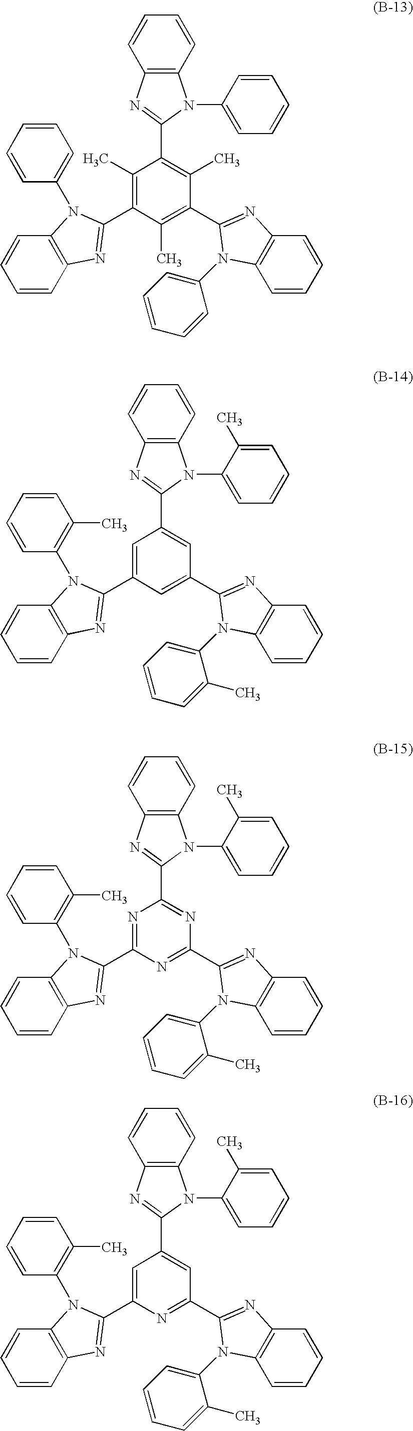

The examples of the electron injecting/transporting material further include compounds each having a structure obtained by combining an electron deficient nitrogen-containing five-membered ring skeleton or an electron deficient nitrogen-containing six-membered ring skeleton with a substituted or unsubstituted indole skeleton, a substituted or unsubstituted carbazole skeleton, or a substituted or unsubstituted azacarbazole skeleton. In addition, suitable examples of the electron deficient nitrogen-containing five-membered ring skeleton or the electron deficient nitrogen-containing six-membered ring skeleton include pyridine, pyrimidine, pyrazine, triazine, triazole, oxadiazole, pyrazole, imidazole, quinoxaline, and pyrrole skeletons, and molecular skeletons each obtained by the condensation of two or more of the skeletons such as benzimidazole and imidazopyridine. Of the combinations, a combination of a pyridine, pyrimidine, pyrazine, ortriazine skeleton and a carbazole, indole, azacarbazole, or quinoxaline skeleton is preferred. Each of the above-mentioned skeletons may be substituted or unsubstituted.

Specific examples of such compounds are shown below.

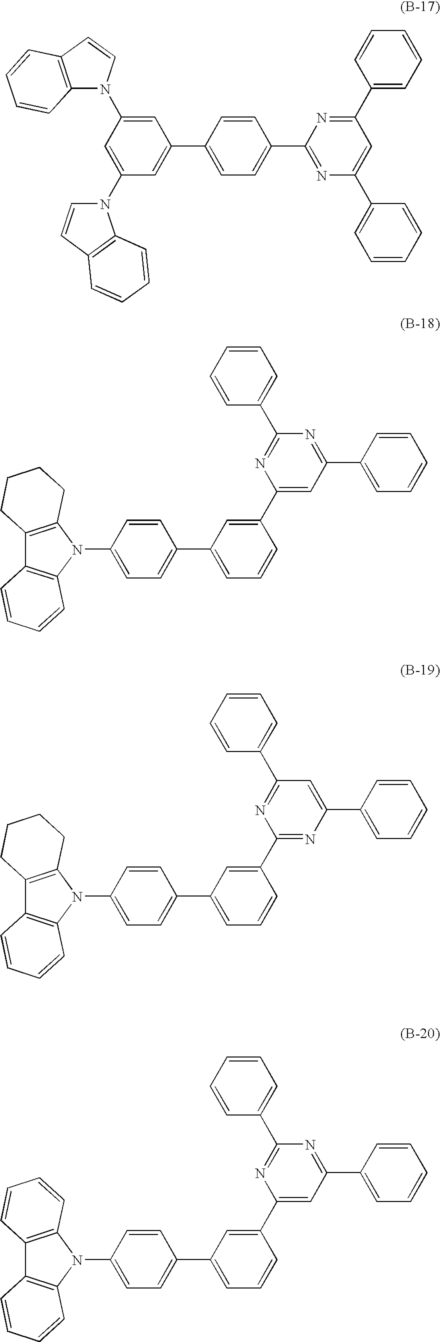

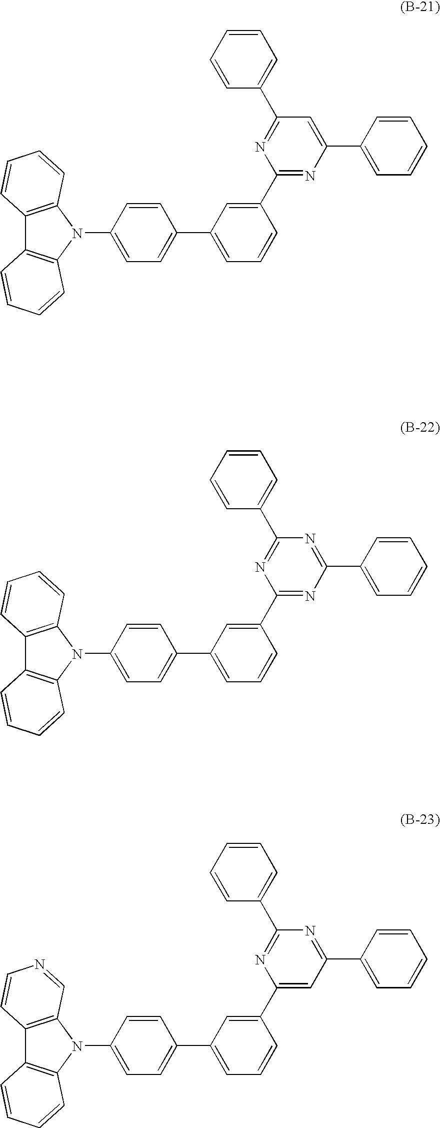

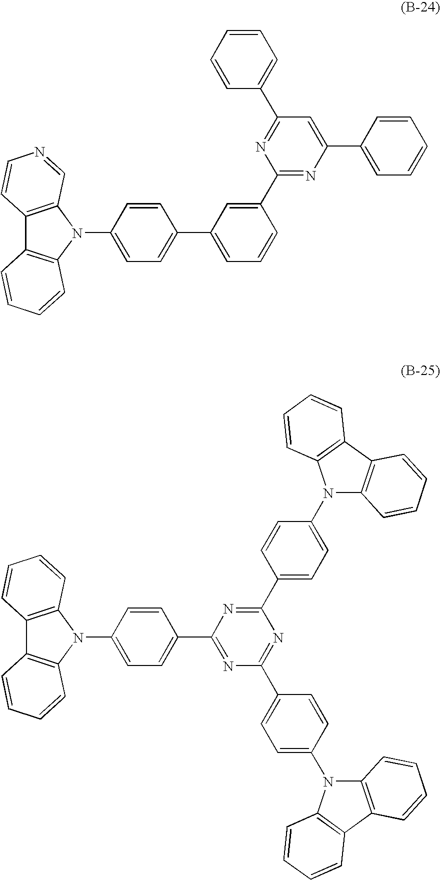

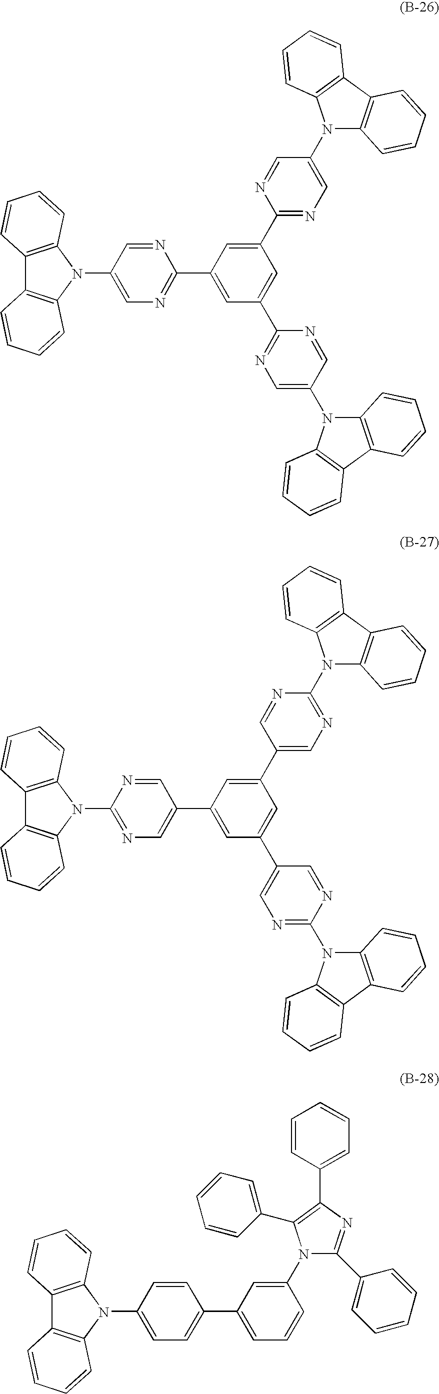

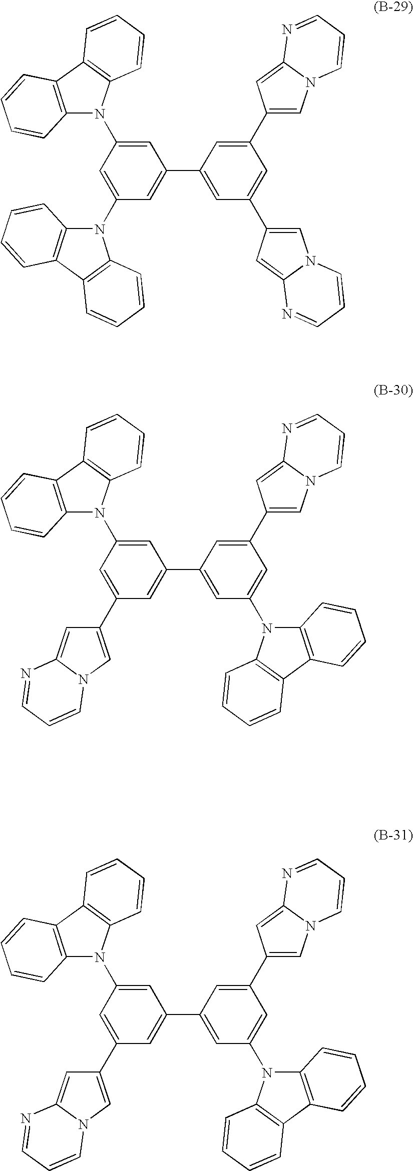

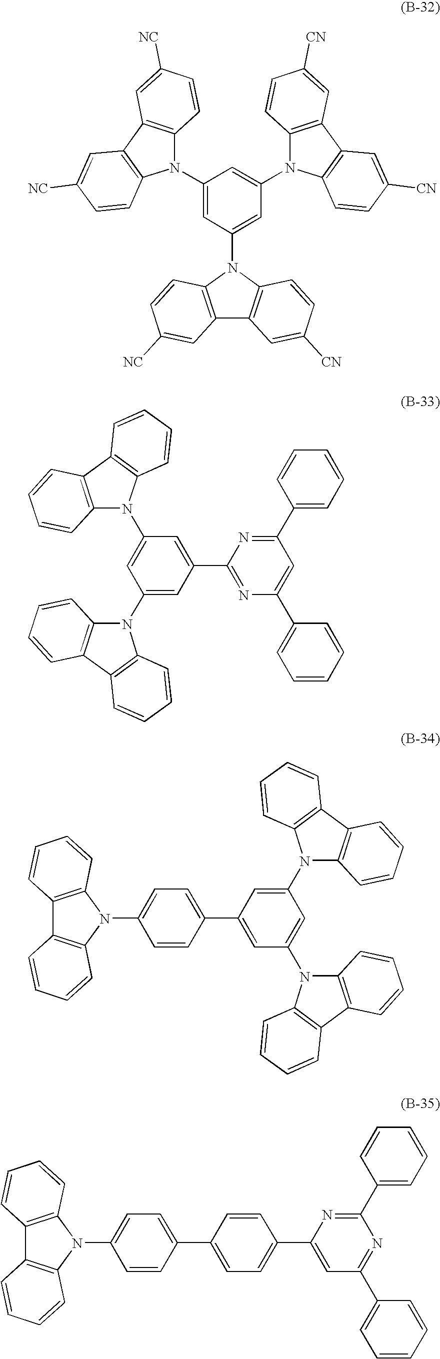

Each of the electron injecting layer and the electron transporting layer may be of a single-layered structure formed of one or two or more kinds of the above materials, or may be of a multi-layered structure formed of multiple layers having the same composition or different compositions. A material for each of the layers preferably has a n-electron deficient nitrogen-containing heterocyclic group.

When the electron injecting/transporting layer is formed of an insulator or a semiconductor, the electron injecting/transporting layer effectively prevents leak in the electric current and improves the electron injecting capability. It is preferred that at least one metal compound selected from the group consisting of alkali metal chalcogenides, alkaline earth metal chalcogenides, alkali metal halides, and alkaline earth metal halides be used as the insulator. It is preferred that the electron injecting/transporting layer be constituted of the above alkali metal chalcogenide because the electron injecting property can be improved.

More specifically, preferred examples of the alkali metal chalcogenide include Li₂O, Na₂S, and Na₂Se. Preferred examples of the alkaline earth metal chalcogenide include CaO, BaO, SrO, BeO, BaS, and CaSe. Preferred examples of the alkali metal halide include LiF, NaF, KF, LiCl, KCl, and NaCl. Preferred examples of the alkaline earth metal halide include fluorides such as CaF₂, BaF₂, SrF₂, MgF₂, and BeF₂ and halides other than the fluorides.

Examples of the semiconductor constituting the electron injecting/transporting layer include oxides, nitrides, and oxide nitrides of at least one element selected from Ba, Ca, Sr, Yb, Al, Ga, In, Li, Na, Cd, Mg, Si, Ta, Sb, and Zn used alone or in combination of two or more. It is preferred that the inorganic compound including the electron injecting/transporting layer form a crystallite or amorphous insulating thin film. When the electron injecting layer is formed of the insulating thin film described above, amore uniform thin film can be formed, and defects of pixels such as dark spots can be decreased.

Examples of the inorganic compound include alkali metal chalcogenides, alkaline earth metal chalcogenides, alkali metal halides, and alkaline earth metal halides that are described above.

Further, a reductive dopant with a work function of 2.9 eV or smaller may be contained in the electron injecting/transporting layer. Here, the reducing dopant is defined as a substance that can reduce a compound having the electron-transporting property. Various compounds can be used as the reducing dopant as long as the compounds have a uniform reductive property. For example, at least one substance selected from the group consisting of alkali metals, alkaline earth metals, rare earth metals, alkali metal oxides, alkali metal halides, alkaline earth metal oxides, alkaline earth metal halides, rare earth metal oxides, rare earth metal halides, organic complexes of alkali metals, organic complexes of alkaline earth metals, and organic complexes of rare earth metals can be preferably used.

Examples of the preferred reductive dopant include at least one alkali metal selected from the group consisting of Na (work function: 2.36 eV), K (work function: 2.28 eV), Rb (work function: 2.16 eV), and Cs (work function: 1.95 eV) or at least one alkaline earth metal selected from the group consisting of Ca (work function: 2.9 eV), Sr (work function: 2.0 to 2.5 eV), and Ba (work function: 2.52 eV), and those with work function of 2.9 eV are particularly preferred. Of those, at least one kind selected from the group consisting of K, Rb, and Cs, Rb and Cs is more preferred, and Cs is most preferred. Those alkaline metals have particularly high reducing capability, and only an addition of relatively small amount of them into an electron injection zone provides improvement of luminance and lifetime extension of the organic EL device.

Further, with regard to the reductive dopant with work function of 2.9 eV or smaller, a combination of two or more kinds of alkali metals is also preferred, and particularly, combinations including Cs, for example, combinations of Cs and Na, Cs and K, Cs and Rb, Cs and Na and K are preferred. Including Cs in combination effects the reducing capability efficiently, and the addition into the electron injection zone provides improvement of luminance and lifetime extension of the organic EL device.

The light emitting layer of the organic EL device of the present invention has: a function with which a hole can be injected from the anode or the hole injecting layer and an electron can be injected from the cathode or the electron injecting layer upon application of an electric field; a function of moving injected charge (the electron and the hole) with the force of the electric field; and a function with which a field for recombination between the electron and the hole is provided so that the recombination can lead to light emission. The light emitting layer of the organic EL device of the present invention preferably contains at least the metal complex compound of the present invention, and may contain a host material using the metal complex compound as a dopant material. Examples of the host material include a host material having a carbazole skeleton, a host material having a diarylamine skeleton, a host material having a pyridine skeleton, a host material having a pyrazine skeleton, a host material having a triazine skeleton, and a host material having an arylsilane skeleton. The energy level of the lowest triplet excited state (Tl) of the host material is preferably larger than the Tl of the dopant material. A light emitting layer in which the host material is doped with a light emitting material can be formed by, for example, the co-deposition of the host material and the light emitting material such as the metal complex compound.

The host material is preferably, for example, a material represented by each of general formulae (C-I) and (C-II).

(Het-)nA (C-I)

Het(-A)m (C-II)

[In the formulae, Het represents a nitrogen-, oxygen-, or sulfur-containing heteroaromatic compound group typified by a substituted or unsubstituted carbazolyl group, a substituted or unsubstituted arylcarbazolyl group, or a substituted or unsubstituted carbazolylalkylene group, A represents a group formed of a site represented by the following general formula (E), and n and m each represent an integer of 1 to 3.

(M′)p-(L)q-(M″)r (E)

(M′ and M″ each independently represent a nitrogen-containing heteroaromatic ring which is formed of 2 to 40 carbon atoms and which may have or may not have a substituent, and M′ and M″ may be identical to or different from each other, L represents a single bond, an arylene group having 6 to 30 carbon atoms, a cycloalkylene group having 5 to 30 carbon atoms, or a heteroaromatic ring which has 2 to 30 carbon atoms and which may have or may not have a substituent bonded to itself, and p represents an integer of 0 to 2, q represents an integer of 1 to 3, and r represents an integer of 0 to 2, provided that p+r is equal to or greater than 1.)]

Specific examples of the material represented by each of the general formulae (C-I) and (C-II) include, but not limited to, the following structures.

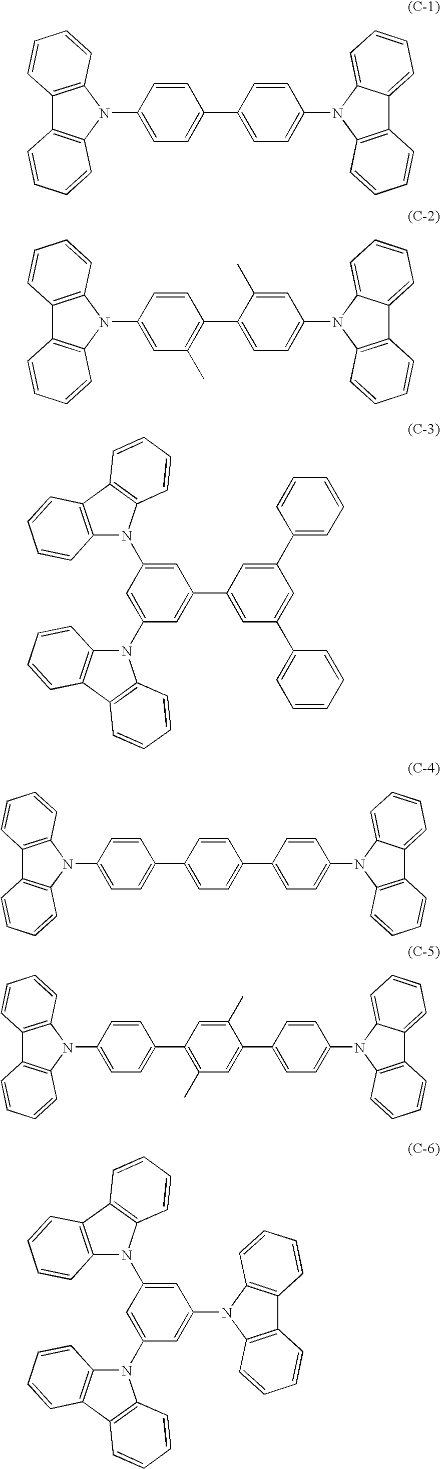

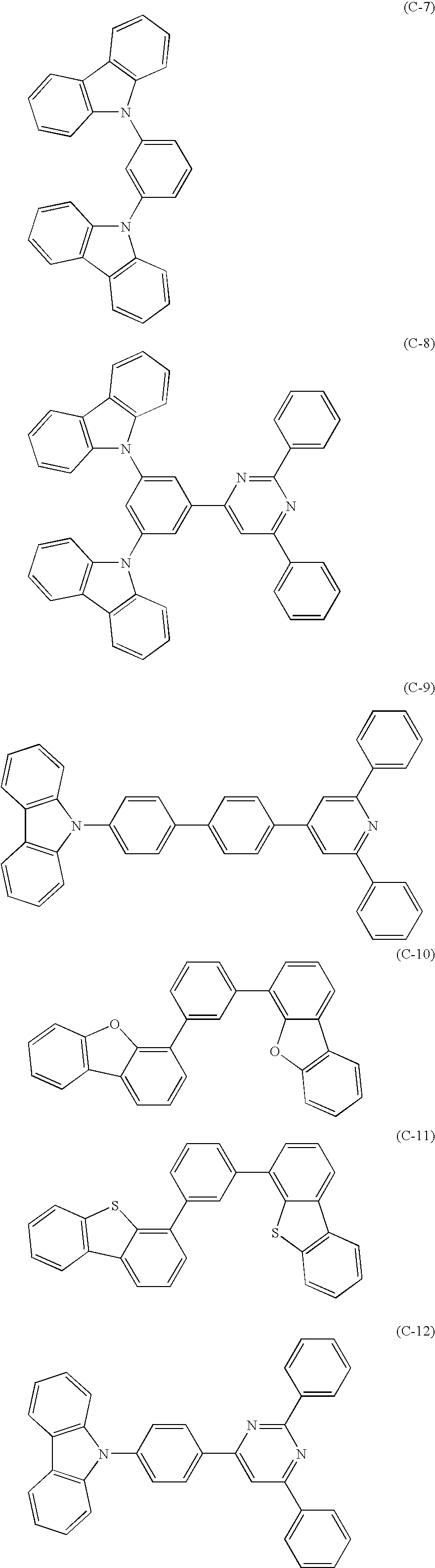

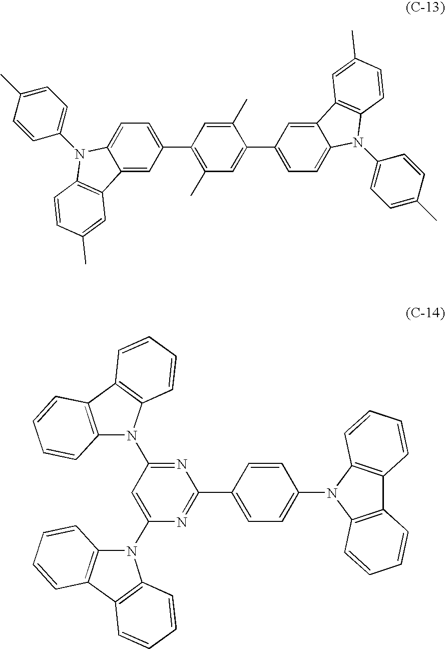

In addition, a compound represented by each of the following general formulae (D-I) and (D-II) can also be used as a host material. In the formulae, Q¹ to Q⁴ each represent a group similar to that represented by R^{B1} of the general formula (B), and L and q each have the same meaning as that defined in the general formula (E).

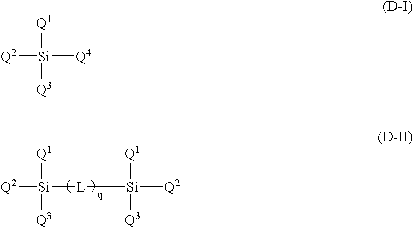

Specific examples of the compound represented by each of the general formulae (D-I) and (D-II) include, but not limited to, the following structures.

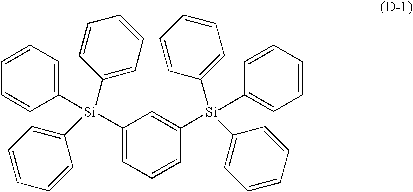

The anode in the organic EL device plays a role of injecting holes into a hole injecting/transporting layer and/or into a light emitting layer, and it is effective that the anode has a work function of 4.5 eV or larger. Specific examples of the material for the anode used in the present invention include indium tin oxide (ITO) alloy, tin oxide (NESA), gold, silver, platinum, copper. With regard to the cathode, its material preferably has a small work function with the aim of injecting electrons into an electron injecting/transporting layer and/or into a light emitting layer. Further in the organic EL device, a hole injecting (transporting) layer may be disposed over the anode. Various organic compounds and polymers usually used for the organic EL device, for example, which are described in Japanese Patent Application Laid-Open Nos. Sho 63-295695 and Hei 02-191694 may be employed as the hole injecting/transporting layer. Examples thereof include aromatic tertiary amine, hydrazone derivatives, carbazole derivatives, triazole derivatives, imidazole derivatives, or polyvinylcarbazole, polyethylenedioxythiophene poly sulfonic acid (PEDOT/PSS).

Materials for the cathode of the organic EL device are not particularly limited, but include indium, aluminium, magnesium, magnesium-indium alloy, magnesium-aluminium alloy, aluminium-lithium alloy, aluminium-scandium-lithium alloy, magnesium-silver alloy.

### EXAMPLES

Next, the present invention will be described in more detail by way of examples. However, the present invention is not limited to those examples.

### Synthesis Example 1

### Synthesis of Compound 3

The above Compound 3 was synthesized via the following route.

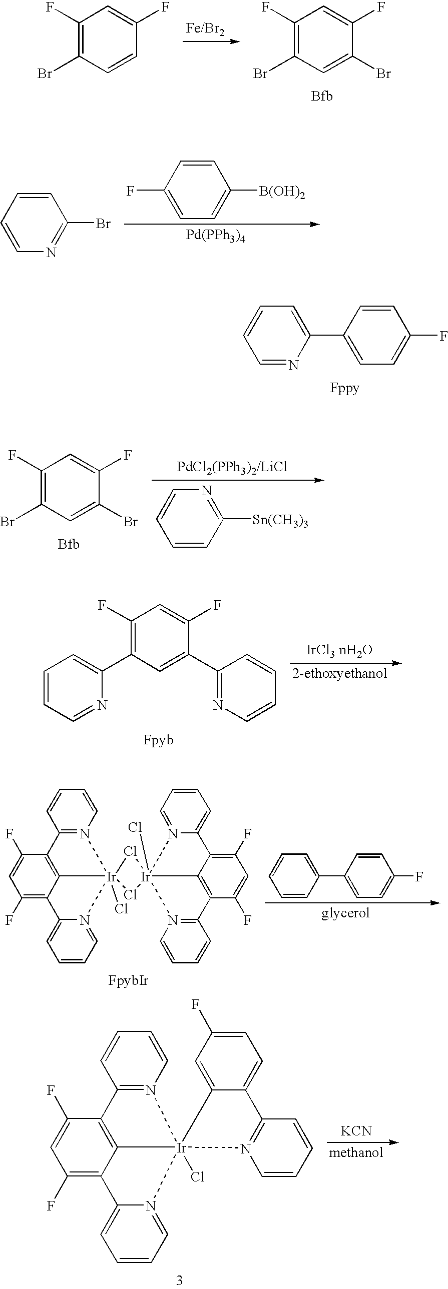

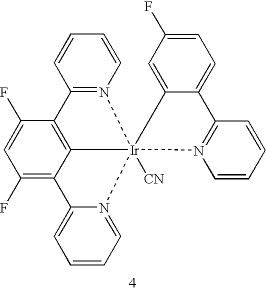

### (1) Synthesis of Bfb

39 mmol (7.52 g) of 1-bromo-2,4-difluorobenzene were loaded into a 100-ml flask, and the 1-bromo-2,4-difluorobenzene was heated to 60° C. Next, 0.15 g of iron was added, and then 39 mmol (6.23 g) of bromine were dropped over 3 hours while the temperature of the mixture was kept at 60° C. After the completion of the dropping, the resultant was further subjected to a reaction at 60° C. for 2 hours.

After the resultant reaction liquid had been cooled to room temperature, the reaction liquid was charged into a cold aqueous solution of sodium hydroxide, and the reaction product was extracted with hexane. The resultant organic layer was washed with pure water and a saturated sodium chloride solution, and was dehydrated with anhydrous sodium sulfate. After that, the solvent was removed. The resultant residue was purified by means of silica gel chromatography (developing solvent: hexane), whereby 8.81 g of Bfb as colorless oil were obtained (84% yield).

¹H-NMR (CDCl₃): δ 7.70 (t, 1H, J=7.2 Hz), 6.92 (t, 1H, J=8.0 Hz)

### (2) Synthesis of Fppy

77 mmol (10.7 g) of 4-fluorophenylboronic acid, 70 mmol (11.0 g) of 2-bromopyridine, 1.4 mmol (1.6 g) of tetrakistriphenylphosphinepalladium(0), 22 g of a 2-M aqueous solution of sodium carbonate, and 140 ml of 1,2-dimethoxyethane were loaded into a 500-ml three-necked flask, and the air in the system was replaced with nitrogen. The mixture was refluxed under heat for 9 hours while being stirred, and was then cooled to room temperature. After that, water and ethyl acetate were added to extract the mixture, and the organic layer was dried with magnesium sulfate.

After filtration, the solution was concentrated, whereby an orange slurry-like substance was obtained. The substance was purified with a silica gel column (developing solvent dichloromethane:hexane=1:2 to 2:1), whereby Fppy was obtained (9.7 g, 80% yield).

¹H-NMR (CDCl₃): δ 8.68 (d, 1H, J=5.7 Hz), 8.00-7.97 (m, 2H), 7.75 (t, 1H, J=7.7 Hz), 7.68 (d, 1H, J=8.0 Hz), 7.24-7.22 (m, 1H), 7.16 (t, 2H, J=8.6 Hz)

### (3) Synthesis of Fpyb

A 200-ml three-necked flask was replaced with nitrogen. 207 mmol (8.78 g) of lithium chloride and 1.61 mmol (1.1 g) of bistriphenylphosphine palladium dichloride were added, and the flask was replaced with nitrogen again. Next, 80 ml of toluene and 20.7 mmol (5.62 g) of Bfb were added. Further, 62.1 mmol (15.0 g) of trimethyl(2-pyridyl) tin were dropped, and the whole was refluxed under heat for 3 days in a stream of nitrogen. After the resultant had been left standing to cool, 150 ml of a saturated aqueous solution of potassium fluoride were added, and the whole was stirred for 30 minutes. A solid was removed by filtration, and the remainder was extracted with methylene chloride and a 5% aqueous solution of sodium hydrogen carbonate. After that, sodium sulfate was added to an organic layer for dehydration. The solvent was removed under reduced pressure, whereby a brown solid was obtained. The resultant was washed with ether, whereby a 4.3 g of white solid of Fpyb were obtained (78% yield).

¹H-NMR (CDCl₃): δ 8.66 (d, 2H, J=5.2 Hz), 8.55 (t, 1H, J=8.9 Hz), 7.72-7.68 (m, 4H), 7.21-7.19 (m, 2H), 6.97 (t, 1H, J=10.9 Hz)

¹⁹F-NMR (CDCl₃): δ-112.95

### (4) Synthesis of FpybIr

To a 100-ml two-necked flask, 1.33 mmol (0.469 g) of iridium chloride hydrate, 1.86 mmol (0.5 g) of Fpyb, and 20 ml of 2-ethoxyethanol were added, and the whole was stirred under heat for 20 hours in a stream of nitrogen. After the resultant had been left standing to cool, the solvent was removed by filtration, whereby 0.51 g of a yellow solid was obtained (73% yield).

### (5) Synthesis of Compound 3

0.283 mmol (0.3 g) of FpybIr, 0.283 mmol (0.49 g) of Fppy, and 10 ml of glycerol were added to a 100-ml egg plant flask, and the mixture was refluxed under heat for 6 minutes while being irradiated with a microwave in a stream of nitrogen. After the mixture had been left standing to cool, water was added to the mixture, and the resultant precipitate was recovered by filtration and washed with hexane, whereby Compound 3 as a yellow solid was obtained (0.221 g, 58% yield).

¹H-NMR (CDCl₃): δ 10.08 (d, 1H, J=5.2 Hz), 8.10 (d, 2H, J=8.0 Hz), 8.00-7.99 (m, 2H), 7.62 (t, 2H, J=8.6 Hz), 7.63-7.61 (m, 3H), 6.85 (t, 2H, J=6.6 Hz), 6.79 (t, 1H, J=11.5 Hz), 6.47 (t, 1H, J=8.6 Hz), 5.72 (d, 1H, J=10.3 Hz)

Anal. calcd for C₂₇H₁₆N₃F₃IrCl: C, 48.61; H, 2.42; N, 6.30

Found: C, 48.35; H, 2.42; N, 6.10

### Synthesis Example 2

### Synthesis of Compound 4

Compound 4 was synthesized from Compound 3 in accordance with the synthesis route shown in Synthesis Example 1.

0.3 mmol (0.2 g) of Compound 3, 3.0 mmol (0.194 g) of potassium cyanide, and 10 ml of methanol were added to a 50-ml egg plant flask, and the mixture was refluxed under heat for 1 hour in a stream of nitrogen.

After the mixture had been left standing to cool, the solvent was removed under reduced pressure, pure water was added to the remainder, and the resultant precipitate was recovered by filtration and washed with hexane. Further, the precipitate was purified by silica gel column chromatography (developing solvent chloroform), whereby Compound 4 as a yellow solid was obtained (0.135 g, 70% yield).

¹H-NMR (CDCl₃): δ 10.02 (d, 1H, J=4.6 Hz), 8.13 (d, 2H, J=8.0 Hz), 8.02 (d, 2H, 4.0), 7.66-7.61 (m, 5H), 7.50 (q, 1H, J=4.8 Hz), 6.85-6.81 (m, 3H), 6.51 (t, 1H, J=8.6 Hz), 5.70 (d, 1H, J=9.2 Hz)

Anal. calcd for C₂₈H₁₆N₄F₃Ir: C, 51.14; H, 2.45; N, 8.52

Found: C, 51.12; H, 2.52; N, 8.26

FT-IR(KBr): 2105 cm⁻¹ [v(CN)]

### Synthesis Example 3

### Synthesis of Compound 5

Compound 5 was synthesized via the following route. Compounds Bfb, Fpyb, and FpybIr were each synthesized in the same manner as in Synthesis Example 1.

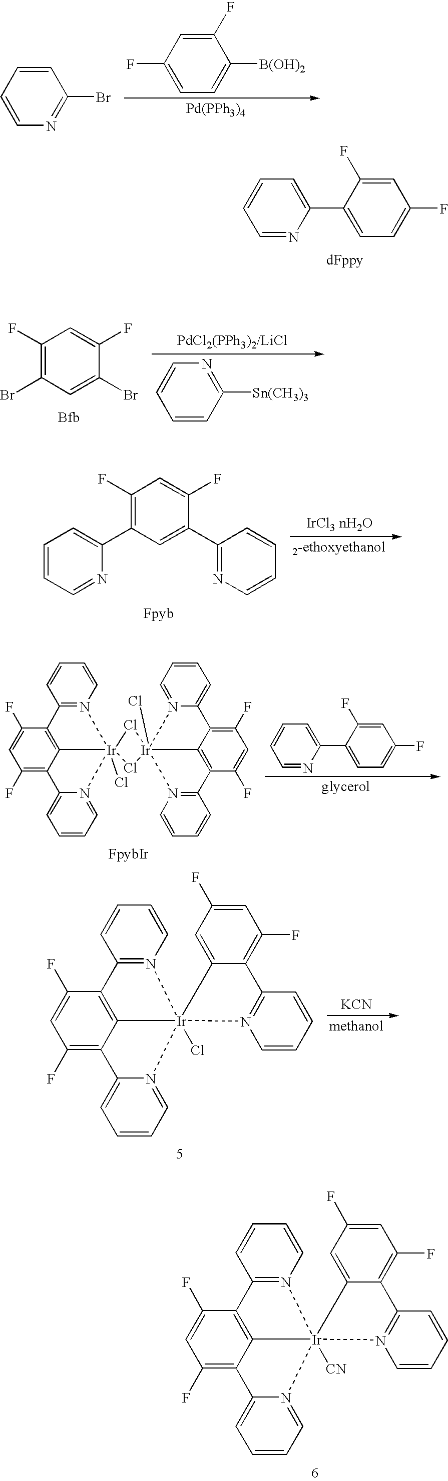

(1) Synthesis of dFppy

63.3 mmol (10 g) of 2,4-difluorophenylboronic acid and 1.73 mmol (2.0 g) of tetrakistriphenylphosphinepalladium(0) were loaded into a 1,000-ml flask, and the air in the system was replaced with nitrogen. After that, 500 ml of 1,2-dimethoxyethane, 120 ml of a 1.3-M aqueous solution of sodium carbonate, and 63.3 mmol (10 g) of 2-bromopyridine were added to the mixture, and the whole was subjected to a reaction for 8 hours under reflux.

The solvent was removed by distillation from the resultant reaction solution, and the remainder was extracted with ether. The separated organic layer was washed with water twice and dried with magnesium sulfate. The dried product was concentrated, and then the resultant oily product was purified by silica column chromatography (developing solvent methylene chloride:hexane=1:1), whereby dFppy as yellow oil was obtained (8.0 g, 67% yield).

¹H-NMR (CO(CD₃)₂-d6): δ8.71 (d, 1H, J=4.6 Hz), 8.11 (q, 1H, J=8.0 Hz), 7.88 (t, 1H, J=7.7 Hz), 7.81 (d, 1H, J=8.0 Hz), 7.36 (t, 1H, J=6.0 Hz), 7.16-7.14 (m, 2H)

### (2) Synthesis of Compound 5

0.094 mmol (0.1 g) of FpybIr, 0.934 mmol (0.18 g) of dFppy, and 10 ml of glycerol were added to a 100-ml egg plant flask, and the mixture was refluxed under heat for 26 hours. After the mixture had been left standing to cool, water was added to the mixture, and the resultant precipitate was recovered by filtration and washed with hexane, whereby Compound 5 as a yellow solid was obtained (0.04 g, 65% yield).

¹H-NMR (CDCl₃): δ 10.15 (d, 1H, J=4.0 Hz), 8.46 (d, 1H, J=8.0 Hz), 8.11 (d, 2H, J=8.6 Hz), 8.02 (t, 1H, J=7.7 Hz), 7.64 (t, 2H, J=8.0 Hz), 7.56 (t, 1H, J=6.3 Hz), 7.52 (d, 2H, J=5.7 Hz), 6.88 (t, 2H, J=6.9 Hz), 6.79 (t, 1H, J=11.5 Hz), 6.25 (t, 1H, J=11.2 Hz), 5.56 (d, 1H, J=9.7 Hz)

### Synthesis Example 4

### Synthesis of Compound 6

Compound 6 was synthesized from Compound 5 in accordance with the synthesis route shown in Synthesis Example 3.

0.3 mmol (0.2 g) of Compound 5, 3.0 mmol (0.194 g) of potassium cyanide, and 10 ml of methanol were added to a 50-ml egg plant flask, and the mixture was refluxed under heat for 1 hour in a stream of nitrogen.

After the mixture had been left standing to cool, the solvent was removed under reduced pressure, pure water was added to the remainder, and the resultant precipitate was recovered by filtration and washed with hexane. Further, the precipitate was purified by silica gel column chromatography (developing solvent chloroform), whereby Compound 6 as a yellow solid was obtained (0.127 g, 63% yield).

### Synthesis Example 5

### Synthesis of Compound 7

Compound 7 was synthesized via the following route. Compound FpybIr was synthesized in the same manner as in Synthesis Example 1.

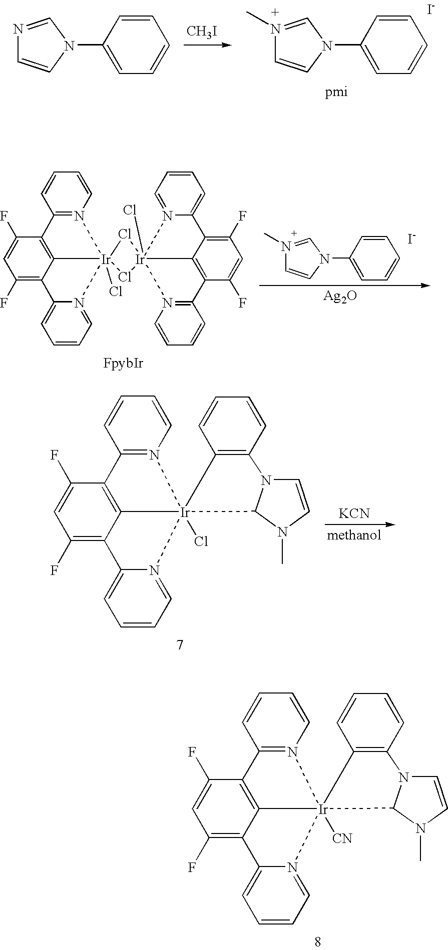

### (1) Synthesis of pmi

13.8 mmol (2.0 g) of 1-phenylimidazole and 30.5 mmol (1.9 ml) of methyl iodide were loaded into 15 ml of toluene in a 50-ml egg plant flask in a stream of nitrogen, and the whole was subjected to a reaction at 30° C. for 24 hours. The product was recovered by filtration and washed with toluene, whereby pmi as a white solid was obtained (3.65 g, 92% yield).

¹H-NMR (CDCl₃): δ10.55 (s, 1H), 7.78-7.76 (m, 2H), 7.61-7.56 (m, 5H), 4.29 (s, 3H)

### (2) Synthesis of Compound 7

0.094 mmol (0.1 g) of FpybIr, 0.282 mmol (0.081 g) of pmi, 1.22 mmol (0.283 g) of silver oxide, and 25 ml of 2-ethoxyethanol were loaded into a 50-ml eggplant flask, and the mixture was refluxed under heat for 6 hours in a stream of nitrogen. After the mixture had been left standing to cool, the solvent was removed under reduced pressure, the remainder was dissolved in methylene chloride, and the solution was filtrated through cerite. The solid after the removal of the solvent under reduced pressure was purified by silica gel column chromatography (developing solvent chloroform methanol=100:1). Further, the purified product was recrystallized with methylene chloride/chloroform/hexane, whereby Compound 7 was obtained (82 mg, 67% yield).

Anal. calcd for C₂₆H₁₉N₅F₂ClIr: C, 47.81; H, 2.93; N, 8.58

Found: C, 47.66; H, 2.53; N, 8.18

¹H-NMR (CDCl₃): δ 8.05 (d, 2H, J=8.0 Hz), 7.88 (d, 2H, J=5.2 Hz), 7.62 (d, 1H, J=2.3 Hz), 7.56 (t, 2H, J=7.7 Hz), 7.24 (d, 2H, J=2.3 Hz), 7.04 (d, 1H, J=9.2 Hz), 6.77 (t, 2H, J=6.6 Hz), 6.71 (t, 1H, J=6.9 Hz), 6.47 (t, 1H, J=7.4 Hz), 5.99 (d, 1H, J=5.99 Hz)

¹⁹F-NMR (CDCl₃): δ-108.62

### Synthesis Example 6

### Synthesis of Compound 8

Compound 8 was synthesized from Compound 7 in accordance with the synthesis route shown in Synthesis Example 5.

0.077 mmol (0.05 g) of Compound 7, 0.766 mmol (0.05 g) of potassium cyanide, and 10 ml of methanol were loaded into a 50-ml egg plant flask, and the mixture was refluxed under heat for 14 hours in a stream of nitrogen. After the mixture had been left standing to cool, the solvent was removed under reduced pressure, pure water was added to the remainder, and the solution was filtrated and washed with hexane. Further, the washed product was purified by silica gel column chromatography (developing solvent methylene chloride:methanol=25:1), whereby Compound 8 as a bright yellow solid was obtained (33 mg, 67% yield).

Anal. calcd for C₂₇H₁₉N₅F₂Ir: C, 50.38; H, 2.98; N, 10.88

Found: C, 50.20; H, 2.69; N, 10.52

¹H-NMR (CDCl₃): δ 8.06 (d, 2H, J=8.6 Hz), 7.83 (d, 2H, J=5.7 Hz), 7.62 (s, 1H), 7.58 (t, 2H, J=8.0 Hz), 7.23 (s, 1H), 7.09 (d, 1H, J=8.0 Hz), 6.82-6.78 (m, 2H), 6.73 (t, 2H, J=6.6 Hz), 6.53 (t, 1H, J=7.2 Hz), 6.02 (d, 1H, J=7.4 Hz)

¹⁹F-NMR (CDCl₃): δ-108.49

FT-IR(KBr): 2103 cm⁻¹ [v(CN)]

### Synthesis Example 7

### Synthesis of Compound 9

Compound 9w as synthesized via the following route. Compound FpybIr was synthesized in the same manner as in Synthesis Example 1.

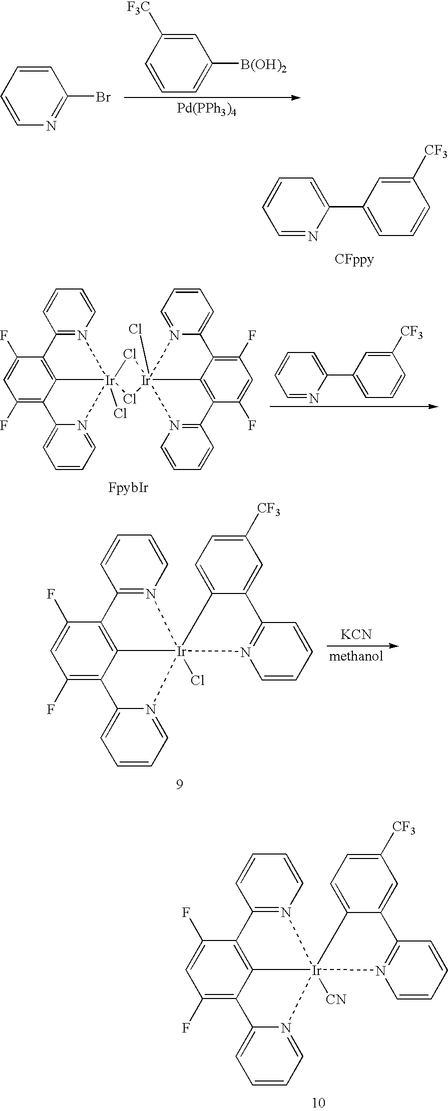

### (1) Synthesis of CFppy

13 mmol (1.49 g) of 2-chloropyridine, 16 mmol (3.0 g) of 2-trifluoromethylphenylboronic acid, 20 ml of 1,2-dimethoxyethane, 12 ml of a 2-M aqueous solution of potassium carbonate, and 0.65 mmol (0.751 g) of tetrakistriphenylphosphinepalladium(0) were loaded into a 100-ml two-necked flask, and the mixture was refluxed under heat for 19 hours. After having been left standing to cool, the mixture was extracted with ethyl acetate and dehydrated with sodium sulfate, and then the solvent was removed. The remainder was purified by distillation under reduced pressure, whereby CFppy was obtained (1.83 g, 63% yield).

¹H-NMR (CDCl₃): δ 8.73 (d, 1H, J=4.6 Hz), 8.28 (s, 1H), 8.18 (d, 1H, J=7.4 Hz), 7.82-7.76 (m, 2H), 7.67 (d, 1H, J=7.4 Hz), 7.60 (t, 1H, J=7.7 Hz), 7.30-7.29 (m, 1H)

### (2) Synthesis of Compound 9

0.189 mmol (0.2 g) of FpybIr, 1.89 mmol (0.421 g) of CFppy, and 10 ml of glycerol were loaded into a 100-ml egg plant flask, and the mixture was refluxed under heat for 12 minutes while being irradiated with a microwave in a stream of nitrogen. After the mixture had been left standing to cool, water was added to the mixture, and the resultant precipitate was recovered by filtration and washed with hexane. The washed product was purified by silica gel column chromatography (developing solvent chloroform) and recrystallization with methylene chloride/hexane, whereby Compound 9 as a whitish yellow solid was obtained (0.216 g, 80% yield).

¹H-NMR (CDCl₃): δ 10.1 (d, 1H, J=6.3 Hz), 8.15 (d, 1H, J=6.3 Hz), 8.10 (d, 2H, J=8.0 Hz), 8.06 (t, 1H, J=8.0 Hz), 7.80 (s, 1H), 7.66-7.61 (m, 3H), 7.53 (d, 2H, J=5.7 Hz), 6.86 (t, 2H, J=6.6 Hz), 6.83-6.78 (m, 2H), 6.22 (d, 1H, J=9.7 Hz)

### Synthesis Example 8

### Synthesis of Compound 10

Compound 10 was synthesized from Compound 9 in accordance with the synthesis route shown in Synthesis Example 7.

0.301 mmol (0.216 g) of Compound 9, 3.0 mmol (0.194 g) of potassium cyanide, and 10 ml of methanol were added to a 50-ml egg plant flask, and the mixture was refluxed under heat for 1 hour in a stream of nitrogen. After the mixture had been left standing to cool, the solvent was removed under reduced pressure, pure water was added to the remainder, and the resultant precipitate was recovered by filtration and washed with hexane. Further, the precipitate was purified by silica gel column chromatography (developing solvent methylene chloride:methanol=50:1), whereby Compound 10 as a whitish yellow solid was obtained (0.11 g, 52% yield).

Anal. calcd for C₂₉H₁₆N₆F₄Ir: C, 49.22; H, 2.28; N, 7.92

Found: C, 49.34; H, 2.31; N, 7.68

¹H-NMR (CDCl₃): δ 10.08 (d, 1H, J=5.7 Hz), 8.17 (d, 1H, J=8.0 Hz), 8.13-8.08 (m, 3H), 7.83 (s, 1H), 7.66-7.58 (m, 5H), 6.88-6.82 (m, 4H), 6.19 (d, 1H, J=8.0 Hz)

¹⁹F-NMR (CDCl₃): δ-62.10 (CFppy), −107.62 (Fpyb)

FT-IR(KBr): 2112 cm⁻¹ [v(CN)]

### Synthesis Example 9

### Synthesis of Compound 11

Compound 11 was synthesized via the following route.

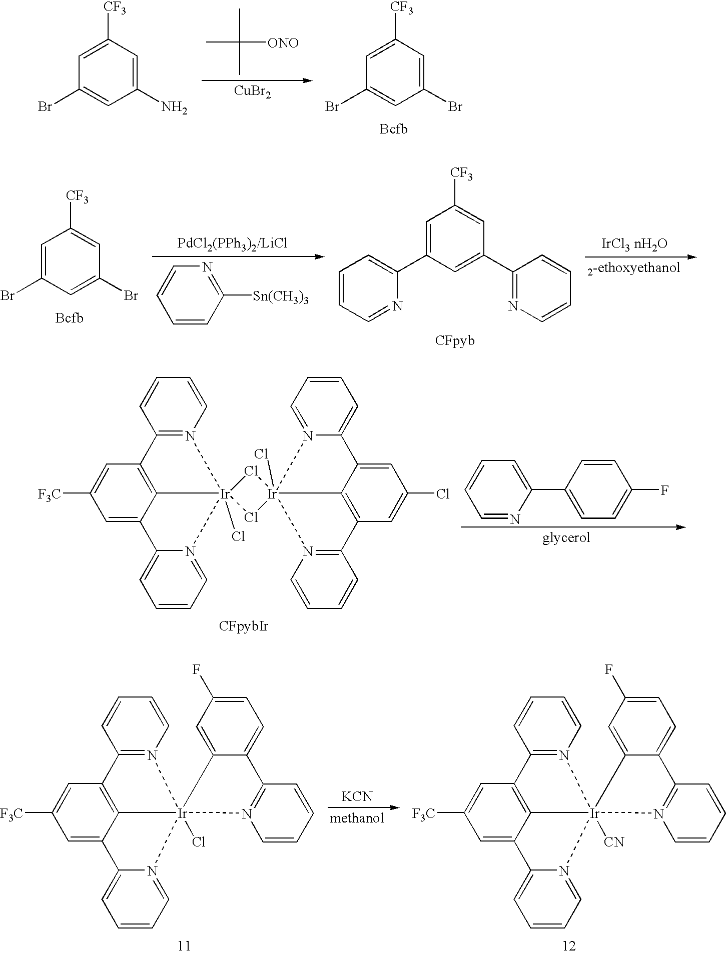

### (1) Synthesis of Bcfb

4.79 mmol (1.07 mg) of copper(II) bromide and 15 ml of acetonitrile were loaded into a three-necked flask. Under nitrogen, at 0° C., 6.4 mmol (0.844 ml) of t-butyl nitrite and 4.16 mmol (1.0 g) of 3-amino-5-bromobenzotrifluoride were dropped to the mixture, and the resultant mixture was stirred for 1.5 hours. After that, the temperature of the mixture was returned to room temperature, and the mixture was stirred for 16 hours.

The resultant solution was concentrated so that its volume might be reduced by half. The concentrate was washed with 1N hydrochloric acid and extracted with ether. After the organic layer had been dehydrated, the solvent was removed under reduced pressure, and the remainder was purified with a silica gel column (developing solvent hexane), whereby Bcfb as orange oil was obtained (0.84 g, 58% yield).

¹H-NMR (CD₃CN): δ 8.04 (s, 1H), 7.88 (s, 2H)

### (2) Synthesis of CFpyb

CFpyb was synthesized in the same manner as in the synthesis of Fpyb in Synthesis Example 1 except that Bcfb was used as a bromide as a raw material and tri-n-butyl(2-pyridyl)tin was used as a tin compound as another raw material. Purification was performed by silica gel column chromatography (developing solvent hexane ether=4:1) (0.64 g, 26% yield).

¹H-NMR (CDCl₃): δ 8.84 (s, 1H), 8.75 (d, 2H, J=5.7 Hz), 8.34 (s, 2H), 7.89 (d, 2H, J=8.0 Hz), 7.82 (t, 2H, J=7.7 Hz), 7.32 (t, 2H, J=6.0 Hz)

### (3) Synthesis of CFpybIr

0.284 mmol (0.1 g) of iridium chloride hydrate and 10 ml of 2-ethoxyethanol were loaded into a 100-ml two-necked flask, and the mixture was stirred at 110° C. in a stream of nitrogen. When the temperature of the mixture increased, 0.397 mmol (0.119 g) of CFpyb was added to the mixture, and the resultant mixture was stirred under heat for 20 hours. After having been left standing to cool, the mixture was filtrated and washed with methanol and ether, whereby an orange solid was obtained (0.103 g, 65% yield).

### (4) Synthesis of Compound 11

0.089 mmol (0.1 g) of CFpybIr, 0.712 mmol (0.123 g) of Fppy, and 10 ml of glycerol were loaded into a 100-ml egg plant flask, and the mixture was refluxed under heat for 12 minutes while being irradiated with a microwave in a stream of nitrogen. After the mixture had been left standing to cool, water was added to the mixture, and the resultant precipitate was recovered by filtration and washed with hexane, whereby a yellow powder was obtained. The powder was purified by silica gel column chromatography (developing solvent methylene chloride:methanol=50:1) and recrystallization with methylene chloride/hexane, whereby the yellow solid of Compound 11 was obtained (67 mg, 54% yield).

¹H-NMR (CDCl₃): δ 10.09 (d, 1H, J=5.7 Hz), 8.02-8.00 (m, 4H), 7.95 (d, 2H, J=8.0 Hz), 7.67 (t, 2H, J=7.7 Hz), 7.64 (d, 2H, J=5.7 Hz), 7.60-7.55 (m, 2H), 6.92 (t, 2H, J=6.6 Hz), 6.45 (t, 1H, J=8.6 Hz), 5.55 (d, 1H, J=9.7 Hz)

¹⁹F-NMR (CDCl₃): δ −60.82 (CF₃pyb), −110.71 (fppy)

### Synthesis Example 10

### Synthesis of Compound 12

Compound 12 was synthesized from Compound 11 in accordance with the synthesis route shown in Synthesis Example 9.

Compound 12 was synthesized in the same manner as in the synthesis of Compound 4 by using 0.086 mmol (60 mg) of Compound 11 as a raw material. Purification was performed by silica gel column chromatography (developing solvent methylene chloride methanol=50:1), whereby the whitish yellow solid of Compound 12 was obtained (37 mg, 63% yield).

¹H-NMR (CDCl₃): δ 10.04 (d, 1H, J=5.2 Hz), 8.04-8.03 (m, 4H), 7.97 (d, 2H, J=8.0 Hz), 7.72-7.68 (m, 4H), 7.62 (t, 1H, J=6.9 Hz), 7.51 (t, 1H, J=7.2 Hz), 6.91 (t, 2H, J=6.0 Hz), 6.48 (t, 1H, J=8.9 Hz), 5.50 (d, 1H, J=9.2 Hz)

### Synthesis Example 11

### Synthesis of Compound 29

Compound 29 was synthesized via the following route.

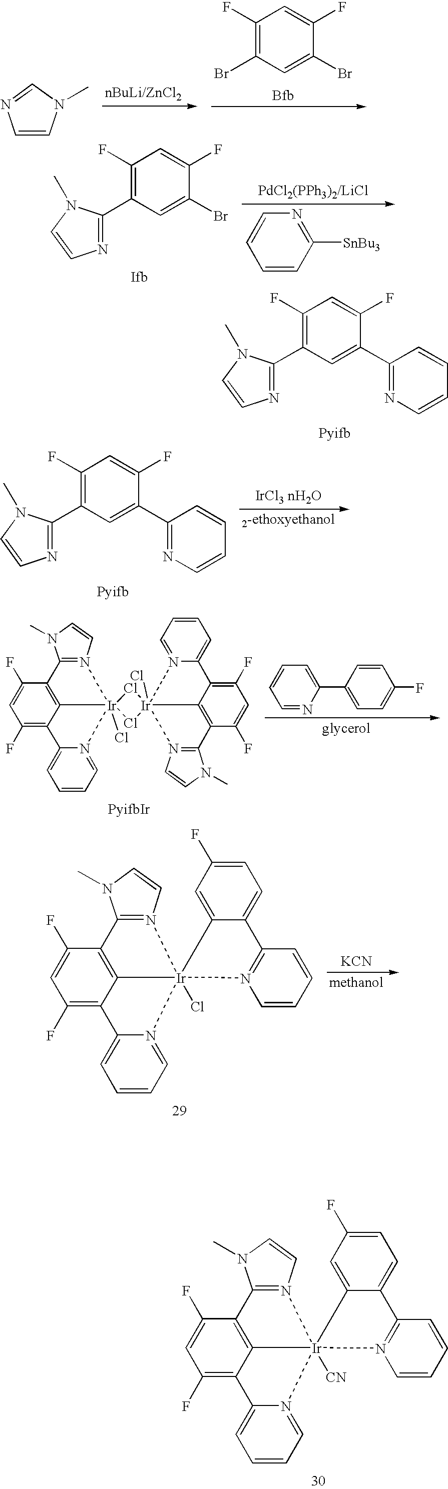

### (1) Synthesis of Ifb

The air in a 500-ml three-necked flask was replaced with nitrogen. 38 mmol (3.1 g) of N-methylimidazole and 50 ml of tetrahydrofuran were loaded into the flask, and 27.5 ml (44 mmol) of 1.6-M n-butyllithium were added to the mixture at −70° C. After the mixture had been stirred for 2 hours, 44 mmol (6.0 g) of anhydrous zinc chloride suspended in tetrahydrofuran were dropped to the mixture. The resultant mixture was stirred for 1 hour, and then its temperature was returned to room temperature. Further, a solution prepared by dissolving 0.504 mmol (0.412 g) of 1,1′-bis(diphenylphosphino) ferrocenepalladium(II) dichloride and 25.2 mmol (6.88 g) of Bfb in 20 ml of tetrahydrofuran was added to the mixture, and the resultant mixture was refluxed for 1.5 hours. After the mixture had been slightly cooled, 76 mmol (10.4 g) of anhydrous zinc chloride were added to the mixture, and the resultant mixture was refluxed for an additional 5 days.

The resultant reaction solution was charged into an aqueous solution (1 L) of 236 mmol (88 g) of ethylenediamine-N,N,N′,N′-disodium tetraacetate anhydride, and the pH of the mixture was adjusted to 8 with a 10% aqueous solution of sodium carbonate. An organic substance was extracted with methylene chloride and dehydrated with sodium sulfate, and then the solvent was removed. The remainder was purified with a silica gel column (developing solvent acetone), whereby a yellow solid was obtained. Further, the solid was sublimated, whereby the white solid of Ifb was obtained (10.2 g, 46% yield).

¹H-NMR (CDCl₃-d): d 7.84 (t, 1H, J=7.7 Hz), 7.16 (d, 1H, J=1.1 Hz), 7.03-7.01 (m, 2H), 3.62 (d, 3H, J=2.3 Hz)

### (2) Synthesis of Pyifb

The air in a 500-ml three-necked flask was replaced with nitrogen. 45.3 mmol (1.92 g) of lithium chloride, 11.3 mmol (3.1 g) of Ifb, 0.354 mmol (0.248 g) of bistriphenylphosphinepalladium dichloride, 13.6 mmol (5.0 g) of tributyl(2-pyridyl)tin, and 40 ml of toluene were added to the flask, and the mixture was refluxed under heat for 6 days.

After the mixture had been left standing to cool, a saturated aqueous solution of potassium fluoride was added to the mixture, and the resultant mixture was stirred for 3 hours. The solid was removed by filtration, and the remainder was extracted with methylene chloride and 150 ml of a 5% aqueous solution of sodium hydrogen carbonate. After that, anhydrous sodium sulfate was added to the organic layer to dehydrate the layer. Brown oil obtained after the removal of the solvent under reduced pressure was purified with a silica column, whereby the yellow oil of Pyifb was obtained (2.4 g, 78% yield).

¹H-NMR (Acetone-d₆): d 8.72 (q, 1H, J=2.1 Hz), 8.29 (t, 1H, J=8.9 Hz), 7.93-7.89 (m, 2H), 7.42-7.39 (m, 1H), 7.34 (t, 1H, J=11.2 Hz), 7.25 (d, 1H, J=1.1 Hz), 7.06 (d, 1H, J=1.1 Hz), 3.70 (d, 3H, J=1.7 Hz)

### (3) Synthesis of PyifbIr

5.9 mmol (2.07 g) of iridium chloride hydrate, 8.8 mmol (2.4 g) of Pyifb, and 30 ml of 2-ethoxyethanol were added to a 100-ml egg plant flask, and the mixture was stirred under heat and reflux for 24 hours in a stream of nitrogen. After the mixture had been left standing to cool, the product was filtrated and washed with hexane and ether, whereby a yellow solid was obtained (2.91 g, 91% yield).

### (4) Synthesis of Compound 29

0.46 mmol (0.5 g) of PyifbIr, 2.3 mmol (0.4 g) of Fppy, and 25 ml of ethylene glycol were added to a 100-ml egg plant flask, and the mixture was refluxed under heat 3 times for 1 minute while being irradiated with a microwave in a stream of nitrogen. After the mixture had been left standing to cool, water was added to the mixture, and the resultant precipitate was filtrated with a centrifugal separator and washed with hexane. Further, the washed product was purified with a silica column (developing solvent methanol:dichloromethane=1:25), whereby Compound 29 as a yellow solid was obtained (0.289 g, 47% yield).

¹H-NMR (CDCl₃-d): δ 10.06 (d, 1H, J=5.2 Hz), 8.12 (d, 1H, J=8.6 Hz), 7.95-7.92 (m, 2H), 7.62-7.54 (m, 3H), 7.47 (t, 1H, J=6.0 Hz), 6.83 (t, 1H, J=6.6 Hz), 6.76 (t, 1H, J=11.7 Hz), 6.65 (d, 1H, J=1.7 Hz), 6.45 (t, 1H, J=8.6 Hz), 6.21 (d, 1H, J=1.7 Hz), 5.63 (d, 1H, J=10.0 Hz), 4.09 (d, 3H, J=4.6 Hz)

### Synthesis Example 12

### Synthesis of Compound 30

Compound 30 was synthesized from Compound 29 in accordance with the synthesis route shown in Synthesis Example 11.

0.45 mmol (0.3 g) of Compound 29, 4.5 mmol (0.292 g) of potassium cyanide, and 40 ml of methanol were added to a 100-ml egg plant flask, and the mixture was refluxed in a stream of nitrogen. The product was recovered by filtration and washed with hexane, whereby a yellow powder was obtained. The powder was purified by silica gel column chromatography (developing solvent methanol:methylene chloride=1:25), whereby the yellow powder of Compound 30 was obtained (0.113 g, 38% yield).

¹H-NMR (CDCl₃-d): δ 0.00 (d, 1H, J=5.2 Hz), 8.14 (d, 1H, J=8.6 Hz), 7.96-7.95 (m, 2H), 7.70 (d, 1H, J=5.2 Hz), 7.62-7.59 (m, 2H), 7.42 (t, 1H, J=5.7 Hz), 6.82-6.79 (m, 2H), 6.67 (d, 1H, J=1.1 Hz), 6.49 (t, 1H, J=8.6 Hz), 6.26 (d, 1H, J=1.7 Hz), 5.64 (d, 1H, J=9.5 Hz), 4.10 (d, 3H, J=5.2 Hz)

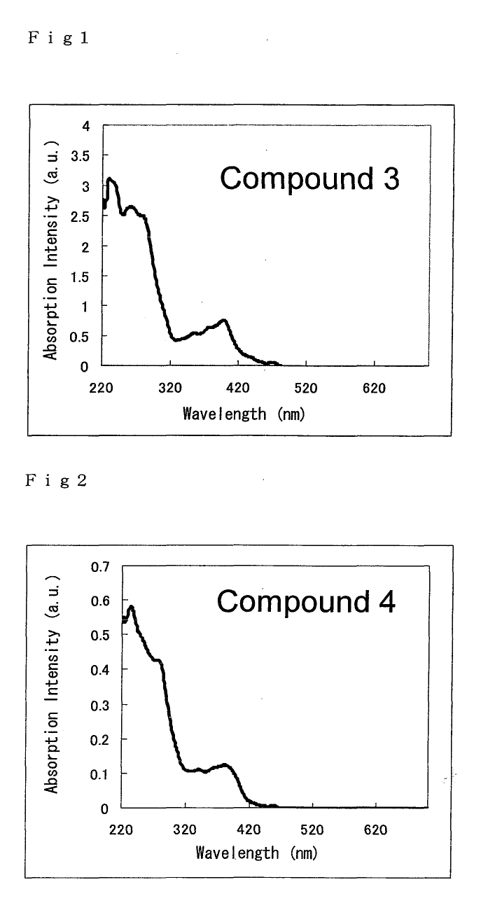

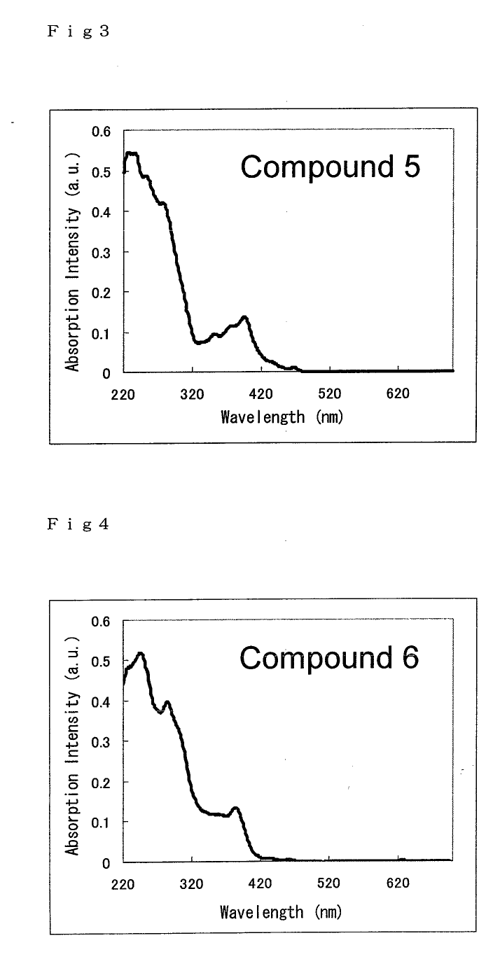

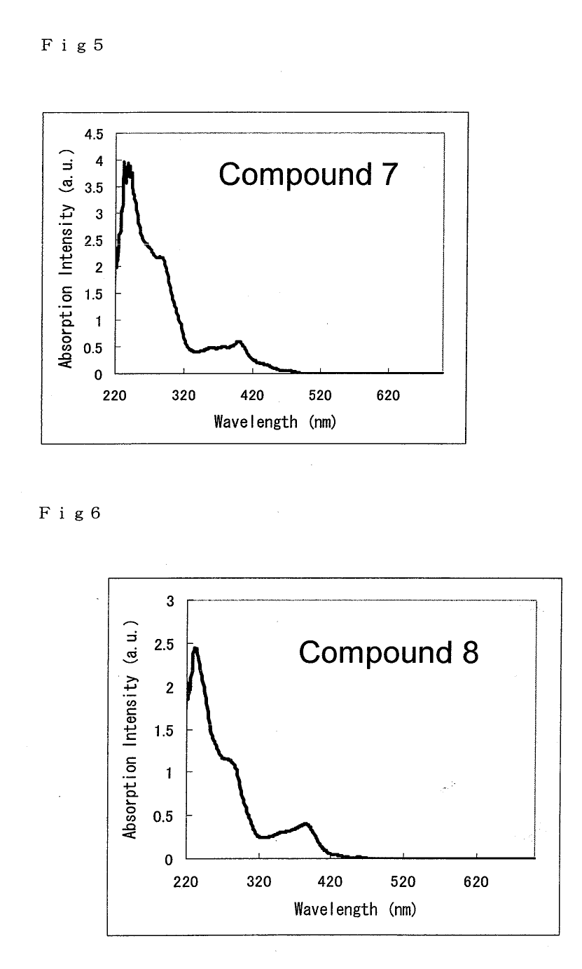

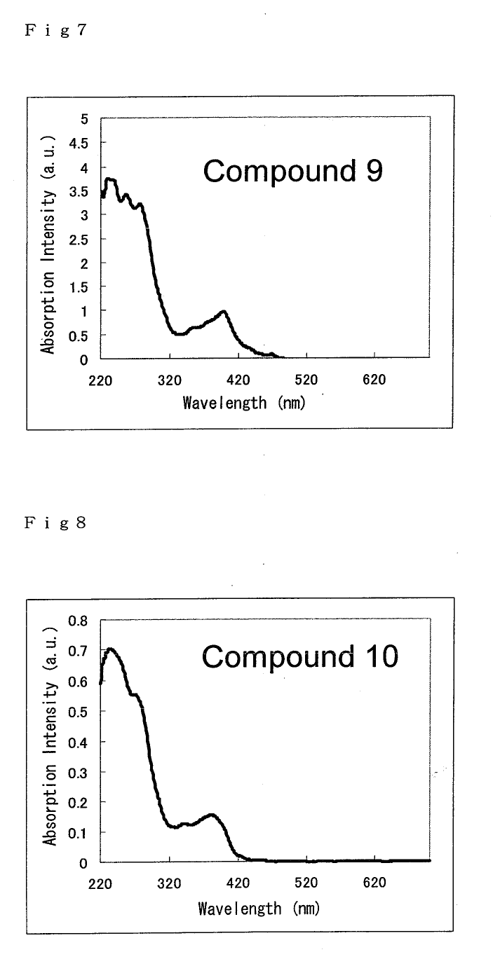

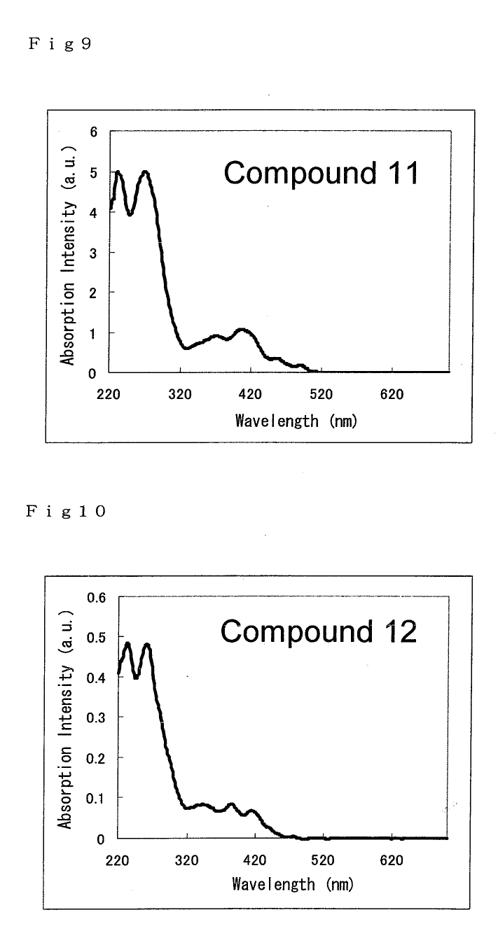

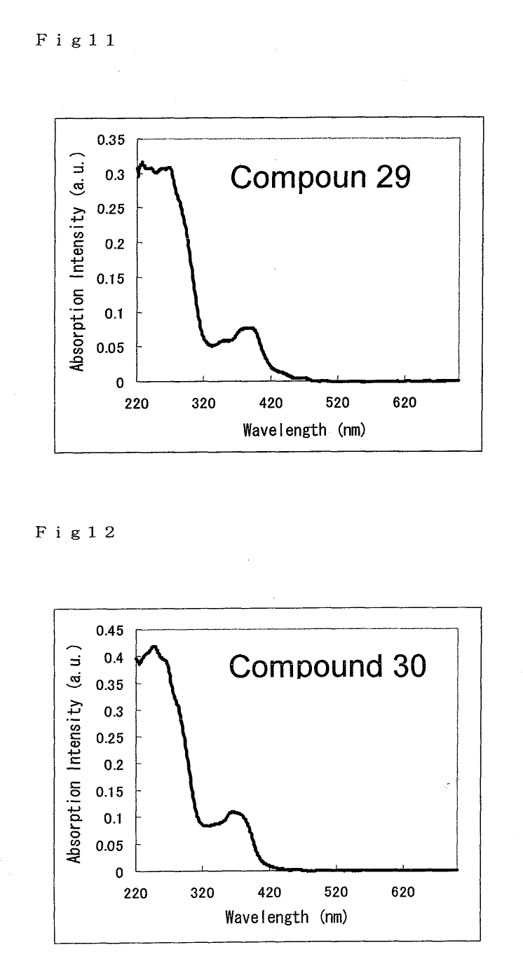

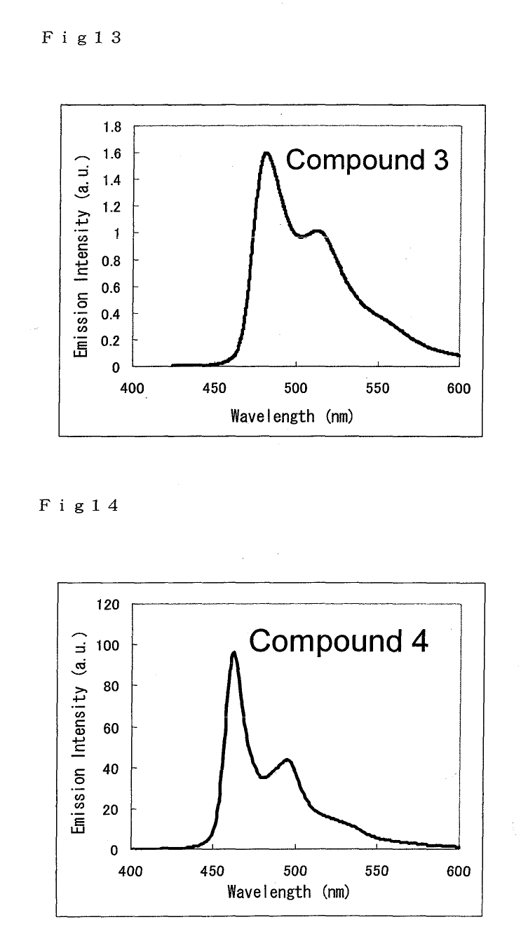

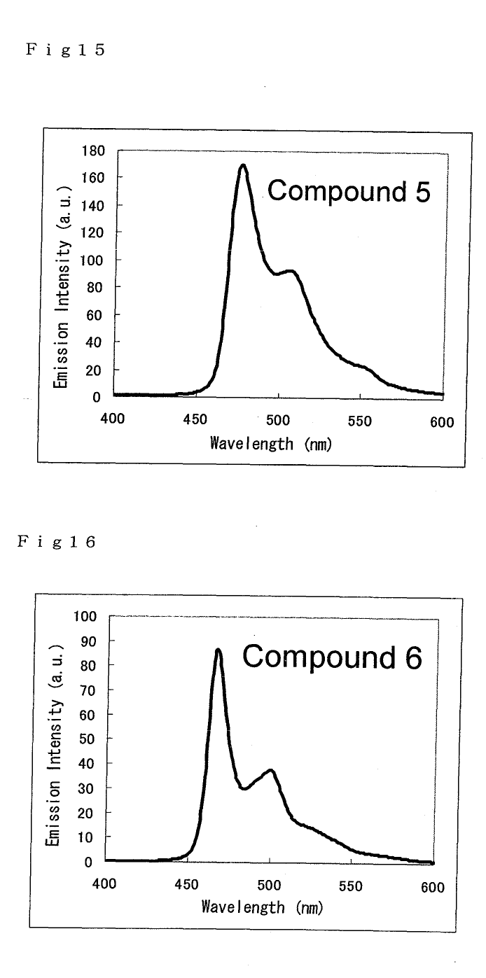

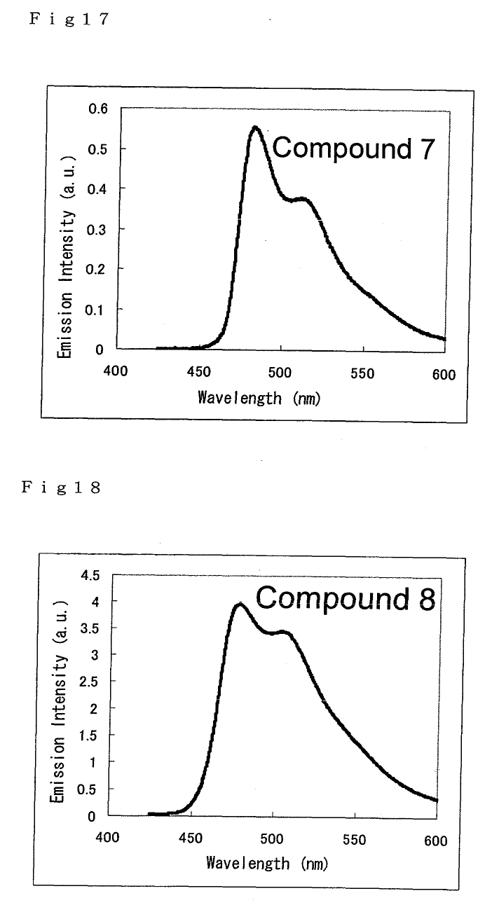

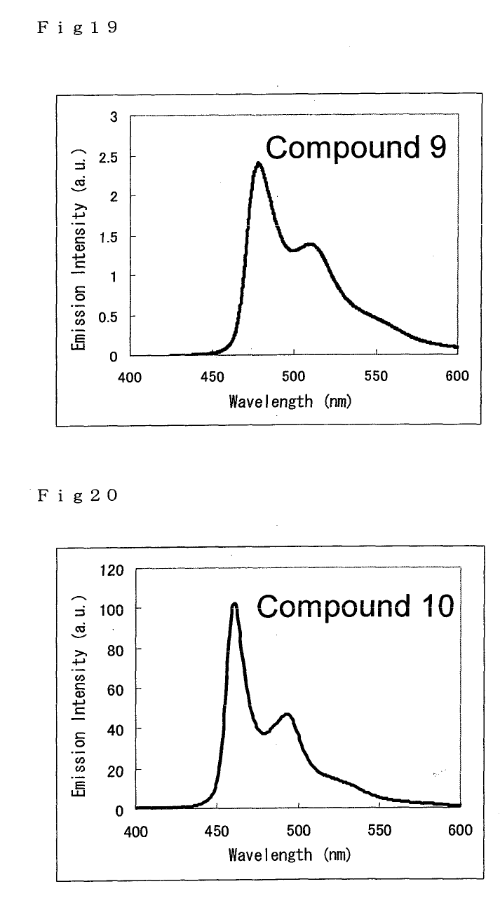

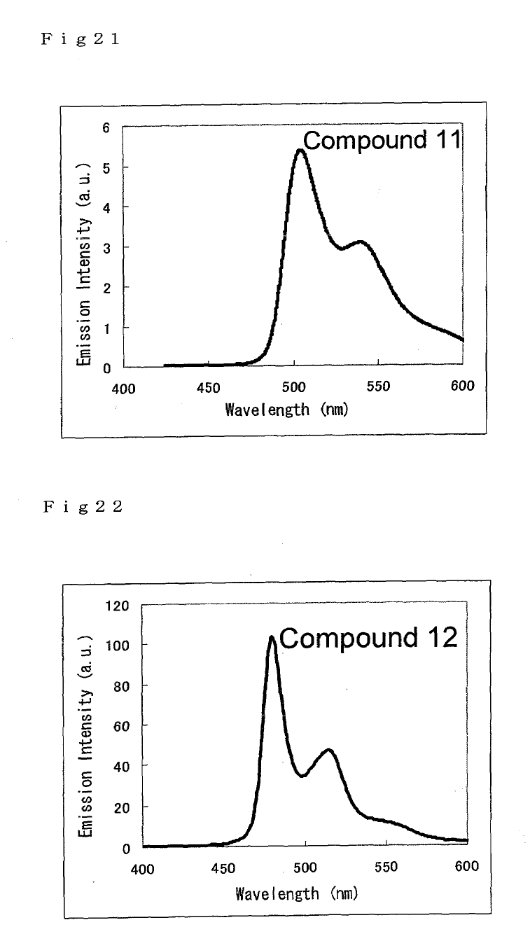

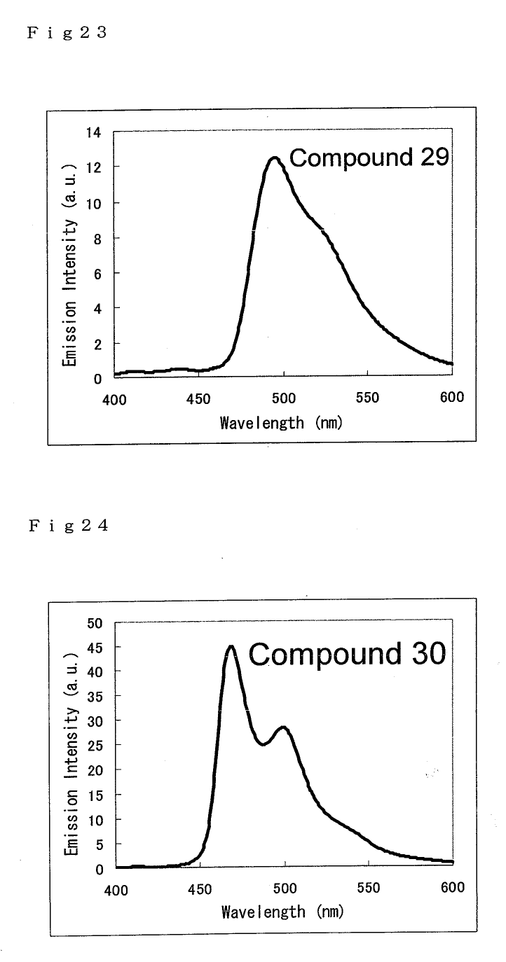

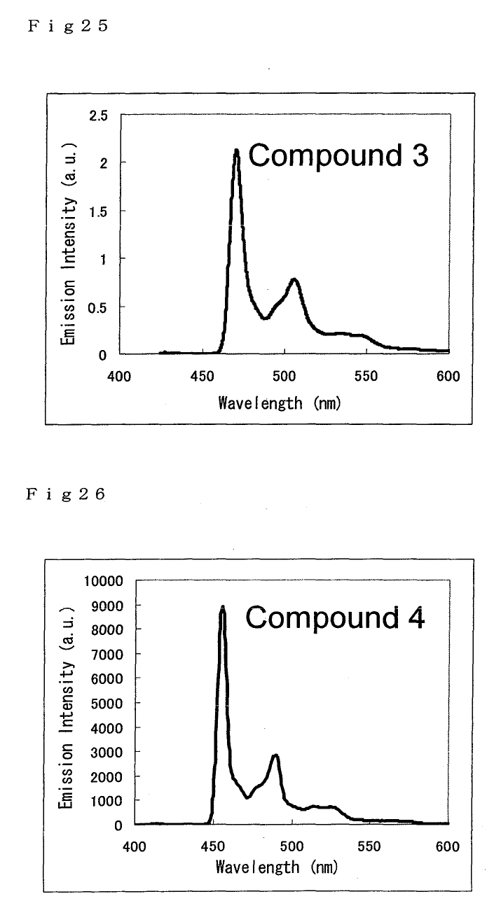

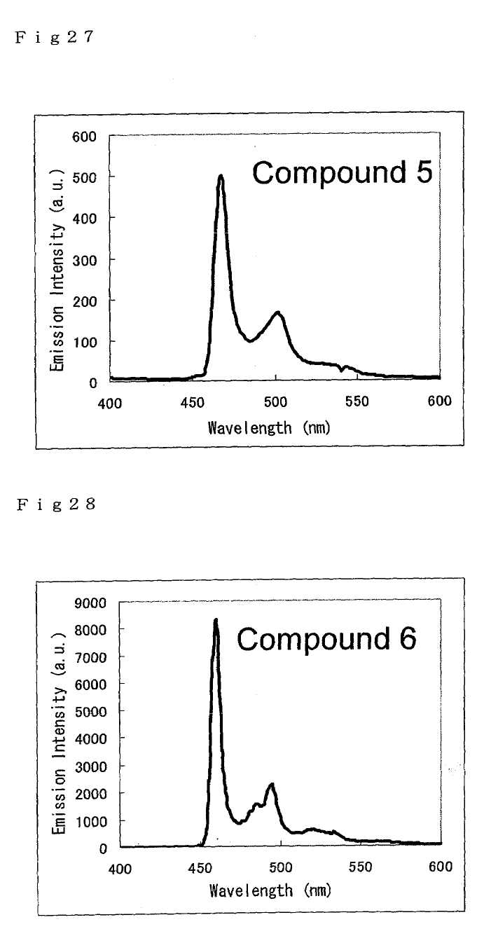

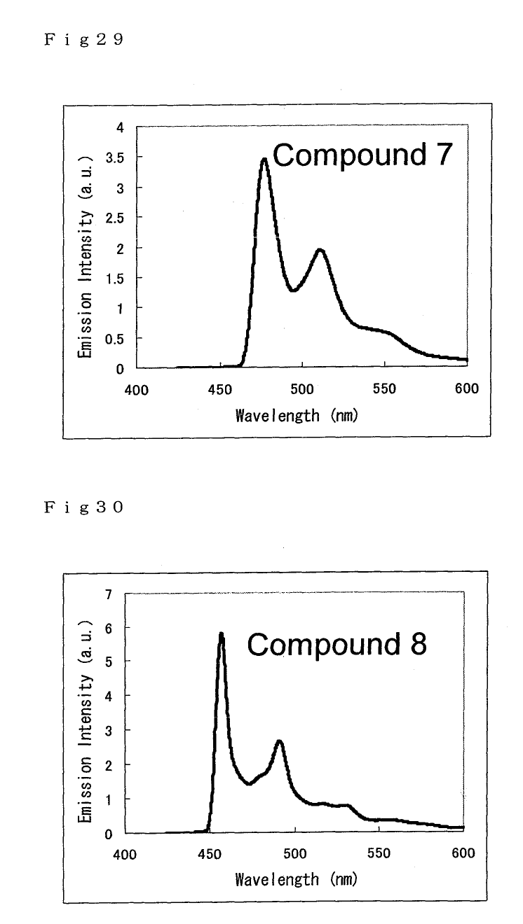

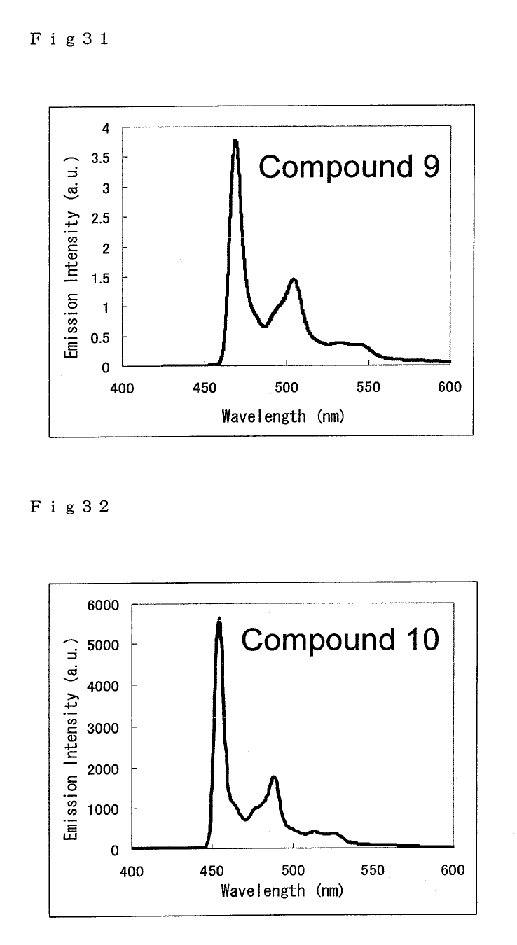

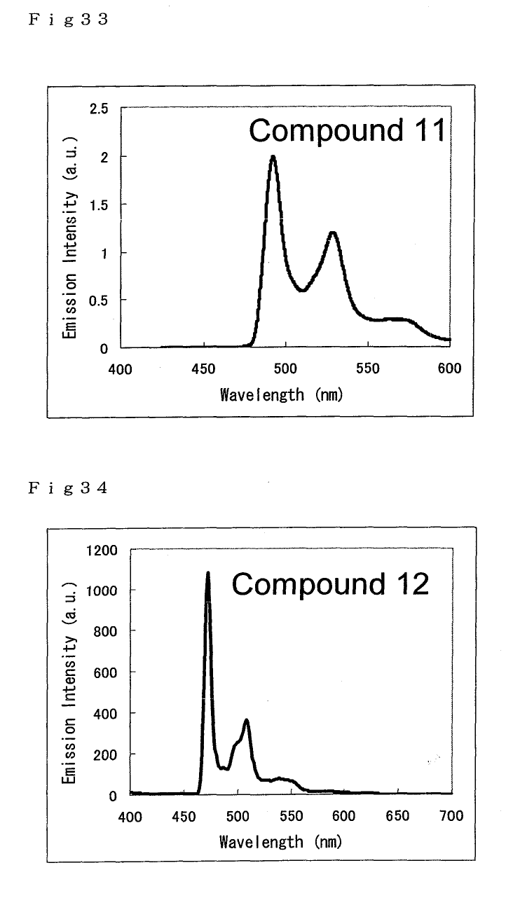

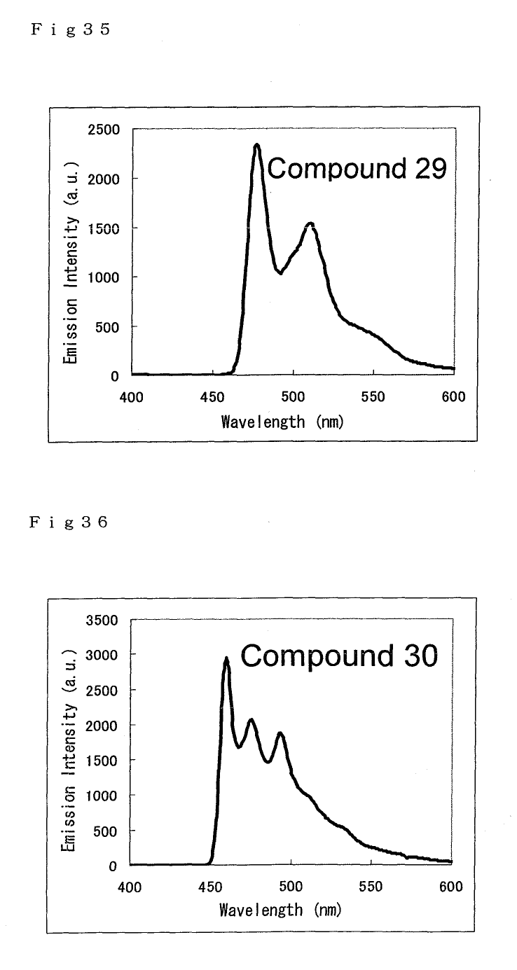

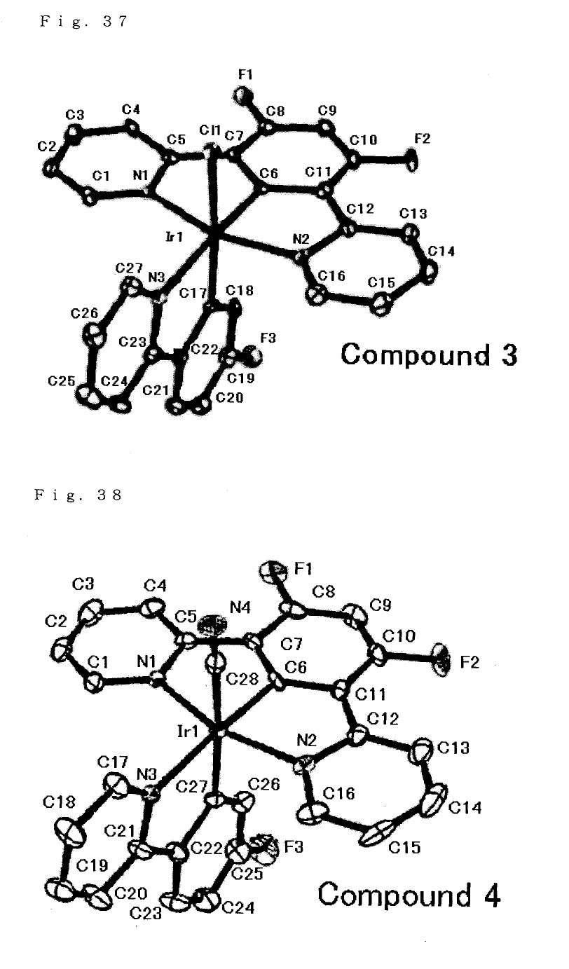

FIGS. 1 to 36 show the UV absorption spectra, room temperature emission spectra, and low temperature emission spectra at 77 K of the compounds synthesized in Synthesis Examples 1 to 12 described above. In addition, Table 2 shows a maximum luminous wavelength or the wavelength of a representative absorption peak.

TABLE 2
Spectral characteristics of compounds

| | Room | | |
|---|---|---|---|
| | temperature | | |
| | luminous | 77 K luminous | UV absorption |
| | wavelength | wavelength | wavelength |
| Compound No. | λmax(nm) | λmax(nm) | (nm) |
| 3 | 480 | 470 | 398 |
| 4 | 461 | 455 | 381 |
| 5 | 475 | 467 | 396 |
| 6 | 466 | 459 | 383 |
| 7 | 480 | 476 | 400 |
| 8 | 478 | 457 | 384 |
| 9 | 478 | 468 | 397 |
| 10 | 460 | 454 | 380 |
| 11 | 504 | 492 | 406 |
| 12 | 480 | 471 | 385, 414 |
| 29 | 494 | 476 | 388 |
| 30 | 468 | 459 | 367 |

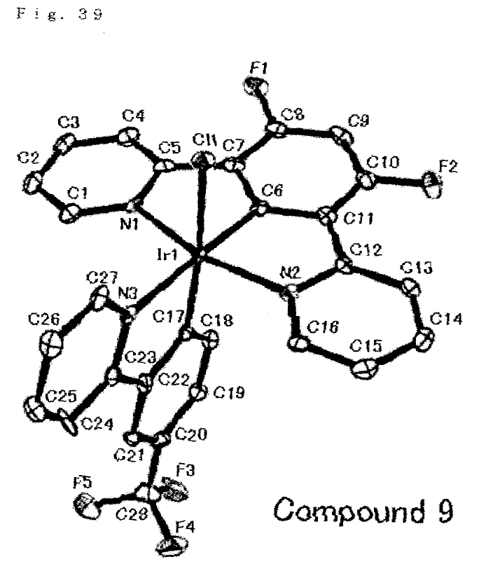

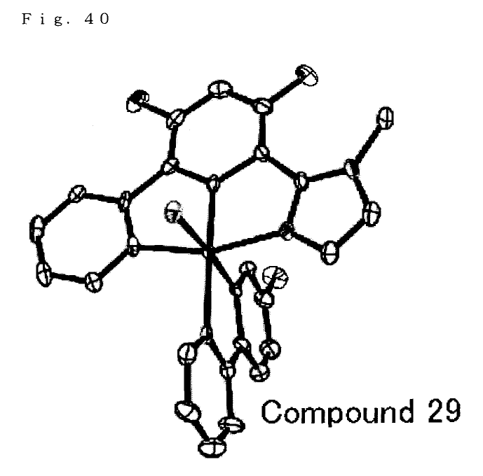

In addition, FIGS. 37 to 40 are each a view showing the X-ray crystallographic analysis of each of Compounds 3, 4, 9, and 29, Table 3 shows photophysicochemical data (a quantum yield, an excitation lifetime, and radiation and non-radiation rates) on synthesized compounds, and Table 4 shows the oxidation-reduction potential of each of the synthesized compounds measured by cyclic voltammetry.

TABLE 3
Photophysicochemical data

| | | Emission | | | |
|---|---|---|---|---|---|
| | | lifetime τ(μs) | | | |
| | Quantum | Room | | Radiation | Non-radiation |
| Compound | yield | temper- | | rate | rate |
| No. | φ^{M)} | ature^{R)} | 77 K^{b)} | Kr(×10⁵)^{c)} | Knr(×10⁵)^{c)} |
| 3 | 0.24 | 0.34 | 1.70 | 7.06 | 22.4 |
| 4 | 0.21 | 0.42 | 2.10 | 5.0 | 18.8 |
| 7 | 0.021 | 0.01 | 1.93 | — | — |
| 8 | 0.021 | 4.98 | 1.86 | — | — |
| 9 | 0.48 | 0.5 | 1.55 | 9.6 | 10.4 |
| 10 | 0.39 | 0.57 | 2.11 | 6.84 | 10.7 |
| 11 | 0.67 | 1.04 | 9.54 | 6.44 | 3.17 |
| 12 | 0.75 | 1.23 | 3.27 | 6.1 | 2.03 |
| 30 | 0.63 | 1.43 | 3.42 | 4.41 | 2.58 |

^{a)}Measured in methylene chloride saturated with argon
^{b)}Measured in a solution containing methylene chloride and toluene at a ratio of 1:1
^{c)}Calculated from Kr = φ/τ and Knr = (1 − φ)/τ

TABLE 4
Oxidation-reduction potential^{a),b)}

| | Oxidation | Reduction | |
|---|---|---|---|
| Compound No. | potential E_{1/3}^{ox} (V) | potential E_{1/2}^{rod} (V) | ΔE (V) |
| 3 | 0.90 | −2.34 | 3.24 |
| 4 | 1.10^{c)} | −2.33 | 3.43 |
| 7 | 0.64 | −2.35 | 2.99 |
| 8 | 0.90 | −2.41 | 3.31 |
| 9 | 0.86 | −2.02 | 2.88 |
| 11 | 0.79 | −2.23 | 3.02 |
| 12 | 1.03 | −2.20 | 3.23 |
| 29 | 0.68 | −2.46 | 3.14 |
| 30 | 0.90 | −2.36 | 3.26 |

^{a)}Calculated with reference to the oxidation-reduction potential of a ferrocene/ferricinium salt
^{b)}In a DMF solvent (0.1 M TBABF₄)
^{c)}In an acetonitrile solvent (0.1 M TBABF₄)

### Example 1

An organic EL device formed of a glass substrate, an anode, a hole transporting layer, a light emitting layer, a hole blocking layer, an electron transporting layer, an electron injecting layer, and a cathode was produced by using Compound 4.

A glass substrate measuring 25 mm wide by 75 mm long by 1.1 mm thick and provided with an ITO transparent electrode was subjected to ultrasonic cleaning in isopropyl alcohol for 5 minutes, and was then subjected to UV ozone cleaning for 30 minutes. 4,4′,4″-tris(carbazol-9-yl)-triphenylamine (TCTA) to be used in the hole transporting layer was formed into a film having a thickness of 95 nm by a vacuum vapor deposition method on the surface after the cleaning on the side where the ITO transparent electrode was formed. Next, the mixture of Compound 4 and Compound (C-3) to be used in the light emitting layer (a mass ratio between Compound 4 and Compound (C-3) was 1.5:20) was formed into a film by a vacuum vapor deposition method on the hole transporting layer formed of TCTA, whereby the light emitting layer was obtained. The thickness of the light emitting layer was set to 30 nm. Subsequently, Compound (B-20) shown above was formed into a film having a thickness of 25 nm by a vacuum vapor deposition method, and then tris(8-hydroxyquinoline)aluminum (Alq₃) was formed into a film having a thickness of 5 nm by a vacuum vapor deposition method. Further, lithium fluoride was formed into a film having a thickness of 1 nm by a vacuum vapor deposition method to serve as the electron injecting layer. Finally, an aluminum (Al) cathode having a thickness of 150 nm was formed by a vacuum vapor deposition method, whereby the organic EL device was produced.

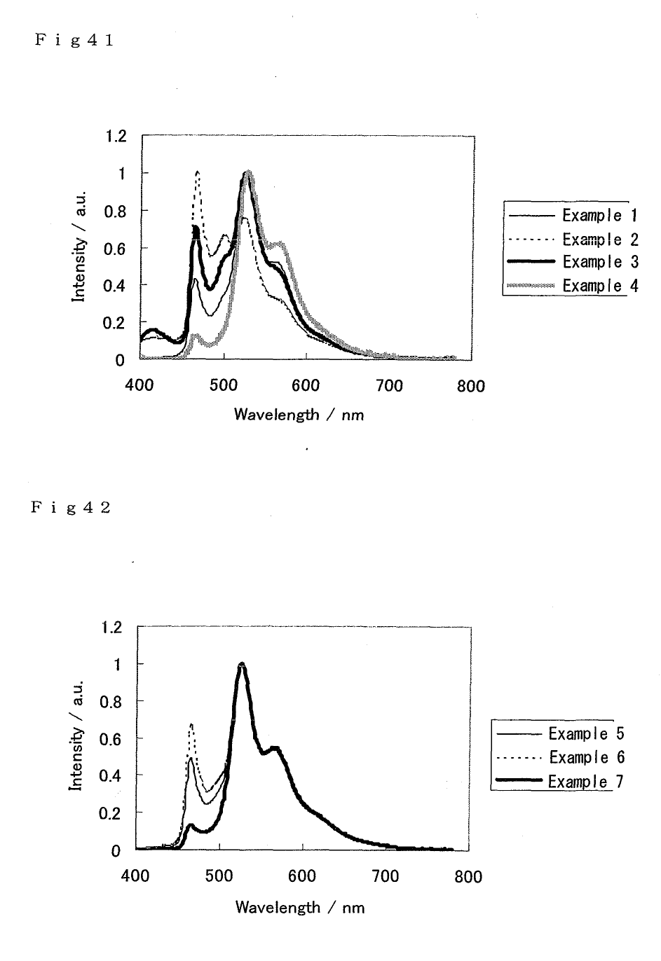

A DC voltage was applied to the resultant organic EL device while the Al electrode was defined as a negative electrode and the ITO transparent electrode was defined as a positive electrode. As a result, the device emitted light with a luminance of 111 cd/m² at a voltage of 5 V and a current density of 0.6 mA/cm². The emitted light had chromaticity coordinates of (0.29, 0.53) and a current efficiency of 18.6 cd/A. Table 5 shows the results. In addition, FIG. 41 shows the EL spectrum of the device.

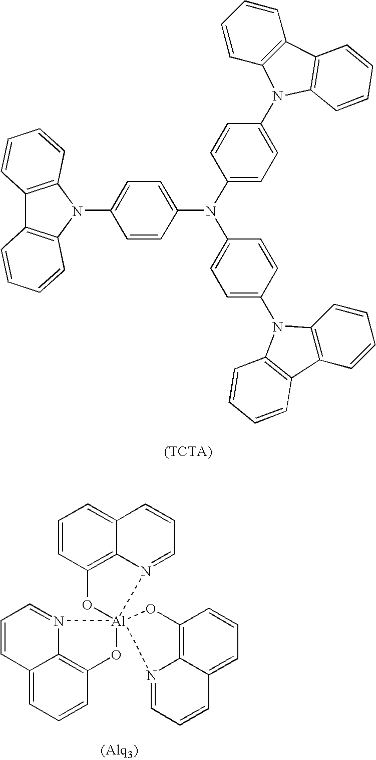

### Example 2

An organic EL device was produced in the same manner as in Example 1 except that a mass ratio between Compound 4 and Compound (C-3) in the mixture of Compound 4 and Compound (C-3) to be used in the light emitting layer was changed to 0.4:20, and the device was evaluated in the same manner as in Example 1. Table 5 shows the results. In addition, FIG. 41 shows the EL spectrum of the device.

### Example 3

An organic EL device was produced in the same manner as in Example 1 except that a mass ratio between Compound 4 and Compound (C-3) in the mixture of Compound 4 and Compound (C-3) to be used in the light emitting layer was changed to 0.8:20, and the device was evaluated in the same manner as in Example 1. Table 5 shows the results. In addition, FIG. 41 shows the EL spectrum of the device.

### Example 4

An organic EL device was produced in the same manner as in Example 1 except that a mass ratio between Compound 4 and Compound (C-3) in the mixture of Compound 4 and Compound (C-3) to be used in the light emitting layer was changed to 3.0:20, and the device was evaluated in the same manner as in Example 1. Table 5 shows the results. In addition, FIG. 41 shows the EL spectrum of the device.

### Example 5

An organic EL device was produced in the same manner as in Example 1 except that Compound (C-7) was used instead of Compound (C-3) to be used in the light emitting layer, and the device was evaluated in the same manner as in Example 1. Table 5 shows the results. In addition, FIG. 42 shows the EL spectrum of the device.

### Example 6

An organic EL device was produced in the same manner as in Example 5 except that a mass ratio between Compound 4 and Compound (C-7) in the mixture of Compound 4 and Compound (C-7) to be used in the light emitting layer was changed to 0.8:20, and the device was evaluated in the same manner as in Example 5. Table 5 shows the results. In addition, FIG. 42 shows the EL spectrum of the device.

### Example 7

An organic EL device was produced in the same manner as in Example 5 except that a mass ratio between Compound 4 and Compound (C-7) in the mixture of Compound 4 and Compound (C-7) to be used in the light emitting layer was changed to 3.0:20, and the device was evaluated in the same manner as in Example 5. Table 5 shows the results. In addition, FIG. 42 shows the EL spectrum of the device.

### Example 8

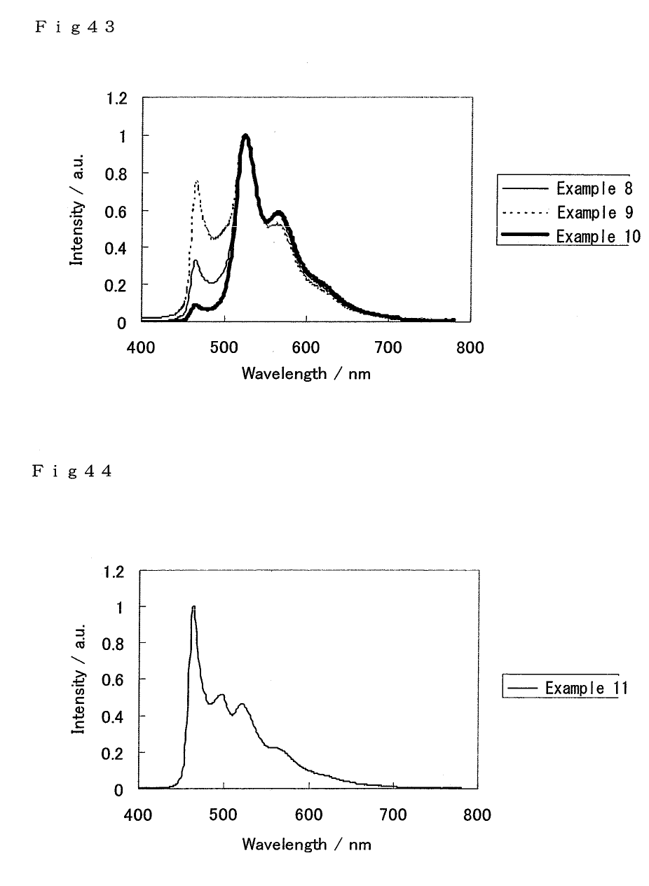

An organic EL device was produced in the same manner as in Example 1 except that: Compound (C-1) was used instead of Compound (C-3) to be used in the light emitting layer; and BCP shown below was used instead of Compound (B-20), and the device was evaluated in the same manner as in Example 1. Table 5 shows the results. In addition, FIG. 43 shows the EL spectrum of the device.

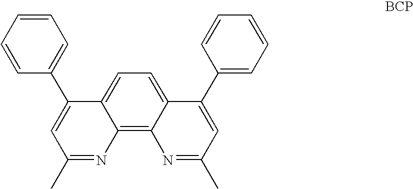

### Example 9

An organic EL device was produced in the same manner as in Example 8 except that a mass ratio between Compound 4 and Compound (C-1) in the mixture of Compound 4 and Compound (C-1) to be used in the light emitting layer was changed to 0.8:20, and the device was evaluated in the same manner as in Example 8. Table 5 shows the results. In addition, FIG. 43 shows the EL spectrum of the device.

### Example 10

An organic EL device was produced in the same manner as in Example 8 except that a mass ratio between Compound 4 and Compound (C-1) in the mixture of Compound 4 and Compound (C-1) to be used in the light emitting layer was changed to 3.0:20, and the device was evaluated in the same manner as in Example 8. Table 5 shows the results. In addition, FIG. 43 shows the EL spectrum of the device.

### Example 11

An organic EL device was produced in the same manner as in Example 1 except that Compound (D-1) was used instead of Compound (C-3) to be used in the light emitting layer, and the device was evaluated in the same manner as in Example 1. Table 5 shows the results. In addition, FIG. 44 shows the EL spectrum of the device.

### Example 12

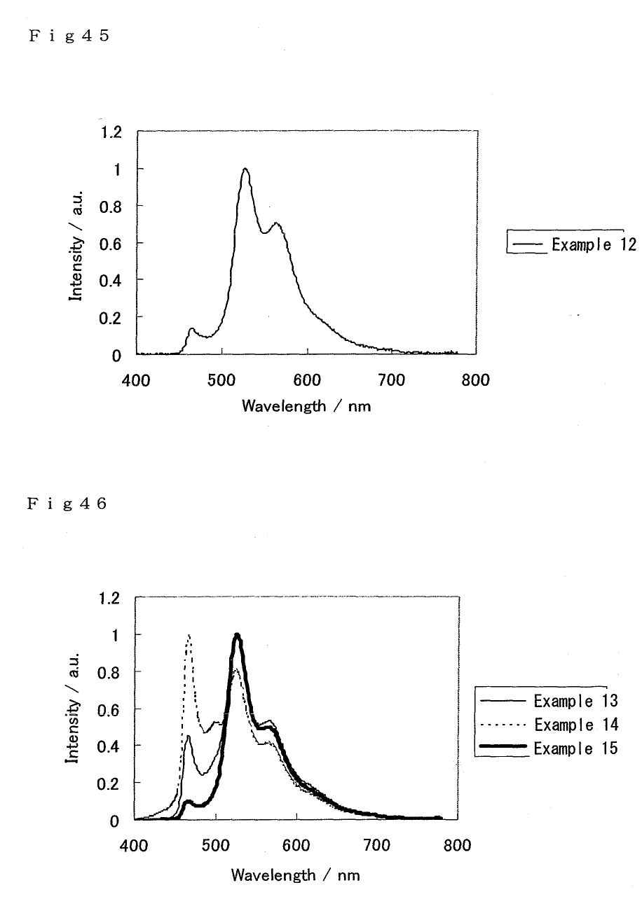

An organic EL device was produced in the same manner as in Example 1 except that Compound (C-10) was used instead of Compound (C-3) to be used in the light emitting layer, and the device was evaluated in the same manner as in Example 1. Table 5 shows the results. In addition, FIG. 45 shows the EL spectrum of the device.

### Example 13

An organic EL device formed of a glass substrate, an anode, a hole injecting layer, a hole transporting layer, a light emitting layer, a hole blocking layer, an electron transporting layer, an electron injecting layer, and a cathode was produced by using Compound 4.

A glass substrate measuring 25 mm wide by 75 mm long by 1.1 mm thick and provided with an ITO transparent electrode was subjected to ultrasonic cleaning in isopropyl alcohol for 5 minutes, and was then subjected to UV ozone cleaning for 30 minutes. Compound (F-1) shown below to be used in the hole injecting layer and TCTA to be used in the hole transporting layer was formed into films having thicknesses of 85 nm and 10 nm, respectively, by a vacuum vapor deposition method on the surface after the cleaning on the side where the ITO transparent electrode was formed. Next, the mixture of Compound 4 and Compound (C-3) to be used in the light emitting layer (amass ratio between Compound 4 and Compound (C-3) was 1.5:20) was formed into a film by a vacuum vapor deposition method on the hole transporting layer formed of TCTA, whereby the light emitting layer was obtained. The thickness of the light emitting layer was set to 30 nm. Subsequently, Compound (B-20) was formed into a film having a thickness of 25 nm by a vacuum vapor deposition method, and then Alq₃ was formed into a film having a thickness of 5 nm by a vacuum vapor deposition method. Further, lithium fluoride was formed into a film having a thickness of 1 nm by a vacuum vapor deposition method to serve as the electron injecting layer. Finally, an Al cathode having a thickness of 150 nm was formed by a vacuum vapor deposition method, whereby the organic EL device was produced.

A DC voltage was applied to the resultant organic EL device while the Al electrode was defined as a negative electrode and the ITO transparent electrode was defined as a positive electrode. As a result, the device emitted light with a luminance of 109 cd/m² at a voltage of 7.8 V and a current density of 0.6 mA/cm². The emitted light had chromaticity coordinates of (0.31, 0.52) and a current efficiency of 18.3 cd/A. Table 5 shows the results. In addition, FIG. 46 shows the EL spectrum of the device.

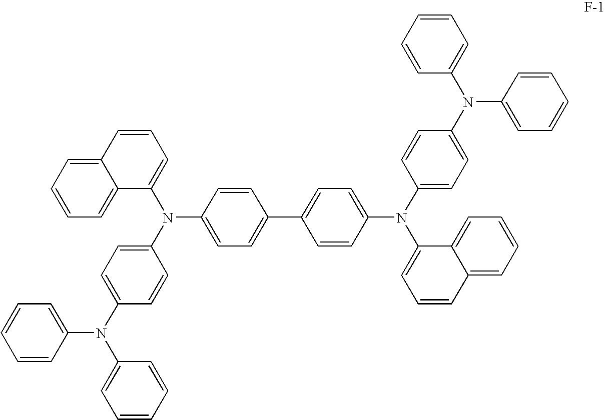

### Example 14

An organic EL device was produced in the same manner as in Example 13 except that a mass ratio between Compound 4 and Compound (C-3) in the mixture of Compound 4 and Compound (C-3) to be used in the light emitting layer was changed to 0.8:20, and the device was evaluated in the same manner as in Example 13. Table 5 shows the results. In addition, FIG. 46 shows the EL spectrum of the device.

### Example 15

An organic EL device was produced in the same manner as in Example 13 except that a mass ratio between Compound 4 and Compound (C-3) in the mixture of Compound 4 and Compound (C-3) to be used in the light emitting layer was changed to 3.0:20, and the device was evaluated in the same manner as in Example 13. Table 5 shows the results. In addition, FIG. 46 shows the EL spectrum of the device.

### Example 16

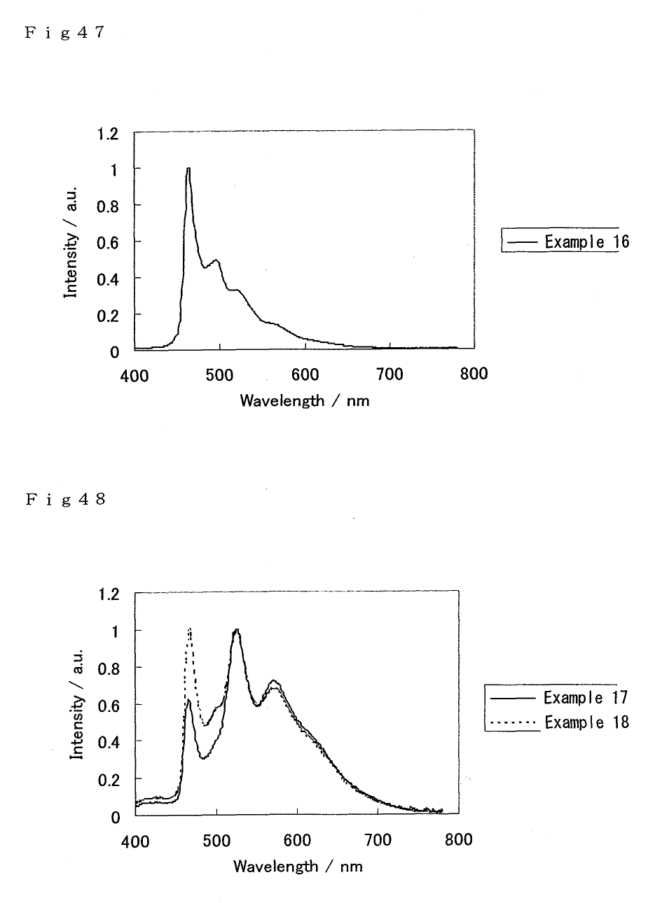

An organic EL device was produced in the same manner as in Example 13 except that Compound (D-1) was used instead of Compound (C-3) to be used in the light emitting layer, and the device was evaluated in the same manner as in Example 13. Table 5 shows the results. In addition, FIG. 47 shows the EL spectrum of the device.

### Example 17

An organic EL device formed of a glass substrate, an anode, a hole transporting layer, a light emitting layer 1, a light emitting layer 2, a hole blocking layer, an electron transporting layer, an electron injecting layer, and a cathode was produced by using Compound 4.

A glass substrate measuring 25 mm wide by 75 mm long by 1.1 mm thick and provided with an ITO transparent electrode was subjected to ultrasonic cleaning in isopropyl alcohol for 5 minutes, and was then subjected to UV ozone cleaning for 30 minutes. TCTA to be used in the hole transporting layer was formed into a film having a thickness of 85 nm by a vacuum vapor deposition method on the surface after the cleaning on the side where the ITO transparent electrode was formed. Next, the mixture of Compound (F-2) and Compound (C-3) to be used in the light emitting layer 1 (amass ratio between Compound (F-2) and Compound (C-3) was 0.4:20) was formed into a film by a vacuum vapor deposition method on the hole transporting layer formed of TCTA, whereby the light emitting layer 1 was obtained. The thickness of the light emitting layer 1 was set to 5 nm. Further, the mixture of Compound 4 and the Compound (C-3) to be used in a light emitting layer 2 (a mass ratio between Compound 4 and Compound (C-3) was 0.4:20) was formed into a film having a thickness of 30 nm on the light emitting layer 1, whereby the light emitting layer 2 was obtained. Subsequently, Compound (B-20) was formed into a film having a thickness of 25 nm by a vacuum vapor deposition method, and then Alq₃ was formed into a film having a thickness of 5 nm by a vacuum vapor deposition method. Further, lithium fluoride was formed into a film having a thickness of 1 nm by a vacuum vapor deposition method to serve as the electron injecting layer. Finally, an Al cathode having a thickness of 150 nm was formed by a vacuum vapor deposition method, whereby the organic EL device was produced.

A DC voltage was applied to the resultant organic EL device while the Al electrode was defined as a negative electrode and the ITO transparent electrode was defined as a positive electrode. As a result, the device emitted light with a luminance of 97 cd/m² at a voltage of 8.7 V and a current density of 1.7 mA/cm². The emitted light had chromaticity coordinates of (0.35, 0.46) and a current efficiency of 5.7 cd/A. The foregoing confirmed that the emitted light was white light. Table 5 shows the results. In addition, FIG. 48 shows the EL spectrum of the device.

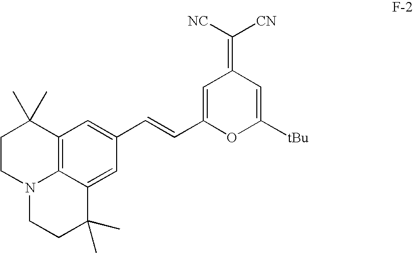

### Example 18

An additionally high voltage was applied in Example 17. As a result, the device emitted light with a luminance of 3,921 cd/m² at a voltage of 13.9 V and a current density of 100 mA/cm². The emitted light had chromaticity coordinates of (0.32, 0.42) and a current efficiency of 3.9 cd/A. The foregoing confirmed that the emitted light was white light. Table 5 shows the results. In addition, FIG. 48 shows the EL spectrum of the device.

TABLE 5

| | Volt- | Current | | | Current |
|---|---|---|---|---|---|
| | age | density | Luminance | Chromaticity | efficiency |
| | (V) | (mA/cm²) | (cd/m²) | coordinates | (cd/A) |
| Example 1 | 5 | 0.6 | 111 | 0.29, 0.53 | 18.6 |
| Example 2 | 7.7 | 3.3 | 99 | 0.22, 0.39 | 3 |
| Example 3 | 7.4 | 1.9 | 100 | 0.26, 0.46 | 5.3 |
| Example 4 | 6.2 | 0.4 | 105 | 0.34, 0.58 | 26.2 |
| Example 5 | 5.8 | 2.8 | 98 | 0.30, 0.51 | 3.5 |
| Example 6 | 6 | 3.7 | 99 | 0.29, 0.48 | 2.7 |
| Example 7 | 5.8 | 1.9 | 99 | 0.34, 0.58 | 5.2 |
| Example 8 | 5.7 | 3.2 | 97 | 0.32, 0.53 | 3 |
| Example 9 | 6.6 | 7.5 | 98 | 0.27, 0.46 | 1.3 |
| Example 10 | 5 | 0.9 | 101 | 0.35, 0.58 | 11.2 |
| Example 11 | 12.6 | 1.9 | 99 | 0.22, 0.35 | 5.2 |
| Example 12 | 8 | 0.4 | 99 | 0.34, 0.58 | 24.7 |
| Example 13 | 7.8 | 0.6 | 109 | 0.31, 0.52 | 18.3 |
| Example 14 | 8.3 | 0.9 | 103 | 0.25, 0.41 | 11.2 |
| Example 15 | 7.2 | 0.4 | 100 | 0.33, 0.59 | 28.7 |
| Example 16 | 14.2 | 2.7 | 97 | 0.19, 0.30 | 3.6 |
| Example 17 | 8.7 | 1.7 | 97 | 0.35, 0.46 | 5.7 |
| Example 18 | 13.9 | 100 | 3921 | 0.32, 0.42 | 3.9 |

### INDUSTRIAL APPLICABILITY

As described above in detail, an organic EL device using a metal complex compound of the present invention emits blue light with high purity and of short wavelength with an enhanced current efficiency, and is capable of white light emission by combining with other light emitting compounds. Accordingly, the present invention is applicable in fields of various display devices, display panels, backlights, illuminating light sources, beacon lights, signboards, interior designs and the like, suitable as a display device for color displays, and particularly suitable for a material for organic EL devices.

1. A metal complex compound comprising a structure having a tridentate chelate ligand and represented by the following general formula (I): 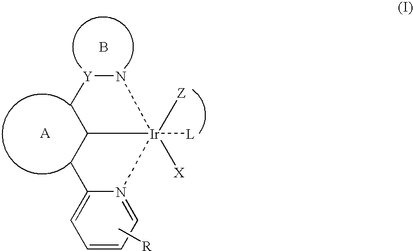
where:
Ring A comprises an aromatic hydrocarbon group which has 6 to 20 carbon atoms and which may have a substituent, or a heterocyclic group which has 2 to 20 carbon atoms and which may have a substituent;
Ring B comprises a heterocyclic group which has 2 to 20 carbon atoms and which may have a substituent, N represents a nitrogen atom, and Y represents a carbon atom or a nitrogen atom;
L and Z each independently represent an organic group containing an atom belonging to any one of Groups 14 to 16 in the periodic table;
X represents a monovalent ligand containing an atom belonging to any one of Groups 14 to 17 in the periodic table; and
R represents a hydrogen atom, a cyano group, a nitro group, a halogen atom, an alkyl group which has 1 to 12 carbon atoms and which may have a substituent, an alkylamino group which has 1 to 12 carbon atoms and which may have a substituent, an arylamino group which has 6 to 20 carbon atoms and which may have a substituent, an alkoxy group which has 1 to 12 carbon atoms and which may have a substituent, an alkoxy halide group which has 1 to 12 carbon atoms and which may have a substituent, an aryloxy group which has 6 to 20 carbon atoms and which may have a substituent, an aromatic hydrocarbon group which has 6 to 20 carbon atoms and which may have a substituent, a heterocyclic group which has 2 to 20 carbon atoms and which may have a substituent, an alkyl halide group which has 1 to 12 carbon atoms and which may have a substituent, an alkenyl group which has 2 to 12 carbon atoms and which may have a substituent, an alkynyl group which has 2 to 12 carbon atoms and which may have a substituent, or a cycloalkyl group which has 3 to 20 carbon atoms and which may have a substituent, and the number of R may be two or more, and, in this case, Rs may be identical to or different from each other, and adjacent Rs may be bonded to each other to form a cyclic structure,
provided that at least one of the tridentate chelate ligand and a bidentate chelate ligand contains an electron withdrawing group.

2. A metal complex compound according to claim 1, wherein X in the general formula (I) represents a cyano group, a chlorine atom, a bromine atom, an iodine atom, an alkoxy group, a hydrogen atom, Si (R′)₃ where R′ represents a group similar to that represented by R described above, or a substituted phenyl group.

3. A metal complex compound according to claim 1, wherein each of both the tridentate chelate ligand and the bidentate chelate ligand in the general formula (I) contains the electron withdrawing group.

4. A metal complex compound according to claim 1, wherein the electron withdrawing group in the general formula (I) comprises a halogen atom, a cyano group, a nitro group, a halogen atom-containing alkyl or ester group, or an aldehyde group.

5. A metal complex compound according to claim 1, wherein the tridentate chelate ligand in the general formula (I) comprises a compound represented by the following general formula (1) or (2): 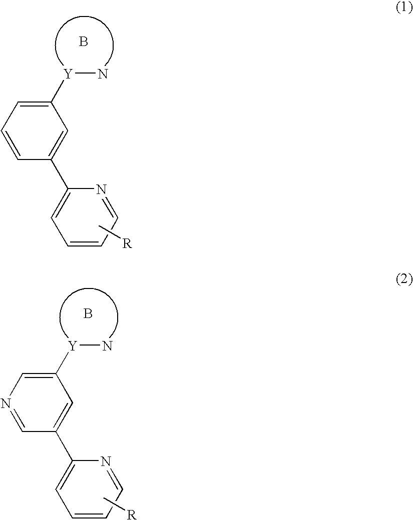
where Ring B, Y, and R each have the same meaning as that described above.

6. A metal complex compound according to claim 1, wherein the tridentate chelate ligand in the general formula (I) comprises a compound represented by any one of the following general formulae (3) to (16): 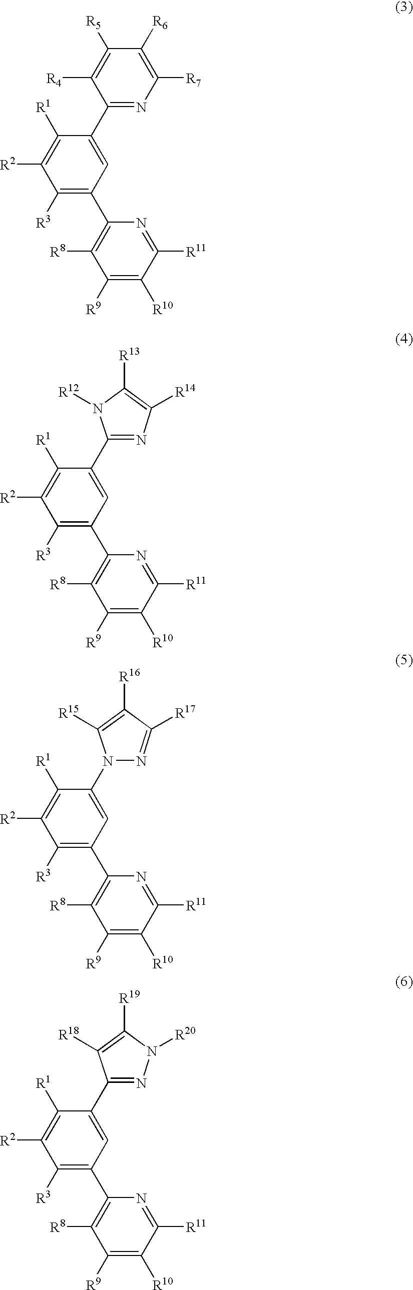 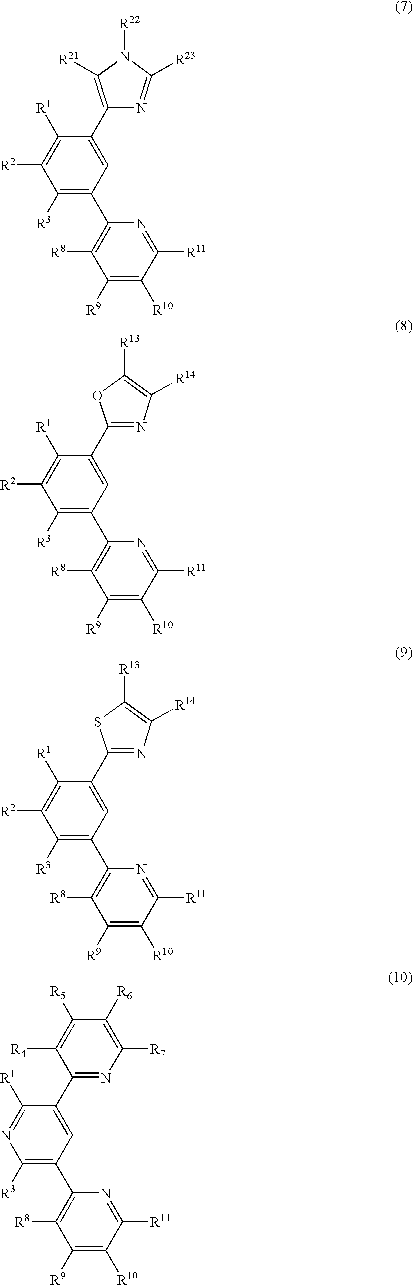 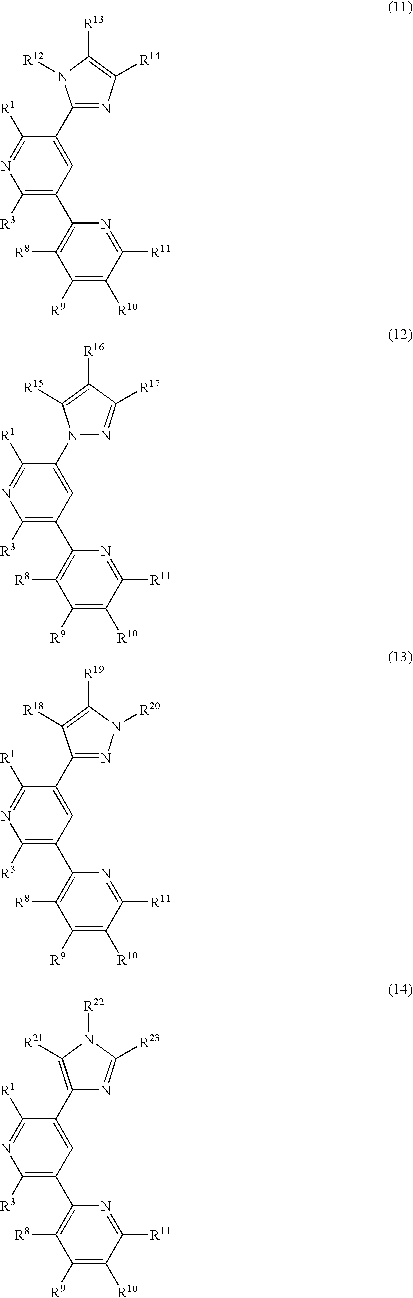 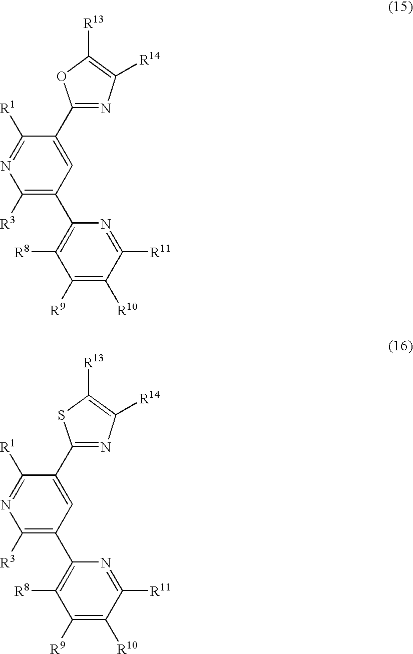
where R¹ to R²³ each have the same meaning as that of R described above, and adjacent groups of R¹ to R²³ may be bonded to each other to form a cyclic structure.

7. A metal complex compound according to claim 1, wherein the bidentate chelate ligand formed of L-Z in the general formula (I) comprises a compound represented by any one of the following general formulae (17) to (22): 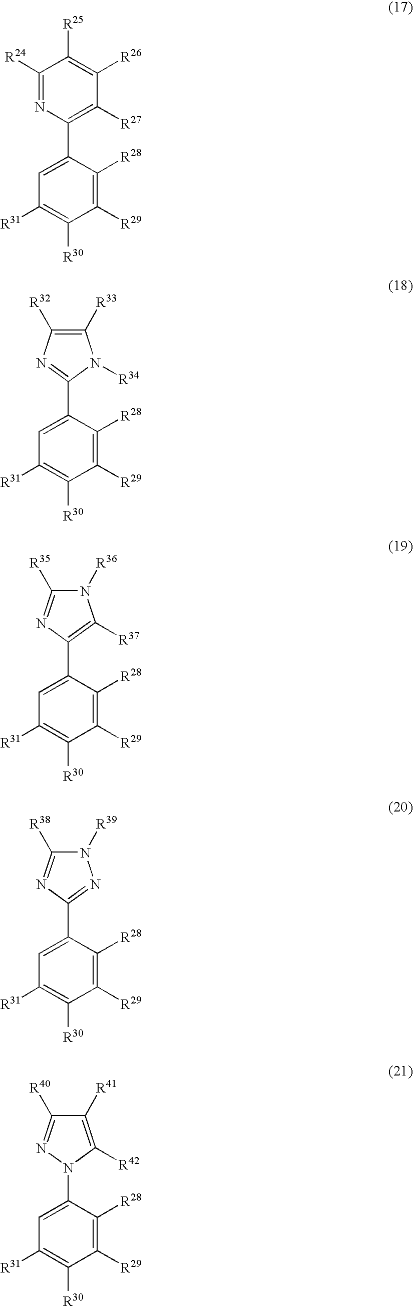 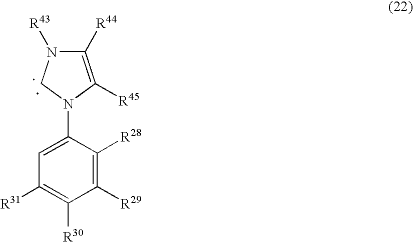
where R²⁴ to R⁴⁵ each have the same meaning as that of R described above, and adjacent groups of R²⁴ to R⁴⁵ may be bonded to each other to form a cyclic structure.

8. A metal complex compound according to claim 1, wherein the compound is represented by any one of the following general formulae (I-1) to (I-12): 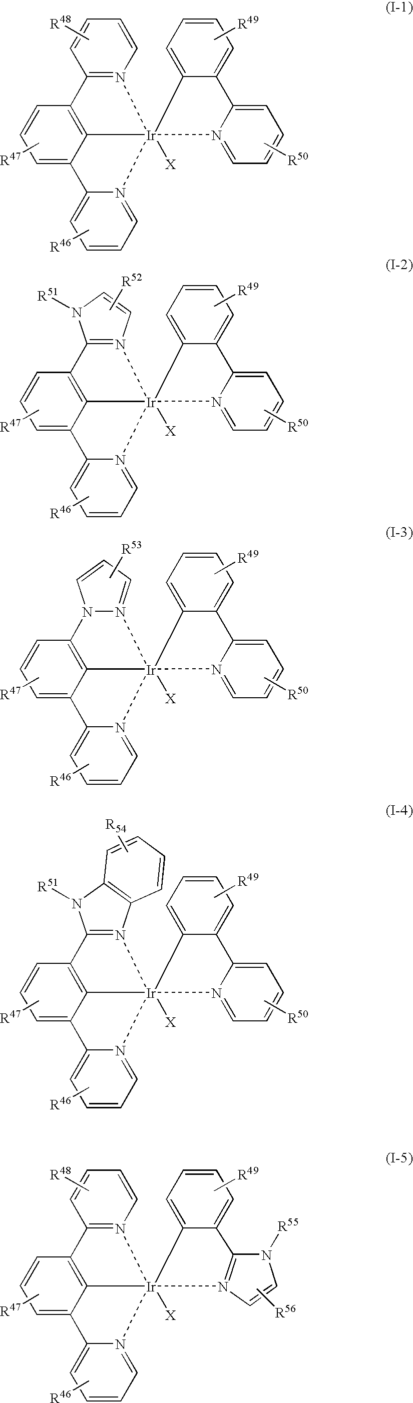 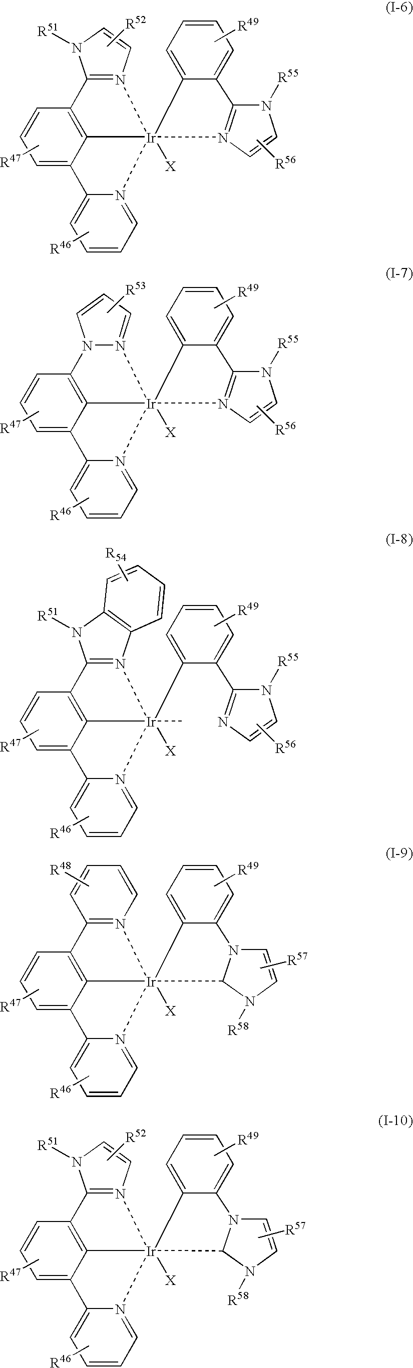 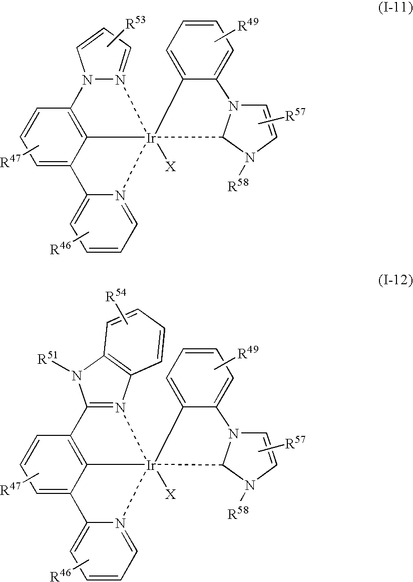
where R⁴⁶ to R⁵⁸ each have the same meaning as that of R described above, the number of each of R⁴⁶ to R⁵⁸ may be two or more, and, in this case, R⁴⁶s, R⁴⁷s, R⁴⁸s, R⁴⁹s, R⁵⁰s, R⁵¹s, R⁵²s, R⁵³s, R⁵⁴s, R⁵⁵s, R⁵⁶s, R⁵⁷s, or R⁵⁸s may be identical to or different from each other, and adjacent groups of R⁴⁶ to R⁵⁸ may be bonded to each other to form a cyclic structure.

9. A metal complex compound according to claim 1, wherein the compound is represented by any one of the following general formulae (I-13) to (I-24): 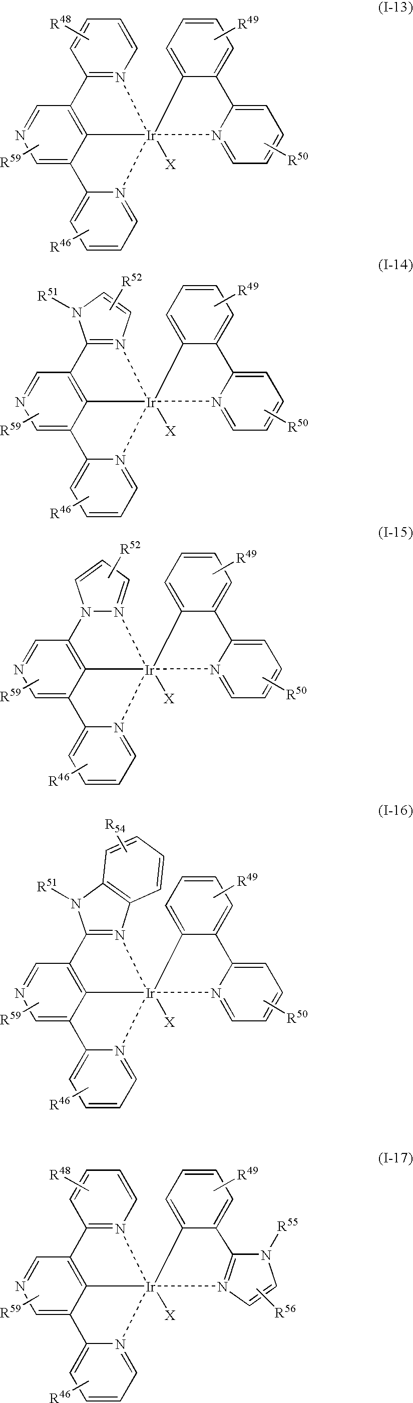 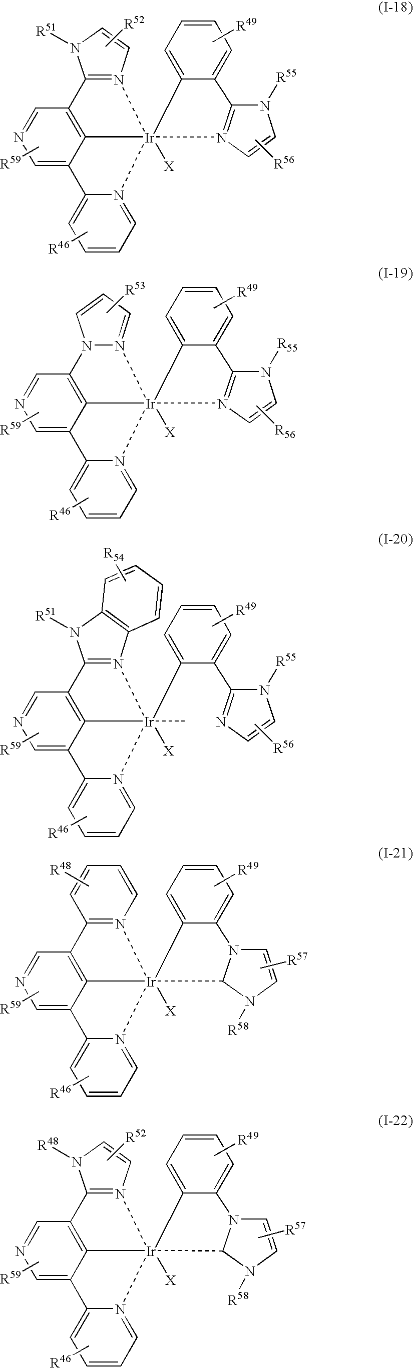 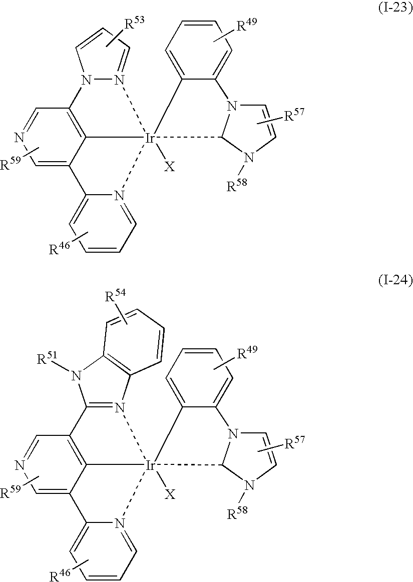
where R⁴⁶ and R⁴⁸ to R⁵⁹ each have the same meaning as that of R described above, the number of each of R⁴⁶ and R⁴⁸ to R⁵⁹ may be two or more, and, in this case, R⁴⁶s, R⁴⁸s, R⁴⁹s, R⁵⁰s, R⁵¹s, R⁵²s, R⁵³s, R⁵⁴s, R⁵⁵s, R⁵⁶s, R⁵⁷s, R⁵⁸s, or R⁵⁹s may be identical to or different from each other, and adjacent groups of R⁴⁶ and R⁴⁸ to R⁵⁹ may be bonded to each other to form a cyclic structure.

10. A material for an organic electroluminescence device comprising the metal complex compound according to claim 1.

11. An organic electroluminescence device comprising an organic thin film layer formed of one or more layers including at least a light emitting layer, the organic thin film layer being interposed between a pair of electrodes, wherein at least one layer of the organic thin film layer contains the metal complex compound according to claim 1, and emits light by applying a voltage between both the electrodes.

12. An organic electroluminescence device according to claim 11, wherein a luminescent color of the light emitted from the organic electroluminescence device is white.

13. An organic electroluminescence device according to claim 11 or 12, wherein the light emitting layer contains the metal complex compound.

14. An organic electroluminescence device according to claim 13, wherein the light emitting layer contains a luminous dopant.

15. An organic electroluminescence device according to claim 11 or 12, wherein the layer containing the metal complex compound is formed by application.
